(19) United States
(12) Patent Application Publication
(10) Pub. No.: US 2009/0278254 A1
(43) Pub. Date: Nov. 12, 2009

(54) Dielectric materials and methods for integrated circuit applications

(76) Inventors: Juha T. Rantala, Espoo (FI); Nigel Hacker, Palo Alto, CA (US); Jason Reid, Los Gatos, CA (US); William McLaughlin, Espoo (FI); Teemu T. Tormanen, Espoo (FI)

Correspondence Address: KUBOVCIK & KUBOVCIK, SUITE 1105, 1215 SOUTH CLARK STREET, ARLINGTON, VA, 22202, US

(21) Appl. No.: 12/292,968

(22) Filed: Dec. 1, 2008

Related U.S. Application Data
(63) Continuation of application No. 10/886,061, filed on Jul. 8, 2004, now abandoned.
Application No. 10/886,061 is a continuation-in-part of application No. 10/346,449, filed on Jan. 17, 2003, now Pat. No. 6,974,970.
Application No. 10/346,449 is a continuation-in-part of application No. 10/346,450, filed on Jan. 17, 2003, now abandoned.
Application No. 10/346,450 is a continuation-in-part of application No. 10/346,451, filed on Jan. 17, 2003, now Pat. No. 7,060,634.
Application No. 10/346,451 is a continuation-in-part of application No. 10/346,539, filed on Jan. 17, 2003, now Pat. No. 7,144,827.
(60) Provisional application No. 60/349,734, filed on Jan. 17, 2002.
(60) Provisional application No. 60/349,873, filed on Jan. 17, 2002.
(60) Provisional application No. 60/349,955, filed on Jan. 17, 2002.
(60) Provisional application No. 60/395,418, filed on Jul. 13, 2002.
(60) Provisional application No. 60/414,578, filed on Sep. 27, 2002.

(51) Int. Cl. H01L 23/522; H01L 21/768; H01L 21/3105

(52) U.S. Cl. 257/734; 438/624; 438/669; 438/597; 257/E21.585; 257/E21.582; 257/E21.241; 257/E23.142

(57) ABSTRACT

An integrated circuit device is provided having a substrate and areas of electrically insulating and electrically conductive material, where the electrically insulating material is a hybrid organic-inorganic material that requires no or minimal CMP and which can withstand subsequent processing steps at temperatures of 450° C. or more.

This application is a continuation of application Ser. No. 10/886,061, filed Jul. 8, 2004, which is a continuation-in-part of application Ser. Nos. 10/346,450, filed Jan. 17, 2003; 10/346,451, filed Jan. 17, 2003; 10/346,539, filed Jan. 17, 2003; and 10/346,449, filed Jan. 17, 2003.

### BACKGROUND OF THE INVENTION

Built on semiconducting substrates, integrated circuits comprise millions of transistors and other devices, which communicate electrically with one another and with outside packaging materials through multiple levels of vertical and horizontal wiring embedded in a dielectric material. Within the multilayer metallization structure, “vias” make up the vertical wiring, whereas “interconnects” form the horizontal wiring. Fabricating the metallization can involve the successive depositing and patterning of multiple layers of dielectric and metal to achieve electrical connection among transistors and to outside packaging material. The patterning for a given layer is often performed by a multi-step process comprising layer deposition, photoresist spin, photoresist exposure, photoresist develop, layer etch, and photoresist removal on a substrate. Alternatively, the metal may sometimes be patterned by first etching patterns into a layer of a dielectric material, filling the pattern with metal, then subsequently chemically/mechanically polishing the metal so that the metal remains embedded only in the openings of the dielectric. As an interconnect material, aluminum has been utilized for many years due to its high conductivity, good adhesion to SiO₂, known processing methods (sputtering and etching) and low cost. Aluminum alloys have also been developed over the years to improve the melting point, diffusion, electromigration and other qualities as compared to pure aluminum. Spanning successive layers of aluminum, tungsten has traditionally served as the conductive via plug material.

In IC's, silicon dioxide, having a dielectric constant of around 4.0, has been the dielectric of choice, used in conjunction with aluminum-based and tungsten-based interconnects and via for many years. The drive to faster microprocessors and more powerful electronic devices in recent years has resulted in very high circuit densities and faster operating speeds which—in turn—have required that higher conductivity metals and lower-k dielectrics (preferably below 3.0, more preferably below 2.5 dielectric constant) be used. In the past few years, VLSI (and ULSI) processes have been moving to copper damascene processes, where copper (or a copper alloy) is used for the higher conductance in the conductor lines and a spin-on or CVD process is used for producing low-k dielectrics which can be employed for the insulating material surrounding the conductor lines. To circumvent problems with etching, copper along with a barrier metal is blanket deposited over recessed dielectric structures consisting of interconnect and via openings and subsequently polished in a processing method known as the “dual damascene.” The bottom of the via opening is usually the top of an interconnect from the previous metal layer or, in some instances, the contacting layer to the substrate.

In addition to being lithographically patternable, the dielectric IC material should be easy to deposit or form, preferably at a high deposition rate and at a relatively low temperature. Once the material has been deposited or formed, it should also be readily patterned, and preferably patterned with small feature sizes if needed. The patterned material should preferably have low surface and/or sidewall roughness. It might also be desirable that such materials be hydrophobic to limit uptake of moisture (or other fluids), and be stable with a relatively high glass transition temperature (not degrade or otherwise physically and/or chemically change upon further processing or when in use).

Summarizing: aside from possessing a low dielectric constant, the ideal dielectric should have the following properties:

1. High modulus and hardness in order to bind the maze of metal interconnects and vias together as well as abet chemical mechanical polishing processing steps.
2. Low thermal expansion, typically less than or equal to that of metal interconnects.
3. Excellent thermal stability, generally in excess of 400° C.
4. No cracking, excellent fill and planarization properties
5. Excellent adhesion to dielectric, semiconductor, and metal materials.
6. Sufficient thermal conductivity to dissipate joule healing from interconnects and vias.
7. Material density that precludes absorption of solvents, moisture, or reactive gasses.
8. Allows desired etch profiles at very small dimensions.
9. Low current leakage, high breakdown voltages, and low loss-tangents.
10. Stable interfaces between the dielectric and contacting materials.

By necessity, low-k materials are usually engineered on the basis of compromises. Silicate-based low-k materials can demonstrate exceptional thermal stability and usable modulus but can be plagued by brittleness and cracking. Organic materials, by contrast, often show improved material toughness, but at the expense of increased softness, lower thermal stability, and higher thermal expansion coefficients.

Porous materials sacrifice mechanical properties and possess a strong tendency of absorbing chemicals used in semiconductor fabrication leading to reliability failures. Furthermore, these porous materials are mesoporous or micro porous with pore diameters in excess of 2 nm and pore volumes greater than 30%. Fluorinated materials can induce corrosion of metal interconnects, rendering a chip inoperative. Generally, the mechanical robustness and thermal conductivity of low-k materials is lower than the corresponding properties of their pure silicon dioxide analogues, making integration into the fabrication flow very challenging. Further, known materials comprising exclusively inorganic bonds making up the siloxane matrix are brittle and have poor elasticity at high temperatures.

FIG. 1 gives an example of a typical process for patterning a dielectric film. First a dielectric layer film 12 is deposited on a wafer substrate 10 typically by spin-on or chemical vapor deposition processes. Next, a removable, photosensitive “photoresist” film 14 is spun onto the wafer substrate 10. Afterward, the photoresist 12 is selectively exposed through a mask which serves as a template for the layer's circuit pattern and is subsequently developed (developer applied to remove either exposed or unexposed areas depending upon the type of resist). The photoresist is typically baked after spin, exposure, and develop. Next, the layer film is etched in a reactive plasma, wet bath, or vapor ambient in regions not covered by the photoresist to define the circuit pattern. Lastly, the photoresist 14 is stripped. The process of layer deposition, photoresist delineation, etching, and stripping is repeated many times during the fabrication process.

Because photoresist may unacceptably erode during the etch process or may not be able to be adequately delineated within device specifications, a hard mask is sometimes inserted between the layer film and the photoresist (the materials of the invention could also be used for making such a hard mask). FIG. 2 illustrates this typical method, which is similar to the dielectric patterning process described previously in relation to FIG. 1. The layer film could be metal, semiconductor, or dielectric material depending on the application. As can be seen in FIG. 2, a substrate 10 is provided on which is deposited a layer film 12. On film 12 is deposited a hard mask 13. On hard mask 13 is deposited a photoresist material 14. The photoresist is exposed and developed so as to selectively expose the underlying hard mask 13. Then, as can be further seen in FIG. 2, the hard mask 13 is etched via the exposed areas in photoresist 12. Thereafter, the photoresist is removed and the dielectric film 12 is etched by using the hard mask 13 as the pattern mask.

The “dual damascene” process used in integrated circuit application combines dielectric etches and sometimes hard masks to form trenches and vias to contain metal interconnects. FIG. 3 demonstrates one implementation of the technique. From the bottom up in FIG. 3a, the stack is made up of a substrate 20, a dielectric film 22, a hard mask 23, a second dielectric film 24, and a patterned photoresist layer 26. After etching and photoresist strip, a dual-width trench feature is formed as shown in FIG. 3b. The openings are then filled with metal and subsequently polished, leaving metal only within the openings.

The procedures shown in FIGS. 1-3 are often repeated many times during integrated circuit application, which adds to the cost of the circuit and degrades yield. Reducing the number of steps, such as implementing a photopatternable dielectric material which obviates the need for photoresist and etching steps, has huge benefits to the circuit manufacturer.

In addition to the dielectric IC material being photopatternable, it is also desirable that the material be easy to deposit or form, preferably at a high deposition rate and at a relatively low temperature. Once deposited or formed, it is desirable that the material be easily patterned, and preferably patterned with small feature sizes if needed. Once patterned, the material should preferably have low surface and/or sidewall roughness. It might also desirable that such materials be hydrophobic to limit uptake of moisture (or other fluids), and be stable with a relatively high glass transition temperature (not degrade or otherwise physically and/or chemically change upon further processing or when in use).

There is a need for improved methods of making dielectric materials. There is a further need for improved methods of making dielectric materials.

### SUMMARY OF THE INVENTION

The present invention is directed generally to methods for making dielectric materials for semiconductor devices. The invention is directed to utilizing specific precursors so as to reliably control such methods for making the dielectric materials. In one embodiment, particular silanes, preferably those having a single halogen, alkoxy or OH group bound to silicon (with various organic groups, as will be discussed below, being bound in other positions to the silicon).

In one embodiment of the invention, an integrated circuit device is provided having a substrate and areas of electrically insulating and electrically conductive material, wherein the electrically insulating material is a hybrid organic-inorganic material that has a coefficient of thermal expansion (CTE) of 12 to 22 ppm and a dielectric constant of 3.0 or less.

In another embodiment of the invention, an integrated circuit device is provided having a substrate and areas of electrically insulating and electrically conductive material, wherein the electrically insulating material is a hybrid organic-inorganic siloxane or silsesquioxane material that has a coefficient of thermal expansion in the range of 12 to 22 ppm.

In a still further embodiment of the invention, an integrated circuit device is provided having a substrate and areas of electrically insulating and electrically conductive material, wherein the electrically insulating material is a hybrid organic-inorganic material that has a coefficient of thermal expansion in the range of 12-22 ppm and a modulus of 4.0 GPa or more.

In yet another embodiment of the invention, an integrated circuit device is provided comprising a substrate and areas of electrically insulating and electrically conductive material, wherein the electrically insulating material is a hybrid organic-inorganic material that has a coefficient of thermal expansion of 12 to 22 ppm, a density of 1.2 g/cm³ or more, and a dielectric constant of 3.0 or less.

In another embodiment of the present invention, precursors, as described above, are used to make fully, partially and non-fluorinated hybrid organic-inorganic siloxane materials (FHOSM) as an interlevel dielectric and/or hard mask in integrated circuit processes and devices. In one embodiment of the invention, the FHOSM takes the place of the typical interlevel dielectric or hard mask films depicted in FIGS. 1-3. Application of the IC material of the invention is performed with spin-on or other deposition processes. Patterning can be accomplished by masking and etching procedures described previously. Or, the sensitivity of FHOSM can be utilized to reduce the number of processing steps. Instead of patterning the film with photoresist and etch processes, the film dielectric itself is photopatternable like photoresist. Compared to the standard process depicted in FIG. 1, the photopatternable FHOSM process eliminates several processing steps potentially reducing costs and improving yield. Similar to the photopatternable dielectric concept described in the previous embodiment, a photopatternable FHOSM may be used as a hard mask material for etching semiconductor, dielectric, or metal underlayers. The number of processing steps required to fabricate the feature is reduced with respect conventional processing techniques shown in FIG. 1. And, owing to their “negative” behavior under exposure, photopatternable FHOSM can also be applied to reduce the number of processing steps required to build a dielectric “dual damascene” structure. In addition, to patterning FOSHM by photolithography processes defined previously, exposure by particle beams, such as electron beams, is also possible. Also, the present invention covers use of FOSHM in printed circuit board applications, which are similar to those discussed for integrated circuits.

### BRIEF DESCRIPTION OF THE DRAWINGS

FIG. 1 is a cross-sectional view of a conventional process flow for patterning of dielectric film using conventional processes;

FIG. 2 is a cross-sectional view of a conventional process flow for etching of a layer film through a hard mask. In some processes, the photoresist strip may occur after the film etch;

FIG. 3 is an illustration of a damascene structure before (a) and after (b) final etch and photoresist strip;

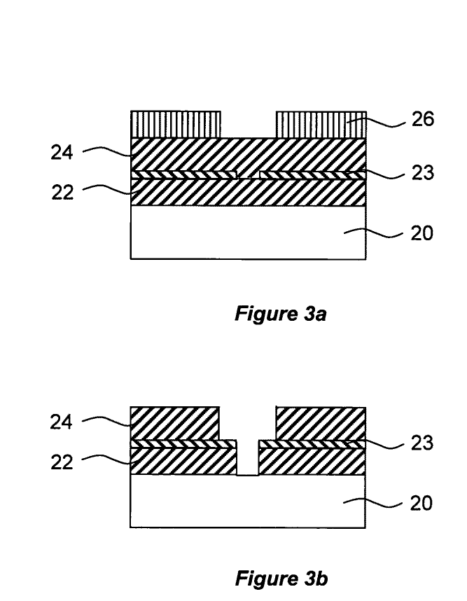

FIG. 4 is an illustration of a cross-sectional process flow of the present invention for patterning FHOSM films. Note the reduction in steps compared to the standard dielectric process depicted in FIG. 1;

FIG. 5 is a process flow of the present invention for implementing a photopatternable hard mask process using FHOSM. Note the reduction in steps compared to the convention process shown in FIG. 2; and

FIG. 6 is a “dual damascene” process flow of the present invention using FHOSM;

FIG. 7A is a cross section of a tungsten via process using materials of the present invention, whereas FIG. 7B is a hot aluminum process using materials of the present invention.

### DESCRIPTION OF THE PREFERRED EMBODIMENTS

In one embodiment of the present invention, hybrid organic-inorganic materials are used for IC applications. In this embodiment, the hybrid materials of the invention can provide the benefits of low dielectric constant, direct patternability, by exposure to light or particle beam, as well as other characteristics such as stability, glass transition temperature, ease of handling and deposition, etc. In this embodiment, the hybrid materials of the can have an inorganic backbone, including but not limited to one that is made of a metal or metalloid oxide three dimensional network, and the like, with organic substituents and cross linking groups, that can be partially or fully fluorinated.

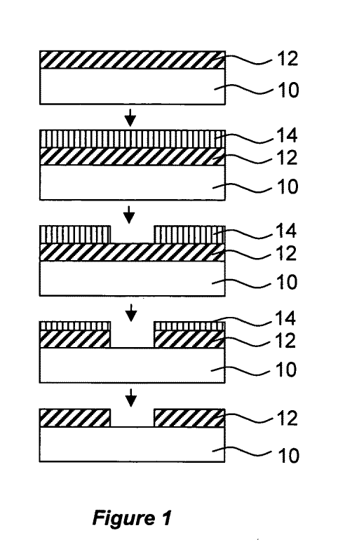

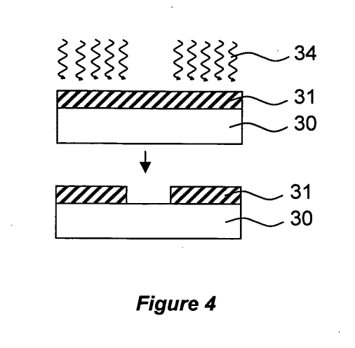

In one embodiment of the invention, the photosensitivity of FHOSM is utilized to reduce the number of processing steps. Instead of patterning the film with photoresist and etch processes, the film dielectric itself is photopatternable like photoresist. Compared to the standard process depicted in FIG. 1, the photopatternable FHOSM process eliminates several processing steps potentially reducing costs and improving yield. As can be seen in FIG. 4, in the present invention, a substrate 30 is provided. The substrate 30 can be any suitable substrate, such as a silicon substrate, or a substrate having multiple film layers already deposited thereon. On the substrate is deposited the hybrid material 31 of the present invention. The hybrid material is selectively exposed to electromagnetic energy (e.g., UV light) or particle beam (e.g., electron beam), so as to selectively crosslink exposed areas. Non-exposed areas are removed with a developer, as can be seen in FIG. 4. Similar to photo-resist, the material is baked after spin, development, and when applicable, exposure to optimize performance. As can be seen from the above, the additional steps of adding photoresist, developing the photoresist, etching through exposed areas of the photoresist, and final photoresist removal, are not needed in the present invention as compared to the prior art method illustrated in FIG. 1.

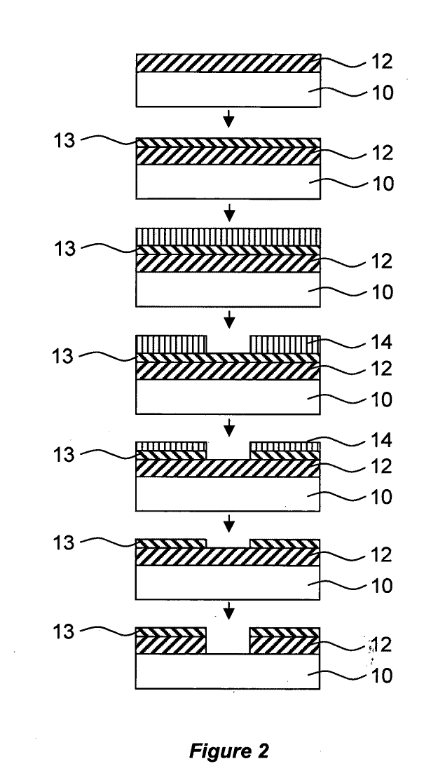

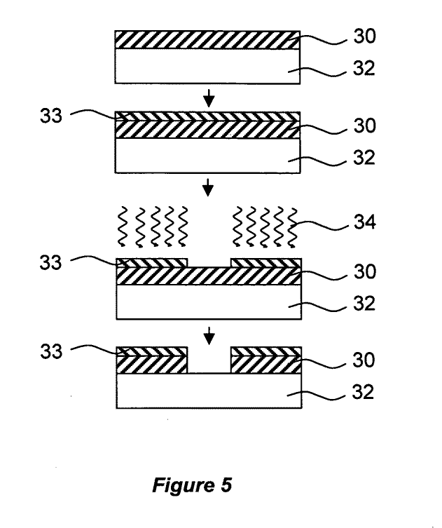

Similar to the photopatternable dielectric concept described in the previous embodiment, a photopatternable hybrid material of the present invention may be used as a hard mask material when etching semiconductor, dielectric, or metal underlayers as shown in FIG. 5. The number of processing steps required to fabricate the feature is reduced with respect conventional processing techniques shown in FIGS. 1 and 2. As can be seen in FIG. 5, a substrate 30 is provided on which is deposited a material to be etched 32 (e.g., metal, dielectric or semiconductor layer). On layer 32 is deposited a hard mask 33 which is formed of the hybrid material of the present invention. The hard mask is selectively exposed to electromagnetic radiation or particle beam 34 followed by removal of non-exposed areas of the mask layer. Finally, the underlying layer 32 is etched via the pattern in the mask layer 33 (with an etch chemistry that is tailored to the material 32 and that will not remove to an appreciable degree mask 33). Etching can be accomplished through ion, vapor, or liquid methods.

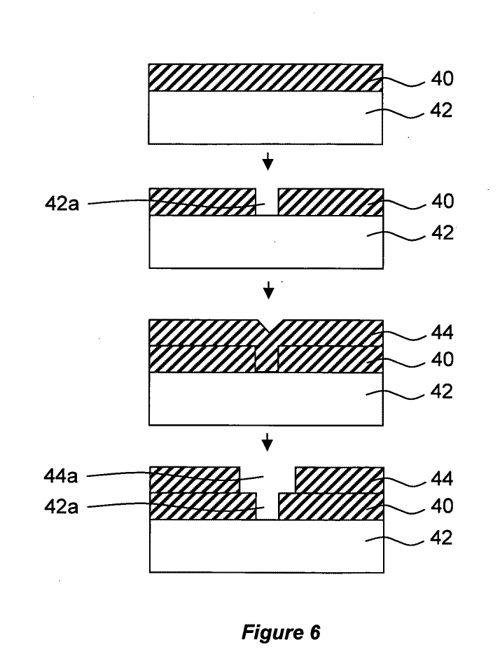

Owing to their “negative” behavior under exposure, the photopatternable dielectric materials of the present invention can also be applied to reduce the number of processing steps required to build a dielectric “dual damascene” structure. FIG. 6 illustrates one embodiment of this. First, the hybrid dielectric material is spun on or otherwise deposited as layer 42 on a substrate 40. Then, layer 42 is selectively exposed and developed to define a via 42a. Next, a “trench” layer 44 (also of the hybrid dielectric material of the invention) is deposited e.g., by spin on, exposed, and developed so as to form a trench 44a and reopen via 42a. No hard mask step or etch steps are required. Because of the negative developing characteristics of the material of the invention, the trench exposure needs no compensation to develop out the unexposed via area 44a filled by the material from trench layer 44.

In the above dual damascene example, either “via” layer 42 or “trench” layer 44, or both can be made of the hybrid, preferably photopatternable, material of the invention. Also, it is possible that though both layers 42 and 44 are hybrid materials of the invention, the hybrid material for layer 42 is different than the material for hybrid layer 44 (different inorganic backbone and/or organic groups discussed further below). Also, though a dual damascene example is illustrated in FIG. 6, a “single” damascene or other IC process could be performed—though preferably one that benefits from a photopatternable dielectric. Also, the dielectric materials of the present invention can be used in printed circuit board applications, similar to those discussed above for integrated circuit applications.

### Compounds:

In this section, compounds are described that can be hydrolyzed and condensed (alone or with one or more other compounds) into a hybrid material having a weight average molecular weight of from 500 to 100,000 g/mol. The weight average molecular weight can be in the lower end of this range (e.g., from 500 to 5,000, or more preferably 500 to 3,000) or the hybrid material can have a molecular weight in the upper end of this range (such as from 5,000 to 100,000 or from 10,000 to 50,000). It should be noted that all molecular weights disclosed in the present context and hereinafter are weight average molecular weights. In addition, it may be desirable to mix a hybrid material having a lower molecular weight with a hybrid material having a higher molecular weight. The hybrid material can be suitably deposited such as by spin-on, spray coating, dip coating, or the like. Such compounds are preferably partially or fully fluorinated, though not necessarily so. The compounds will preferably have an element M selected from groups 3-6 or 13-16 of the periodic table, which element is preferably tri-, tetra- or penta-valent, and more preferably tetravalent, such as those elements selected from group 14 of the periodic table. Connected to this element M are from three to five substituents, wherein from one to three of these substituents are organic groups to be discussed further below, with the remainder being a halogen or an alkoxy group.

Of particular interest are Compound Examples VIII and IX where three organic groups are bound to the metal or metalloid M group, which when hydrolyzed (fully or partially) with other Compound Examples herein (preferably those having one or two organic groups) allow for greater control of the process for making the dielectric material of the invention.

### Compound Example I

A compound is provided of the general formula: R¹MOR³₃, where R¹ is any partially or fully fluorinated organic group (preferably a partially or fully fluorinated aryl, alkenyl, alkynyl or alkyl group), where M is an element selected from column 14 of the periodic table, and where OR³ is an alkoxy group—except where M is Si, R¹ is perfluorinated phenyl or perfluorinated vinyl, and OR³ is ethoxy, which can be part of one of the novel methods for making the materials of the invention as will be discussed further below. R¹ can have an inorganic component, though if so, a portion should preferably be a partially or fully fluorinated organic component. In various embodiments, OR³ can have one to 12 carbons, one to 7 carbons, and more preferably one to five carbons, and the like. The carbon chain R can be linear, branched or cyclic. In a more preferred example of this, R¹ comprises a double bond that is capable of physical alteration or degradation in the presence of an electron beam, or electromagnetic radiation and a photoinitiator (or sensitizer, photoacid or thermal initiator- to be discussed further below). In this example, R¹ could be an alkenyl group such as a vinyl group, or could be an epoxy or acrylate group, that is preferably partially or fully fluorinated. Such a group, as will be discussed further herein, can allow for crosslinking upon application of an electron beam or preferably electromagnetic radiation (e.g., directing ultra-violet light through a mask with the material comprising a photoinitiator). In the alternative, R¹ could be an organic group that is (or a hybrid organic-inorganic group that comprises) a single or multi ring structure (an “aryl group”) or an alkyl group of any length, such as from 1 to 14 carbon atoms or longer (preferably 4-10)—the alkyl group capable of being a straight or branched chain. If R¹ is a ring structure, or a carbon chain of sufficient length (e.g., 4 (or 5) or more carbons), then such an R¹ group can provide bulk to the final material once hydrolyzed, condensed and deposited on a substrate. If R¹ is a ring structure, whether single ring or multi ring, it can have substituents thereon, fluorinated, though not necessarily, such as alkyl or alkenyl substituents (preferably from 1 to 5 carbons), and where the substituents on the ring structure can be at from 1 to 3 location around the ring. R¹ can be a 4 to 8 sided ring structure (preferably 5 or 6 sided) which ring structure could comprise N or O. R¹ could comprise nitrogen, or R¹ can also have an oxygen component, such as a carboxylate group (e.g., acrylate, butenecarboxylate, propenecarboxylate, etc.).

For purposes of this disclosure The term ‘alkenyl’ as used herein includes straight-chained and branched alkenyl groups, such as vinyl and allyl groups. The term ‘alkynyl’ as used herein includes straight-chained and branched alkynyl groups, suitably acetylene. ‘Aryl’ means a mono-, bi-, or more cyclic aromatic carbocyclic group; examples of aryl are phenyl and naphthyl. More specifically the alkyl, alkenyl or alkynyl may be linear or branched. Alkyl contains preferably 1 to 18, more preferably 1 to 14 and particularly preferred 1 to 12 carbon atoms. The alkyl is preferably branched at the alpha or beta position with one and more, preferably two, C1 to C6 alkyl groups, especially preferred per-fluorinated alkyl, alkenyl or alkynyl groups. Some examples are non-fluorinated, partially fluorinated and per-fluorinated i-propyl, t-butyl, but-2-yl, 2-methylbut-2-yl, and 1,2-dimethylbut-2-yl. Alkenyl contains preferably 2 to 18, more preferably 2 to 14 and particularly preferred 2 to 12 carbon atoms. The ethylenic, i.e., two carbon atoms bonded with double bond, group is preferably located at the position 2 or higher, related to the Si or M atom in the molecule. Branched alkenyl is preferably branched at the alpha or beta position with one and more, preferably two, C1 to C6 alkyl, alkenyl or alkynyl groups, particularly preferred per-fluorinated alkyl, alkenyl or alkynyl groups.

For purposes of this specification, alkynyl can preferably contains preferably 3 to 18, more preferably 3 to 14 and particularly preferred 3 to 12 carbon atoms. The ethylinic group, i.e., two carbon atoms bonded with triple bond, group is preferably located at the position 2 or higher, related to the Si or M atom in the molecule. Branched alkynyl is preferably branched at the alpha or beta position with one and more, preferably two, C1 to C6 alkyl, alkenyl or alkynyl groups, particularly preferred per-fluorinated alkyl, alkenyl or alkynyl groups.

Alkoxy, acyl, acyloxy herein have meanings that are understood by the persons skilled in the art, and include straight and branched chains.

In the context of this specification, the organic group substituent halogen may also be F, Cl, Br or I atom and is preferably F or Cl. Generally, term ‘halogen’ herein means a fluorine, chlorine, bromine or iodine atom.

In the example above, in R¹MOR³₃, M can be a tetravalent element from column 14 of the periodic table (e.g., Si or Ge), or a tetravalent element from column 16—e.g., Se (or a tetravalent early transition metal—such as titanium or zirconium). Also, OR³ is an alkoxy group, though preferably one having from 1 to 4 carbon atoms (longer alkoxy groups can be used, but are more expensive).

Specific examples include:

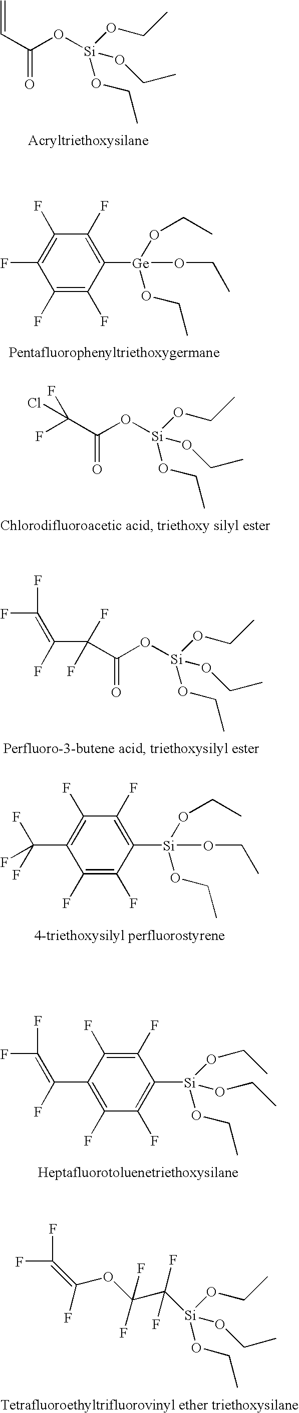

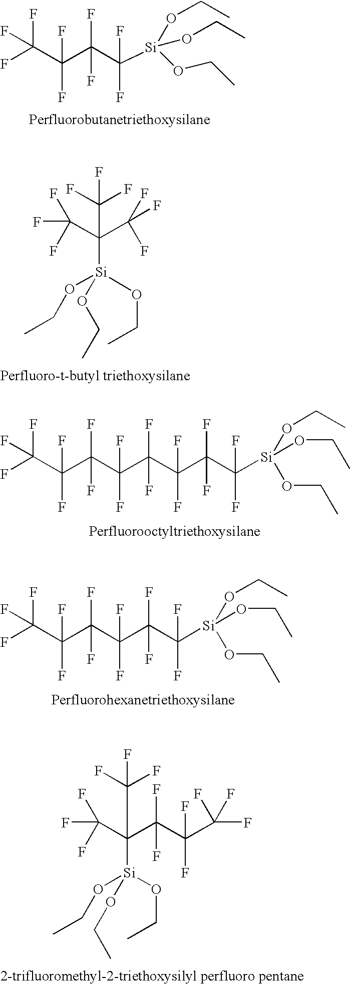

Precursors for the above compositions are available from, Gelest, Inc., Tullytown, Pa., Sigma-Aldrich, Stockholm, Sweden and ABCR Gmbh & Co., Karlsruhe, Germany. It will be appreciated that precursors for the compositions listed below are also commercially available from these sources.

### Compound Example II

In yet another compound example, a compound is provided of the general formula: R¹MOR³₂X, where R¹ is any partially or fully fluorinated organic group (preferably a partially or fully fluorinated aryl, alkenyl, alkynyl or alkyl group) as set forth above, where M is an element selected from group 14 of the periodic table as mentioned above, where X is a halogen, and where OR³ is an alkoxy group as above. X in this example is preferably F, Cl, Br or I, and more preferably Cl or Br. Specific examples of compounds within this category include

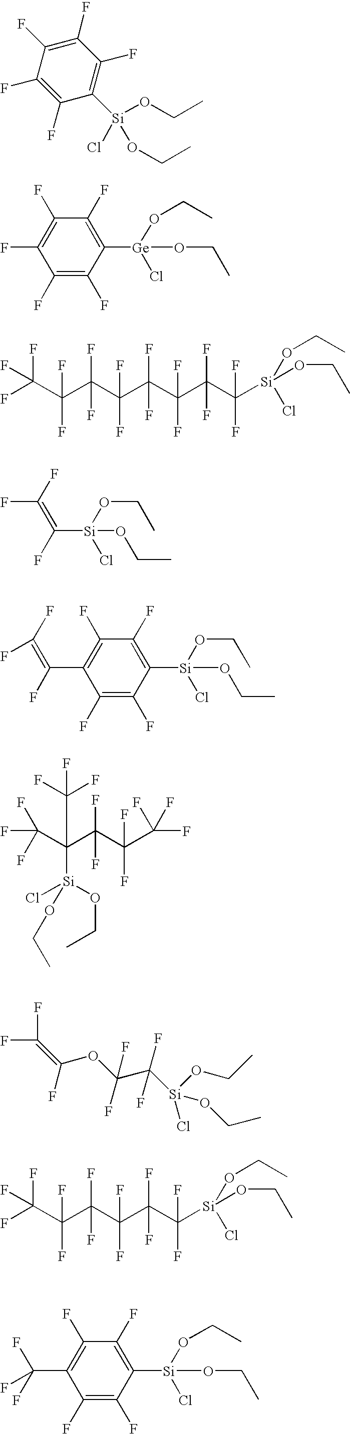

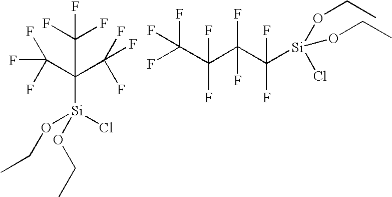

### Compound Example III

In another compound example, a compound is provided of the general formula: R¹MX₂OR³, where R¹ is any partially or fully fluorinated organic group (preferably a partially or fully fluorinated aryl, alkenyl, alkynyl or alkyl group) as set forth above, where M is an element selected from group 14 of the periodic table as mentioned above, where OR³ is an alkoxy group as above, and where X is a halogen as above—Except where M is Si, R¹ is perfluorinated phenyl, X is Cl, and OR³ is ethoxy, which, though not novel per se, is novel when used as part of the methods for making the materials of the invention as will be discussed further below. Specific examples within this category include

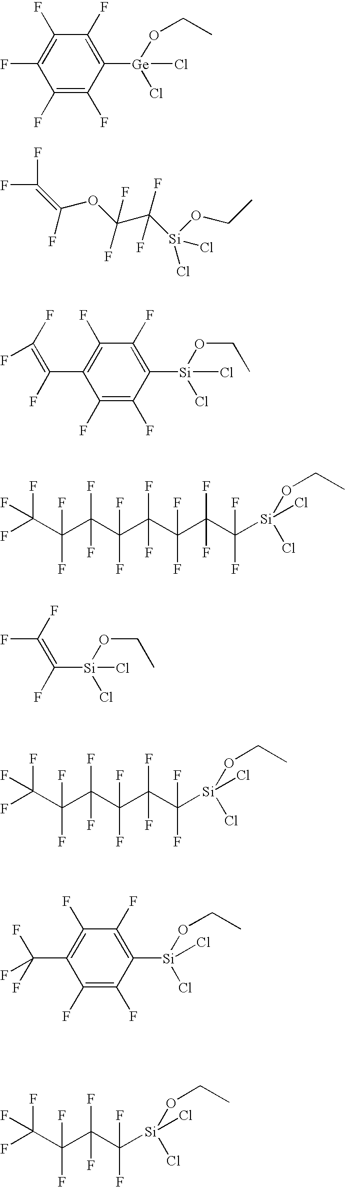

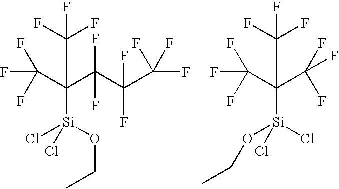

### Compound Example IV

In a further compound example, a compound is provided of the general formula: R¹MX³, where R¹ is any partially or fully fluorinated organic group (preferably a partially or fully fluorinated aryl, alkenyl, alkynyl or alkyl group) as set forth above, where M is an element selected from group 14 of the periodic table as mentioned above, and where X is a halogen as above—Except where M is Si, R¹ is perfluorinated phenyl, perfluorinated methyl or perfluorinated vinyl, and X is Cl, which, though not novel per se, are novel when used as part of the methods for making the materials of the invention as will be discussed further below. (If M is Si and X is Cl, some of these novel trichlorosilanes could be used for forming self assembled monolayers for making a surface hydro-phobic, preferably by application in the vapor phase to a surface made of silicon and having OH end groups and moisture.) Specific examples within this category include:

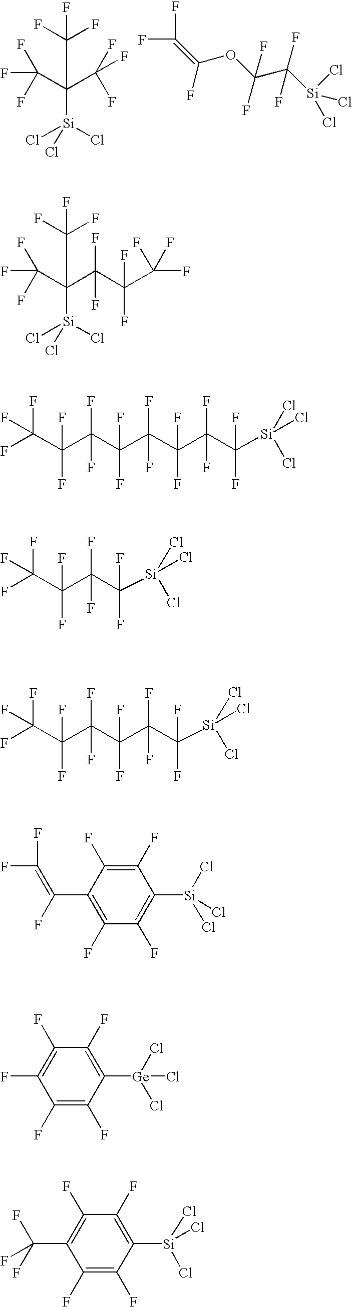

### Compound Example V

In yet another compound example, a compound is provided of the general formula: R¹R²MOR³₂, where R¹ is any partially or fully fluorinated organic group (preferably a partially or fully fluorinated aryl, alkenyl, alkynyl or alkyl group) as set forth above with respect to R¹, R² is any partially or fully fluorinated organic group (preferably a partially or fully fluorinated aryl, alkenyl, alkynyl or alkyl group) as set forth above with respect to R¹, or any such organic groups nonfluorinated, and where R¹ and R² are the same or different from each other, where M is an element selected from group 14 of the periodic table as mentioned above, and where OR³ is an alkoxy group as above—except where M is Si, OR³ is ethoxy and R¹ and R² are perfluorinated phenyl groups, which compound is not novel per se, but is novel when used as part of the methods for making materials of the invention as set forth below. Specific examples within this category include:

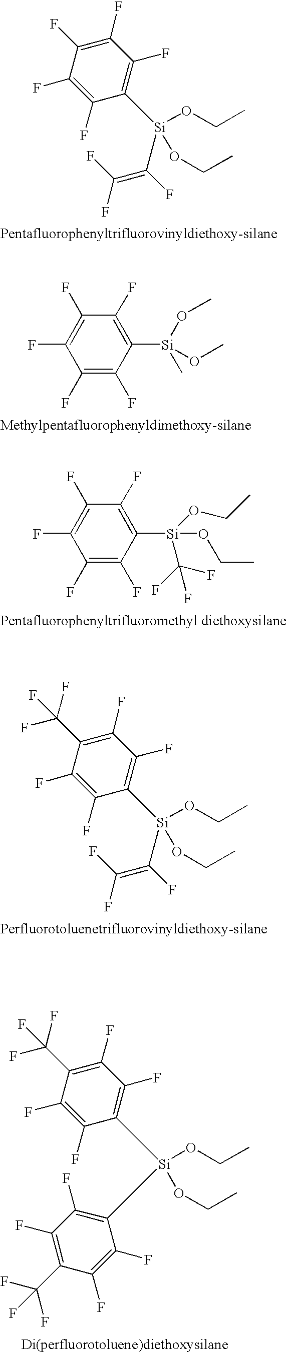

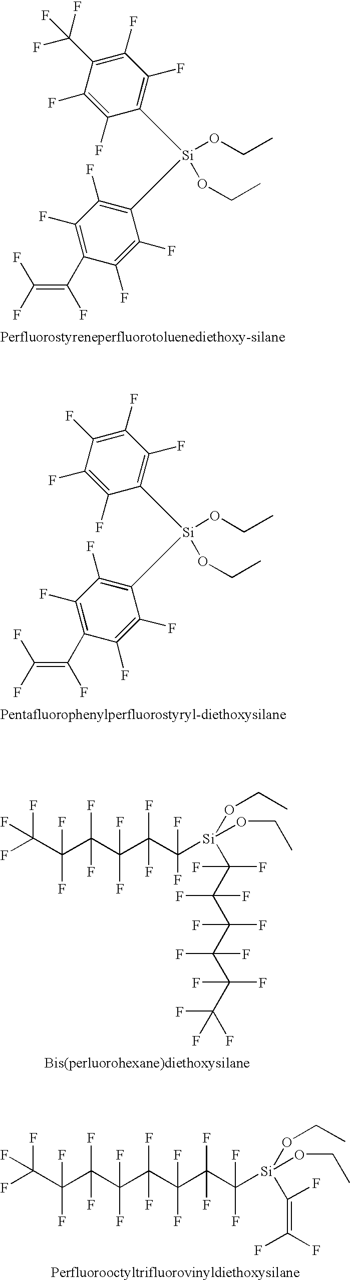

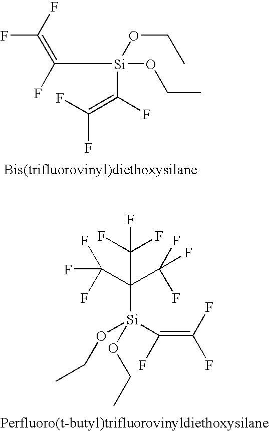

### Compound Example VI

In another compound example, a compound is provided of the general formula: R¹R²MXOR³, where R¹ is any partially or fully fluorinated organic group (preferably a partially or fully fluorinated aryl, alkenyl, alkynyl or alkyl group) as set forth above with respect to R¹, R² is any partially or fully fluorinated organic group (preferably a partially or fully fluorinated aryl, alkenyl, alkynyl or alkyl group) as set forth above with respect to R¹, or any such organic groups nonfluorinated, and where R¹ and R² are the same or different from each other, where M is an element selected from group 14 of the periodic table as mentioned above, where OR³ is an alkoxy group as above, and where X is a halogen. R¹ and R² can be the same or different from each other. Specific examples within this category include:

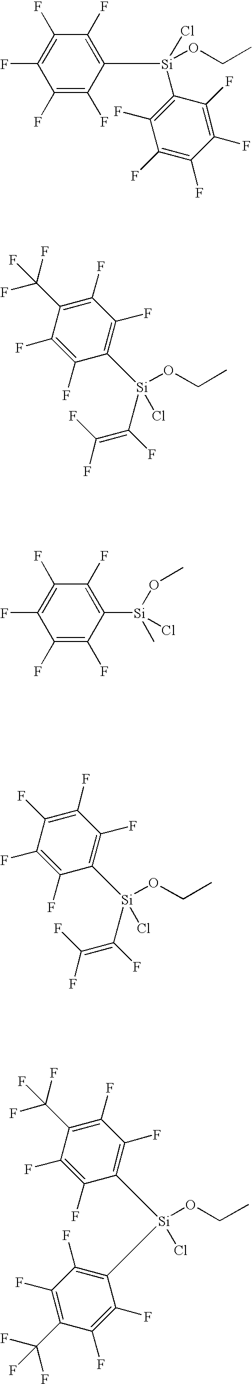

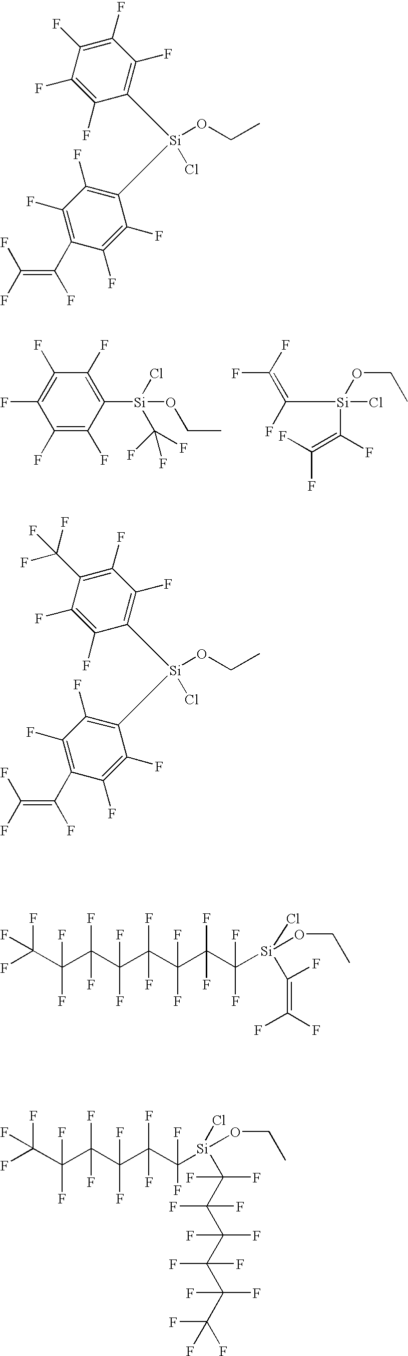

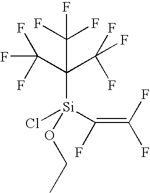

### Compound Example VII

In a further compound example, a compound is provided of the general formula: R¹R²MX₂, where R¹ is any partially or fully fluorinated organic group (preferably a partially or fully fluorinated aryl, alkenyl, alkynyl or alkyl group) as set forth above with respect to R¹, R² is any partially or fully fluorinated organic group (preferably a partially or fully fluorinated aryl, alkenyl, alkynyl or alkyl group) as set forth above with respect to R¹, or any such organic groups nonfluorinated, and where R¹ and R² are the same or different from each other, where M is an element selected from group 14 of the periodic table as mentioned above, and where X is a halogen as above—Except where M is Si, R¹ and R² are perfluorinated phenyl, and X is Cl, which, though not novel per se, is novel when used as part of the methods for making the materials of the invention as will be discussed further below. Specific examples within this category include:

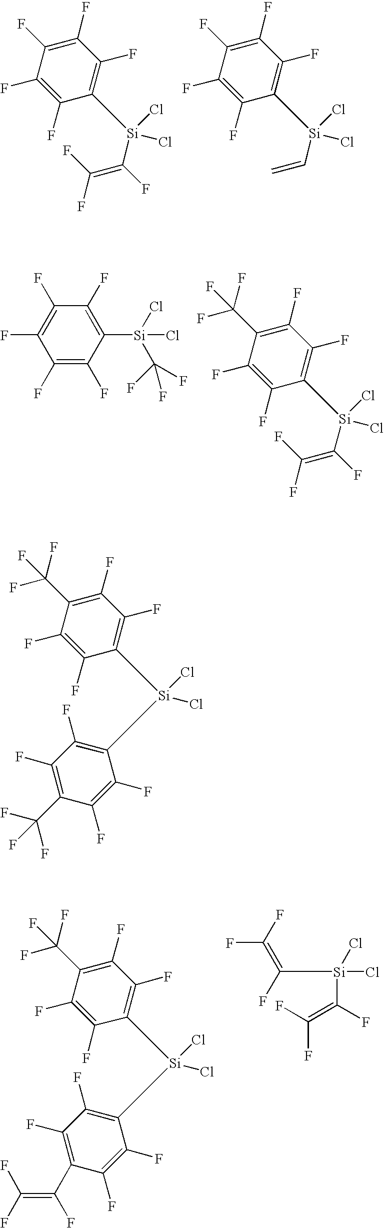

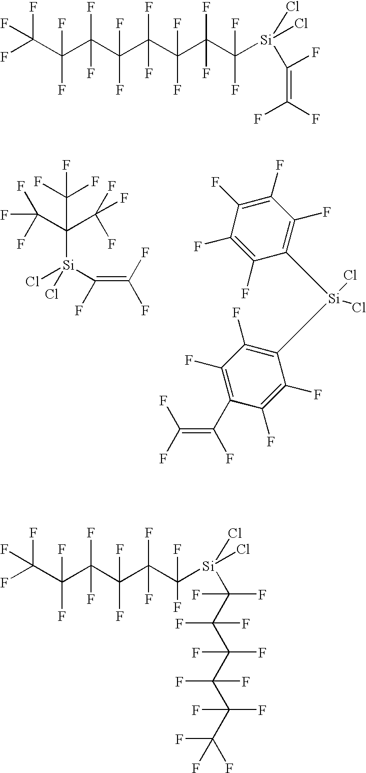

As Compounds V-VII have two organic groups, they can be formed by various combinations of Methods A, B and/or C (described in further detail below).

### Compound VIII

In a further compound example, a compound is provided of the general formula: R¹R²R³MOR³, where R¹, R² and R³ are independently an aryl, alkenyl, alkynyl or alkyl group) as set forth above with respect to R¹ and R², and where R¹, R² and R³ can each be the same or different from each other (and preferably at least one of where R¹, R² and R³ is partially or fully fluorinated), where M is preferably an element selected from group 14 of the periodic table as above, and where OR³ is an alkoxy group as above. One example is

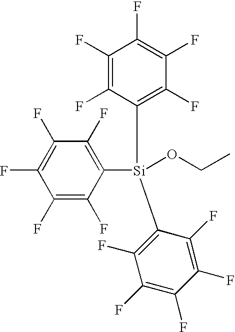

though the organic groups need not each be the same as in this example, and need not each be fluorinated (though preferably at least one of the organic groups is fluorinated).

### Compound IX

In another compound example, a compound is provided of the general formula: R¹R²R³MX, where R¹, R² and R³ are independently an aryl, alkenyl, alkynyl or alkyl group) as set forth above with respect to R¹ and R², and where R¹, R² and R³ can each be the same or different from each other (and preferably at least one of where R¹, R² and R³ is partially or fully fluorinated), where M is preferably an element selected from group 14 of the periodic table as above, and where X is a halogen as above. One example is:

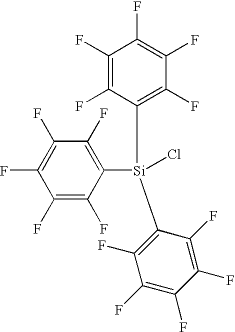

As Compounds VIII and IX have three organic groups, they can be formed by various combinations of Methods A, B and/or C (which methods are described in further detail below).

### Other Compounds:

Additional compounds for making the materials of the invention include those having the general formula R¹MHX₂ where R¹, M and X are as above and H is hydrogen. One example is:

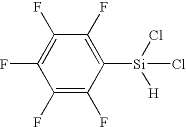

Other examples, where the fluorinated phenyl group is replaced with a substituted phenyl, fluorinated alkyl, vinyl, etc. are possible.

It should be noted that M in the compound formula examples above need not be tetravalent. M can also have other valencies, though preferably tri- or penta-valent. Examples would include early transition metals in group 3 or 5 of the periodic table (e.g., Y, V or Ta), or elements in columns 13 (column headed by B) or 15 (column headed by N), such as B, Al or As. In such situations, the compounds above would have one fewer or one additional alkoxy (OR³), halogen (X) or an organic group (R¹ or R² independently from the other organic group(s)). Examples include R¹MOR³X, R¹MOR³₂, R¹MX₂, R¹R²MX, R¹R²MOR³, where M is a trivalent early transition metal (or similar examples with five substituents selected from R¹ and/or R² groups, as well as alkoxy and halogens for pentavalent elements (including metalloids or transition metals). Such compounds could have the formula R¹₃₋ₘMOR³ₘ, R¹₅₋ₘMOR³ₘ, R²R¹₄₋ₘMOR³ₘ or R²R¹₄₋ₘMOR³ₘ. If such tri- or penta-valent elements are used, such a compound would preferably be hydrolyzed and condensed as a dopant, rather than as the main portion of the material at the time of hydrolysis and condensation (likewise with non-silicon tetravalent elements that form compounds in accordance with the tetravalent examples above, such as germanium compounds).

It should also be noted that the structures illustrated above are exemplary only, as other ring structures (3 sided—e.g., epoxy, or 4 to 8 sided—preferably 5 or 6 sided) are possible, which structures can include nitrogen or oxygen in or bound the ring. The aryl group can have from 1 to 3 substituents, such as one or more methyl, ethyl, ally, vinyl or other substituents—that can be fluorinated or not. Also, carbon chain R groups can include oxygen (e.g., carboxylate) or nitrogen or sulfur. If an alkyl group is bound to the silicon (or other M group), it can have from 1 to 4 carbons (e.g., a C2+ straight or C3+ branched chain), or up to 14 carbons (or more)—if used as a bulk enhancing group for later hydrolysis and deposition, 4 or more carbons are preferable. These aryl groups can be fully or partially fluorinated, as can alkenyl or alkynyl groups if used.

### Methods of Making the Compounds for Later Hydrolysis and Condensation:

In a number of the following examples of methods for making the materials of the invention, “M” is silicon, OR³ is ethoxy, and X is Cl. However, as noted above, other alkoxy groups could easily be used (methoxy, propoxy, etc.), and other group 3-5 or 13-16 elements could be used in place of silicon and other halogens in place of chlorine. Starting materials can vary from tetraethoxy silane, to ethoxy silanes having one or more organic groups bound to the silicon, to chorosilanes having one or more chlorine groups and/or one or more organic groups, as well as starting materials having chlorine and alkoxy groups and with one or more organic groups. Any compound examples within Compounds I-IX above could be used as starting materials—or could be intermediate or final compounds as will be seen below. For example, trifluorovinyltriethoxysilane could be a final compound resulting from reacting a particular trifluorovinyl compound with tetraethoxysilane, or trifluorovinylsilane could be a starting material that, when reacted with a particular pentafluorophenyl compound, results in penta-fluorophenyltrifluorovinyldiethoxysilane. As mentioned above, it is also preferred that any organic groups that are part of the starting material or are “added” by chemical reaction to become part of the compound as set forth below, are partially or fully fluorinated (or fully or partially deuterated), though such is not necessary as will also be seen below.

One example of a method for making the materials of the present invention comprises providing a compound R¹_{4-q}MOR³_{q} where M is selected from group 14 of the periodic table, OR³ is an alkoxy group, R¹ is an alkyl, alkenyl, aryl or alkynyl, and q is from 2 to 4; reacting the compound R¹_{4-g}MOR³_{q} with either a) Mg and R²X² where X² is Cl, Br or I and R² is an alkyl, alkenyl, aryl or alkynyl group, or b) reacting with R²X¹ where R² is an alkyl, alkenyl, aryl or alkynyl group and wherein R² is fully or partially fluorinated or deuterated and X¹ is an element from group 1 of the periodic table; so as to replace one of the OR³ groups in R¹_{4-q}MOR³_{q} so as to form R¹_{4-q}R²MOR³_{q-1.}

The starting material preferably has 1 or 2 (or no) organic groups (R¹) bound to the group 14 element “M”, which organic groups may or may not comprise fluorine, with the remaining groups bound to M being alkoxy groups. An additional preferably fluorinated (partially of fully) organic group becomes bound to the group 14 element by one of a number of reactions. One method (Method A) involves reacting the starting material with magnesium and a compound having the desired organic group (R²) bound to a halogen X² (preferably Cl, Br or I)—namely R²X2, which reaction replaces one of the alkoxy groups with the organic group R². In the above example, a single alkoxy group is replaced, however, depending upon the molar ratios of starting material to R²X² and Mg, more than one alkoxy group can be replaced with an R² organic group. In one example of the above, a tetraethoxysilane, MOR³₄ is reacted with a compound R²X² where R² is a preferably fluorinated alkyl, aryl, alkenyl or alkynyl group and X² is preferably Br or I, so as to form R²MOR³₃. In another example, R¹MOR³₃ is reacted with R²X² so as to form R¹R²MOR³₂. This group of reactions can be referred to as: reacting the starting material R¹₄ MOR³_{q} with R²X² where R² is a preferably fluorinated alkyl, aryl, alkenyl or alkynyl group and X² is preferably Br or I, so as to form R¹_{4-q}R²MOR³_{q-1}.

This method A can be described as a method comprising reacting a compound of the general formula R¹₄₋ₘMOR³ₘ, wherein m is an integer from 2 to 4, OR³ is an alkoxy, and M is an element selected from group 14 of the periodic table; with a compound of the general formula R²X²+Mg, wherein X² is Br or I, where R¹ and R² are independently selected from alkyl, alkenyl, aryl or alkynyl, and wherein at least one of R¹ and R² is partially or fully fluorinated, so as to make a compound of the general formula R²MR¹₃₋ₙOR³ₙ, wherein n is an integer from 1 to 3.

An alternate to the above method (Method B) is to react the same starting materials (R¹_{4-q}MOR³_{q}) with a compound R²X¹ where, as above, R² is an alkyl, alkenyl, aryl or alkynyl group and wherein R² is fully or partially fluorinated or deuterated and X¹ is an element from group 1 of the periodic table; so as to replace an OR³ group in R¹_{4-q}MOR³_{q} to form R¹_{4-q}R²MOR³_{q-1}. In this example, X¹ is an element from group 1 of the periodic table, and is preferably Na, Li or K (more preferably Na or Li). In one example of the above, a tetraethoxysilane, MOR³₄ is reacted with a compound R²X¹ where R² is a preferably fluorinated alkyl, aryl, alkenyl or alkynyl group and X¹ is preferably an element from group I of the periodic table, so as to form R²MOR³₃. In another example, R¹ MOR³₃ is reacted with R²X¹ so as to form R¹R²MOR³₂.

This method B can be described as a method comprising reacting a compound of the general formula R¹₄₋ₘMOR³ₘ wherein m is an integer from 2 to 4, R¹ is selected from alkyl, alkenyl, aryl, or alkyl, alkenyl or aryl, and wherein R¹ is nonfluorinated, or fully or partially fluorinated, OR³ is alkoxy, and M is an element selected from group 14 of the periodic table; with a compound of the general formula R²M1, wherein R² is selected from alkyl, alkenyl, aryl, alkynyl, and wherein R² is at least partially fluorinated; and M1 is an element from group I of the periodic table; so as to make a compound of the general formula R¹₄₋ₘMOR³ₘ₋₁R².

A modification (Method C) of the aforementioned (Method B), is to react the starting material (R¹_{4-q}MOR³_{q}) with a halogen or halogen compound so as to replace one or more of the OR³ groups with a halogen due to reaction with the halogen or halogen compound. The halogen or halogen compound can be any suitable material such as hydrobromic acid, thionylbromide, hydrochloric acid, chlorine, bromine, thionylchloride or sulfurylchloride and the like. Depending upon the ratio of halogen or halogen compound to starting material (and other parameters such as reaction time and/or temperature), one or more alkoxy groups can be replaced by a halogen—though in most examples, a single alkoxy group or all alkoxy groups will be replaced. If a single alkoxy group is replaced, then the starting material R¹_{4-q}MOR³_{q} becomes

R¹_{4-q}MOR³_{q-1}X³ where X³ is a halogen from the halogen or halogen compound reacted with the starting material (or simply begin with starting material
R¹_{4-q}MOR³_{q-1}X³). If all alkoxy groups are replaced due to the reaction with the halogen or halogen compound, then the starting material R¹_{4-q}MOR³_{q} becomes R¹_{4-q}MX³q. Then, as mentioned for Method B above, either starting material R¹_{4-q}MOR³_{q-1}X³ or R¹_{4-q}MX³q is reacted with a compound R²X¹ where R² is a preferably fluorinated alkyl, aryl, alkenyl or alkynyl group and X¹ is preferably an element from group I of the periodic table, so as to form R¹_{4-q}R²MOR³_{q-1},
R¹_{4-q}R²MX³_{q-1} (or even R¹_{4-q}R²₂MX³_{q-2} depending upon reaction conditions). A reaction with R¹_{4-q}MOR³_{q-1}X³ is preferred due to greater ease of control of the reaction.

This Method C can be described as a method comprising reacting a compound of the general formula X³MOR³₃, where X³ is a halogen, M is an element selected from group 14 of the periodic table, and OR³ is alkoxy; with a compound of the general formula R¹M1; where R¹ is selected from alkyl, alkenyl, aryl and alkynyl and wherein R¹ is partially or fully fluorinated; and M1 is an element from group I of the periodic table; so as to form a compound of the general formula R¹MOR3₃.

Related Methods B and C can be described as a single method comprising reacting a compound of the general formula R¹₄₋ₘMOR³ₘ₋ₙXₙ wherein m is an integer from 2 to 4, and n is an integer from 0 to 2, R¹ is selected from alkyl, alkenyl, aryl, or alkyl, alkenyl or aryl, and wherein R¹ is nonfluorinated, or fully or partially fluorinated; OR³ is alkoxy, and M is an element selected from group 14 of the periodic table; with a compound of the general formula R²M1, wherein R² is selected from alkyl, alkenyl, aryl, alkynyl, and wherein R² is at least partially fluorinated, and M1 is an element from group I of the periodic table; so as to make a compound of the general formula R²MR¹₄₋ₘOR³ₘ₋ₙXₙ₋₁.

Of course, as will be seen below, the above starting materials in the method examples set forth above are only examples, as many other starting materials could be used. For example, the starting material could be a halide rather than an alkoxide (e.g., a mono-, di- or trichlorosilanes) or another material having both alkoxy and halogens on the group 14 element, along with 0, 1 or even 2 organic groups (alkyl, alkenyl, aryl, alkynyl) also bound to the group 14 element. Though the methods for making the materials of the invention preferably use starting materials having the group 14 element set forth above, many different combinations of alkoxy groups, halogens, and organic groups (alkyl, alkenyl, etc.) can be bound to the group 14 element. And, of course, such starting materials can be commercially available starting materials or can be made from other available starting materials (in which case such materials are intermediate compounds in the methods for making the materials of the invention).

In addition, the methods for making the materials of the invention include, a method for forming a final compound could include Methods A, B and/or C above. For example, one organic group, preferably fluorinated, could become bound to the group 14 element M by Method A followed by binding a second organic group, preferably fluorinated, to the group 14 element M by Method B. Or, Method B could be performed first, followed by Method A—or Method C could be performed in combination with Methods A and/or B, etc. And, of course, any particular reaction (binding of an organic group to M) could be performed only once by a particular reaction, or multiple times (binding of multiple organic groups, the same or different from each other) by repeating the same reaction (a, b or c) multiple times. Many combinations of these various reactions and starting materials are possible. Furthermore, any of the methods or method combinations could include any of a number of additional steps including preparation of the starting material, replacing one or more alkoxy groups of the final compound with halogens, purifying the final compound, hydrolysis and condensation of the final compound (as will be described further below), etc.

### Example 1

### Making a Compound I Via Method B

CF₂═CF—Cl+sec/tert-BuLi→CF₂═CF—Li+BuCl

CF₂═CF—Li+Si(OEt)₄→CF₂═CF—Si(OEt)₃+EtOLi

200 ml of freshly distilled dry Et₂O is added to a 500 ml vessel (under an argon atmosphere). The vessel is cooled down to −80° C. and 15 g (0.129 mol) of CF₂═CFCl gas is bubbled to Et₂O. 100 ml (0.13 mol) of sec-BuLi is added dropwise during three hours. The temperature of the solution is kept below −60° C. all the time. The solution is stirred for 15 minutes and 29 ml (27.08 g, 0.130 mol) of Si(OEt)₄ is added in small portions. The solution is stirred for over night allowing it to warm up to room temperature. Formed red solution is filtered and evaporated to dryness to result crude trifluorovinyltriethoxysilane, CF₂═CFSi(OEt)₃.

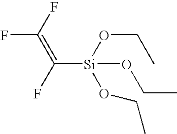

### Example 2

### Making a Compound I Via Method C

CF₂═CF—Li+ClSi(OEt)₃→CF₂═CF—Si(OEt)₃+LiCl

CF₂═CFSi(OEt)₃ is also formed when 30.80 g (0.155 mol) ClSi(OEt)₃ in Et₂O is slowly added to solution of CF₂═CF—Li (0.155 mol, 13.633 g, prepared in situ) in Et₂O at −78° C. Reaction mixture is stirred overnight allowing it slowly warm to room temperature. LiCl is removed by filtration and solution evaporated to dryness to result yellow liquid, crude trifluorovinyltriethoxysilane.

### Example 3

### Making a Compound IV Via Method B or C

Follow steps in Example 1 or 2 above, followed by

CF₂═CF—Si(OEt)₃+excess SOCl₂+py.HCl→CF₂═CF—SiCl₃+3SO₂+3EtCl

24.4 g (0.100 mol) crude trifluorovinyltriethoxysilane, 44 mL (0.60 mol, 71.4 g) thionylchloride and 1.1 g (0.0045 mol) pyridinium hydrochloride are refluxed and stirred for 24 h. Excess of SOCl₂ is evaporated and trifluorovinyl-trichlorosilane

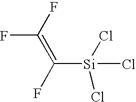

is purified by distillation.

### Example 4

### Making a Compound I Via Method A

C₇F₇Br+Mg+excess Si(OEt)₄→C₇F₇Si(OEt)₃

250 g (0.8418 mol) heptafluorobromotoluene, 22.69 g (0.933 mol) magnesium powder, small amount of iodine (15 crystals) and 750 mL (3.3672 mol, 701.49 g) tetraethoxysilane are mixed together at room temperature and diethylether is added dropwise to the vigorously stirred solution until an exothermic reaction is observed (˜250 mL). After stirring at room temperature for 16 h diethylether is evaporated. An excess of n-heptane (˜600 mL) is added to precipitate the magnesium salts. Solution is filtrated and evaporated to dryness. The residue is fractionally distilled under reduced pressure to yield heptafluorotoluenetriethoxysilane.

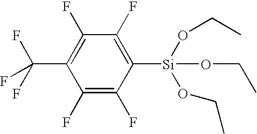

### Example 5

### Making a Compound IV Via Method A

Follow the steps in Example 4, followed by

C₇F₇Si(OEt)₃+6SOCl₂+py.HCl→C₇F₇SiCl₃ 2.

where 114.1 g (0.300 mol) heptafluorotoluenetriethoxysilane, 131 mL (1.800 mol, 214.1 g) thionylchloride and 4.51 g (0.039 mol) pyridinium hydrochloride are refluxed and stirred for 16 h. Excess of SOCl₂ is evaporated and perfluorotoluenetrichlorosilane

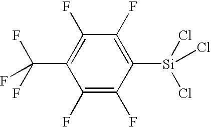

isolated by vacuum-distillation.

### Example 6

### Making a Compound III Via Method A

Follow same steps as in Example 5, except isolate (by vacuum distillation at the end), perfluorotoluenedichloroethoxysilane, CF₃—C₆F₄—Si(OEt)Cl₂

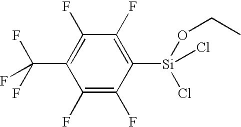

### Example 7

### Making a Compound V from a Compound I or II Via Method C

C₆F₅Si(OEt)₃+SOCl₂+py.HCl→C₆F₅Si(OEt)₂Cl+EtCl 1.

C₆F₅Si(OEt)₂Cl+CF₂═CFLi→C₆F₅(CF₂═CF)Si(OEt)₂ 2.

C₆F₅(CF₂═CF)Si(OEt)₂+excess SOCl₂+py.HCl→C₆F₅(CF₂═CF)SiCl₂ 3.

152.0 g (0.460 mol) pentafluorophenyltriethoxysilane, 34 mL (0.460 mol, 54.724 g) thionylchloride and 6.910 g (0.0598 mol) pyridinium hydrochloride are refluxed and stirred for 18 h. Pyridinium hydrochloride is precipitated at −78° C. and the solution is filtrated. Pentafluorophenylchlorodiethoxysilane

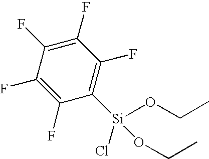

is isolated by vacuum distillation.

Then 49.712 g (0.155 mol) pentafluorophenylchlorodiethoxysilane, C₆F₅SiCl(OEt)₂, in Et₂O is slowly added to solution of CF₂═CF—Li (0.155 mol, 13.633 g, prepared in situ) in Et₂O at −78° C. Reaction mixture is stirred overnight while it will slowly warm to room temperature. LiCl is removed by filtration and the product, pentafluorophenyltrifluorovinyldiethoxysilane,

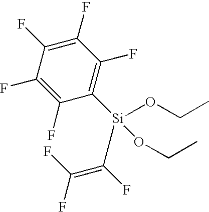

purified by distillation.

### Example 8

### Making a Compound VII from a Compound I or II Via Method C

Follow the steps above for Example 7, and then
12.1 g (0.0328 mol) pentafluorophenyltrifluorovinyldiethoxysilane, 12 mL (0.1638 mol, 19.487 g) thionylchloride and 0.50 g (0.0043 mol) pyridinium hydrochloride are refluxed and stirred for 24 h. Excess of SOCl₂ is evaporated and residue is fractionally distilled under reduced pressure to yield a mixture of 80% pentafluorophenyl-trifluorovinyldichlorosilane.

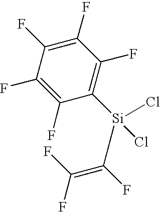

### Example 9

### Making a Compound I Via Method A

C₆F₅Br+Mg+2Ge(OEt)₄→C₆F₅Ge(OEt)₃

61.5 mL (0.4944 mol, 122.095 g) pentafluorobromobenzene, 13.22 g (0.5438 mol) magnesium powder and 250.00 g (0.9888 mol) tetraethoxygermane are mixed together at room temperature and diethylether is added dropwise to the vigorously stirred solution until an exothermic reaction is observed (˜400 mL). After stirring at 35° C. for 16 h the mixture is cooled to room temperature and diethylether evaporated. An excess of n-heptane (˜400 mL) is added to precipitate the magnesium salts. Solution is filtrated and evaporated to dryness. The residue is fractionally distilled under reduced pressure to yield pentafluorophenyl-triethoxygermane.

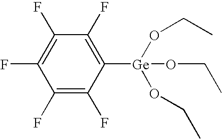

### Example 10

### Making a Compound IV Via Method A

Follow the steps in Example 9, then:

50 g (0.133 mol) pentafluorophenyltriethoxygermane, 58 mL (0.80 mol, 95.2 g) thionylchloride and 1.97 g (0.017 mol) pyridinium hydrochloride are refluxed and stirred for 24 h. Excess of SOCl₂ is evaporated and pentafluorophenyltrichlorogermane isolated by vacuum distillation.

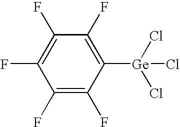

### Example 11

### Making a Compound I Via Method A

C₁₀F₇Br+Mg+excess Si(OEt)₄→CioF₇Si(OEt)₃

166.5 g (0.50 mol) 2-bromoperfluoronaphthalene, 13.37 g (0.55 mol) magnesium powder and 448.0 mL (2.00 mol, 416.659 g) tetraethoxysilane are mixed together at room temperature and diethylether is added drop-wise to the vigorously stirred solution until an exothermic reaction is observed (˜200 mL). After stirring at 35° C. for 16 h the mixture is cooled to room temperature and diethylether evaporated. An excess of n-heptane (˜400 mL) is added to precipitate the magnesium salts. Solution is filtrated and evaporated to dryness. The residue is fractionally distilled under reduced pressure to yield perfluoronaphthalenetriethoxysilane.

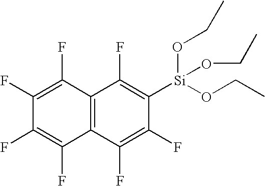

### Example 12

### Making a Compound IV Via Method A

Follow the steps in Example 11, then

100 g (0.240 mol) perfluoronaphthalenetriethoxysilane, 105.2 mL (1.442 mol, 171.55 g) thionylchloride and 3.54 g (0.0306 mol) pyridinium hydrochloride are refluxed and stirred for 24 h. Excess of SOCl₂ is evaporated and perfluoronaphthalenetrichlorosilane isolated by vacuum distillation.

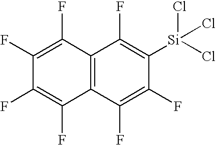

### Example 13

### Making Compound V Via Method A

C₆F₅Br+Mg+4MeSi(OMe)₃→C₆F₅(Me)Si(OMe)₂

57.9 mL (0.465 mol, 114.726 g) bromopentafluorobenzene, 12.42 g (0.511 mol) magnesium powder and 265 mL (1.858 mol, 253.128 g) methyltrimethoxysilane are mixed together at room temperature and diethylether is added dropwise to the vigorously stirred solution until an exothermic reaction is observed (˜320 mL). After stirring at 45° C. for 16 h the mixture is cooled to room temperature and diethylether evaporated. An excess of n-heptane (˜300 mL) is added to precipitate the magnesium salts. Solution is filtrated and evaporated to dryness. The residue, methyl(pentafluorophenyl)-dimethoxysilane, is used without further purification.

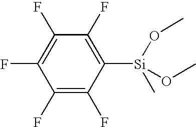

### Example 14

### Making Compound VII Via Method A

Follow steps in Example 13, then

81.68 g (0.300 mol) methyl(pentafluorophenyl)dimethoxysilane, 109 mL (1.50 mol, 178.4 g) thionylchloride and 3.69 g (0.0319 mol) pyridinium hydrochloride are refluxed and stirred for 16 h. Excess of SOCl₂ is evaporated and methyl(pentafluorophenyl)dichlorosilane isolated by vacuum-distillation.

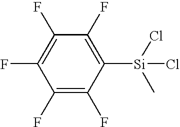

### Example 15

### Making a Compound V Via Method A

2C₆F₅Br+2Mg+Si(OEt)₄→(C₆F₅)₂Si(OEt)₂

265.2 mL (1.95 mol, 525.353 g) bromopentafluorobenzene, 52.11 g (2.144 mol) magnesium powder and 216 mL (0.975 mol, 203.025 g) tetraethoxysilane are mixed together at room temperature and diethylether is added dropwise to the vigorously stirred solution until an exothermic reaction is observed (˜240 mL). The solution is stirred for 30 minutes after which additional 90 mL of Et₂O is carefully added. After stirring at 35° C. for 16 h the mixture is cooled to room temperature and diethylether evaporated. An excess of n-heptane (˜600 mL) is added to precipitate the magnesium salts. Solution is filtrated and evaporated to dryness. The residue is fractionally distilled under reduced pressure to yield di(pentafluorophenyl)diethoxysilane.

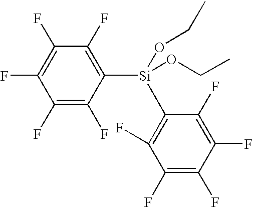

### Example 16

### Making a Compound V Via Method C

C₆F₅Cl+sec-BuLi→C₆F₅Li+sec-BuCl

C₆F₅Li+C₆F₅Si(OEt)₂Cl→(C₆F₅)₂Si(OEt)₂+LiCl

39.52 g (0.195 mol) chloropentafluorobenzene is weighed to a 1000 mL vessel and 250 mL Et₂O is added. The vessel is cooled down to −70° C. and 150 mL (0.195 mol) of sec-BuLi (1.3 M) is added dropwise during one hour. The temperature of the solution is kept below −50° C. all the time. The solution is stirred for 30 minutes and 62.54 g (0.195 mol) of diethoxychloropentafluorophenylsilane in Et₂O (100 mL) is added in small portions. The solution is stirred for over night allowing it to warm up to room temperature. Formed clear solution is filtered and evaporated to dryness to result di(pentafluorophenyl)diethoxysilane, (C₆F₅)₂Si(OEt)₂.

### Example 17

### Making a Compound VII Via Method A or C

Follow the steps in Example 15 or Example 16, then:

(C₆F₅)₂Si(OEt)₂+SOCl₂+py.HCl→(C₆F₅)₂SiCl₂

180.93 g (0.400 mol) di(pentafluorophenyl)diethoxysilane, 146 mL (2.00 mol, 237.9 g) thionylchloride and 4.92 g (0.0426 mol) pyridinium hydrochloride are refluxed and stirred for 16 h. Excess of SOCl₂ is evaporated and di(pentafluorophenyl)dichlorosilane isolated by vacuum-distillation.

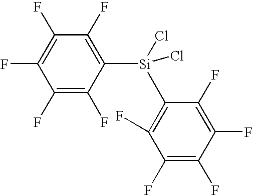

### Example 18

### Making an “Other Compound” Via Method A

C₆F₅MgBr+HSiCl₃→C₆F₅(H)SiCl₂

600.0 mL (0.300 mol) pentafluorophenyl magnesiumbromide (0.5 M sol. in Et₂O) is added dropwise to a solution of 30.3 mL (0.300 mol, 40.635 g) HSiCl₃ in Et₂O at −70° C. Reaction mixture is allowed to warm slowly to room temperature by stirring overnight. Diethylether is evaporated and an excess of n-heptane (˜200 mL) is added to precipitate the magnesium salts. Solution is filtrated and evaporated to dryness. The residue, penta-fluorophenyldichlorosilane, is purified by fractional distillation.

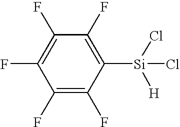

### Example 19

### Making a Compound I Via Method C

CH≡C—Na+ClSi(OEt)₃→CH≡C—Si(OEt)₃+NaCl

79.49 g (0.400 mol) ClSi(OEt)₃ in Et₂O is slowly added to a slurry of CH≡C—Na (0.400 mol, 19.208 g) in Xylene/light mineral oil at −78° C. Reaction mixture is stirred overnight allowing it slowly warm to room temperature. NaCl is removed by filtration and solution evaporated to dryness to result acetylenetriethoxysilane.

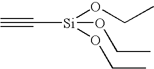

### Example 20

### Making a Compound VII Via Method A

C₆F₅Br+Mg+CH₂═CH—Si(OEt)₃→C₆F₅(CH₂═CH)Si(OEt)₂ 1.

C₆F₅(CH₂═CH)Si(OEt)₂+SOCl₂+py.HCl→C₆F₅(CH₂═CH)SiCl₂ 2.

100 mL (0.8021 mol, 198.088 g) pentafluorobromobenzene, 24.90 g (1.024 mol) magnesium powder and 670 mL (3.2084 mol, 610.623 g) vinyltriethoxysilane are mixed together at room temperature and Et₂O is added dropwise to the vigorously stirred solution until an exothermic reaction is observed (˜400 mL). After stirring at 35° C. for 16 h the mixture is cooled to room temperature and diethylether evaporated. An excess of n-heptane (˜500 mL) is added to precipitate the magnesium salts. Solution is filtrated and evaporated to dryness. The residue is fractionally distilled under reduced pressure to yield pentafluorophenylvinyldiethoxysilane.

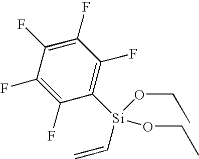

120.275 g (0.3914 mol) pentafluorophenylvinyldiethoxysilane, 143 mL (1.9571 mol, 232.833 g) thionyl-chloride and 5.880 g (0.0509 mol) pyridinium hydrochloride are refluxed and stirred for 24 h. Excess of SOCl₂ is evaporated and pentafluorophenylvinyldichlorosilane

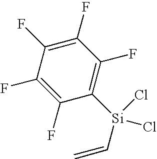

isolated by vacuum distillation.

### Example 21

### Making a Compound I from Method B

CH₂═CH—C(═O)—O—Na+ClSi(OEt)₃→CH₂═CH—C(═O)—O—Si(OEt)₃+NaCl

6.123 g (0.0651 mol) sodium acrylate is dissolved to 25 mL THF and cooled to −70° C. 12.8 mL (0.0651 mol, 12.938 g) chlorotriethoxysilane in THF (15 mL) is added dropwise to reaction solution. The solution is stirred for over night allowing it to warm up to room temperature. NaCl is removed by filtration and solution evaporated to dryness to result clear liquid, acryltriethoxysilane.

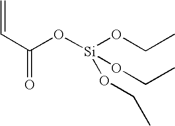

### Example 22

### Making a Compound II

CF₃—(CF₂)₇—CH₂—CH₂—Si(OEt)₃+SOCl₂+py.HCl→CF₃—(CF₂)₇—CH₂—CH₂—Si(OEt)₂Cl

183.11 g (0.300 mol) 1H,1H,2H,2H-Perfluorodecyltriethoxysilane, 22 mL (0.300 mol, 35.69 g) thionyl-chloride and 4.51 g (0.039 mol) pyridinium hydrochloride are refluxed and stirred for 16 h. Excess of SOCl₂ is evaporated and 1H,1H,2H,2H-Perfluorodecylchlorodi(ethoxy)silane isolated by vacuum-distillation.

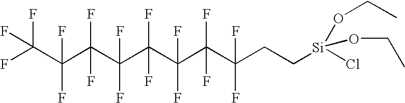

Though this example is not using Methods A, B or C, method C could be used to add a second organic group (replacing the Cl group), or Methods A and B could be used replace an ethoxy group in the starting material with an additional organic group. Also, the starting material could be made by Methods A, B or C (starting earlier with a tetraethoxysilane and reacting as in the other examples herein).

### Example 23

### Making a Compound I Via Method A

C₈F₁₇Br+Mg+excess Si(OEt)₄→C₈F₁₇Si(OEt)₃

C₈F₁₇Si(OEt)₃+excess SOCl₂+py.HCl→C₈F₁₇SiCl₃

250 g (0.501 mol) 1-Bromoperfluorooctane (or 273.5 g, 0.501 mol 1-Iodoperfluorooctane), 13.39 g (0.551 mol) magnesium powder, small amount of iodine (15 crystals) and 363 mL 2.004 mol, 339.00 g) tetraethoxysilane are mixed together at room temperature and diethylether is added dropwise to the vigorously stirred solution until an exothermic reaction is observed (˜200 mL). After stirring at room temperature for 16 h di-ethylether is evaporated. An excess of n-heptane (˜400 mL) is added to precipitate the magnesium salts. Solution is filtrated and evaporated to dryness. The residue is fractionally distilled under reduced pressure to yield perfluorooctyltriethoxysilane.

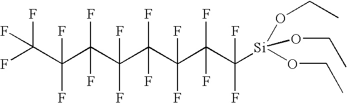

### Example 24

### Making a Compound IV Via Method A

Follow the steps in Example 23, then

174.7 g (0.300 mol) perfluorooctyltriethoxysilane, 131 mL (1.800 mol, 214.1 g) thionylchloride and 4.51 g (0.039 mol) pyridinium hydrochloride are refluxed and stirred for 16 h. Excess of SOCl₂ is evaporated and per-fluorooctyltrichlorosilane isolated by vacuum-distillation.

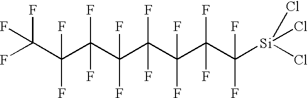

### Example 25

### Making a Compound I Via Method A

CF₂═CF—O—CF₂—CF₂—Br+Mg+excess Si(OEt)₄→CF₂═CF—O—CF₂—CF₂Si(OEt)₃

138.47 g (0.500 mol) 2-Bromotetrafluoroethyl trifluorovinyl ether, 13.37 g (0.550 mol) magnesium powder, small amount of iodine (10 crystals) and 362 mL (2.000 mol, 338.33 g) tetraethoxysilane are mixed together at room temperature and diethylether is added dropwise to the vigorously stirred solution until an exothermic reaction is observed (˜200 mL). After stirring at room temperature for 16 h diethylether is evaporated. An excess of n-heptane (˜400 mL) is added to precipitate the magnesium salts. Solution is filtrated and evaporated to dryness. The residue is fractionally distilled under reduced pressure to yield tetrafluoroethyl trifluorovinyl ether triethoxysilane.

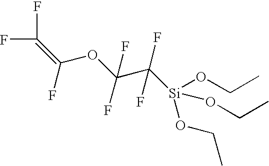

### Example 26

### Making a Compound IV Via Method A

Follow steps in Example 25, followed by

108.1 g (0.300 mol) tetrafluoroethyl trifluorovinyl ether triethoxysilane, 131 mL (1.800 mol, 214.1 g) thionylchloride and 4.51 g (0.039 mol) pyridinium hydrochloride are refluxed and stirred for 16 h. Excess of SOCl₂ is evaporated and tetrafluoroethyl trifluorovinyl ether trichlorosilane is isolated by vacuum-distillation.

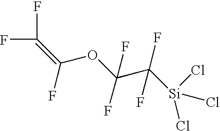

### Example 27

### Making a Compound I Via Method B

CF≡C—Li+ClSi(OEt)₃→CF≡C—Si(OEt)₃+LiCl

30.80 g (0.155 mol) ClSi(OEt)₃ in Et₂O is slowly added to solution of CF—C—Li (0.155 mol, 7.744 g, prepared in situ) in Et₂O at −78° C. Reaction mixture is stirred overnight allowing it slowly warm to room temperature. LiCl is removed by filtration and solution evaporated to dryness to result fluoroacetylenetriethoxysilane.

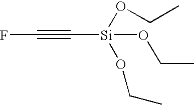

### Example 28

### Making a Compound VII Via Method C

(C₆F₅)₂Si(OEt)₂+SOCl₂→(C₆F₅)₂Si(OEt)Cl+EtCl+SO₂

C₆F₅Li+(C₆F₅)₂Si(OEt)Cl→(C₆F₅)₃SiOEt+LiCl

(C₆F₅)₃SiOEt+SOCl₂→(C₆F₅)₃SiCl+EtCl+SO₂

180.93 g (0.400 mol) di(pentafluorophenyl)diethoxysilane, 29 mL (0.400 mol, 47.6 g) thionylchloride and 4.92 g (0.0426 mol) pyridinium hydrochloride are refluxed and stirred for 16 h. Unreacted SOCl₂ is evaporated and di(pentafluorophenyl)chloroethoxysilane isolated by vacuum distillation.

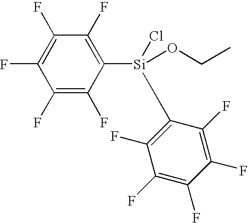

88.54 g (0.200 mol) of di(pentafluorophenyl)chloroethoxysilane in Et₂O is slowly added to solution of C6F₅—Li (0.200 mol, 34.80 g, prepared in situ) in Et₂O at −78° C. The solution is stirred for over night allowing it to warm up to room temperature. Formed clear solution is filtered and evaporated to dryness to result tri(pentafluorophenyl)ethoxysilane, (C₆F₅)₃SiOEt.

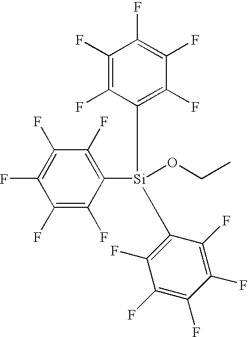

### Example 29

### Making a Compound IX Via Method C

Follow steps in Example 28, followed by

114.86 g (0.200 mol) tri(pentafluorophenyl)ethoxysilane, 14.6 mL (0.200 mol, 23.8 g) thionylchloride and 2.46 g (0.0213 mol) pyridinium hydrochloride are refluxed and stirred for 16 h. Unreacted SOCl₂ is evaporated and tri(pentafluorophenyl)chlorosilane isolated by vacuum-distillation.

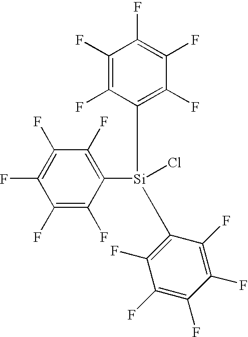

In addition to altering the organic groups in the above examples, it is of course also possible to use other reagents in the methods above. For example, in place of diethyl ether, other solvents such as THF could be used. In place of n-heptane (in Method A) other non polar solvents such as n-hexane could be used. And in place of thionyl chloride (for replacing one or more alkoxy groups with a halogen), chlorine, hydrochloric acid, hydrobromic acid, thionylbromide, chlorine or sulfurylchloride could be used. Also, the temperatures and times (and other process parameters) can be varied as desired. In one example, it is preferred that the molar ratio of the starting material to R²X¹ (Methods B or C) is 0.5:1 to 2:1—preferably 1:1. Also, the starting material and R²X¹ are preferably mixed at a temperature less than −40 C degrees, e.g., between −50 C and −100 C and warmed to a higher temperature over a period of four hours or more (this higher temperature can be room temperature or higher if desired)—or over a longer period of time such as overnight.

As can be seen from the examples above, Methods B and C involve reacting a first compound (having an M group selected from group 14 of the periodic table, 0, 1 or 2 organic groups bound to M) with a second compound (having an element from group 1 of the periodic table and a “new” organic group). As can also be seen from the above, such a reaction can take place if the first compound has alkoxy groups bound to M or both alkoxy and halogens (0, 1 or 2 halogens) bound to M. Method C, as mentioned earlier, is a variation of Method B—and both methods can be viewed as comprising: reacting a compound of the general formula R¹₄₋ₘMOR³ₘ₋ₙXₙ, where R¹ is any nonfluorinated (including deuterated) or partially or fully fluorinated organic group (preferably a partially or fully fluorinated aryl, alkenyl, alkynyl or alkyl group) as set forth above, where M is selected from group 14 of the periodic table, where X is a halogen, where OR³ is an alkoxy group, where m=2 to 4 and n=0 to 2. R¹₄₋ₘMOR³ₘ₋ₙXₙ is reacted with R²X¹ where R² is selected from alkyl, alkenyl, aryl or alkynyl (and where R² is fluorinated (fully or partially), and where X¹ is an element from group 1 of the periodic table. X¹ is preferably Na, Li or K, more preferably Na or Li, and most preferably Li. M is preferably Si, Ge or Sn, more preferably Si or Ge, and most preferably Si. X is preferably Cl, Br or I, more preferably Cl or Br, and most preferably Cl. OR³ is preferably an alkoxy group having from 1 to 4 carbon atoms, more preferably from 1 to 3 carbons, and most preferably 2 carbons (ethoxy). Also, “m” is preferably 3 or 4, whereas “n” is preferably 0 or 1.

R¹ and R² are independently preferably partially or fully fluorinated (though not necessarily as can be seen in prior examples) organic groups such as an aryl group (by aryl group we mean any organic group having a ring structure) though preferably a five or six carbon ring that is unsubstituted or substituted. For a six carbon ring structure, 1, 2 or 3 substituents can be bound to the ring, which substituents can be actively bound to the ring via a variation on the Method C set forth above (to be described further below). The substituents can be alkyl groups of any desired length, straight or branched chain, preferably fluorinated, and preferably having from 1 to 4 carbon atoms. Or the substituents on the ring structure can comprise a C═C double bond and be an alkenyl group (by alkenyl group we mean any organic group with a C═C double bond) such as an acrylate, vinyl or allyl group. A fluorinated vinyl, methyl or ethyl group on a fluorinated phenyl group are examples. Or, the aryl group could be a multi ring structure (e.g., perfluoronaphthalene or a biphenyl group). Or R¹ and R² could independently be an alkenyl group such as a vinyl or longer chain group having a C═C double bond, or a group having other types of double bonds (e.g., C═O double bonds or both C═C and C═O double bonds) such as acrylate and methacrylate groups. R¹ and R² could also be an alkynyl group (by alkynyl group we mean any organic group with a carbon-carbon triple bond) as mentioned previously, as well as an alkyl group. If an alkyl group (by alkyl group we mean a carbon chain of any length), preferably the carbon chain is from 1 to 14, and more preferably from 4 to 8. Perfluorinated alkyl groups from 1 to 8 carbons can be used, as well as fluorinated (e.g., partially fluorinated) groups longer than 8 carbons. All the organic groups above could be deuterated in stead of fluorinated (or partially deuterated and partially fluorinated), though fully or partially fluorinated (particularly fully fluorinated) is preferred. In Method C set forth above, an organic (or hybrid) group “R” (e.g., R²) becomes bound to a group 3-6 or 13-16 element “M” by replacing a halogen “X” bound to “M” via the specified reaction. In an alternative to this method (Method D), an organic (or hybrid) group “R” (e.g., R¹) comprises the halogen “X”—preferably Cl or Br (rather than “X” being bound to “M”). Thus, when the reaction is performed, R² replaces X bound to R¹, such that R² becomes bound to R¹ (which is in turn bound to M). Preferably the other groups bound to M are alkoxy groups (OR³) or other organic groups. More particularly, such a method comprises providing a compound XₐR¹MOR³₂R⁴ where a is from 1 to 3, X is a halogen(s) bound to R¹, R¹ is an organic group (preferably an aryl, alkyl, alkenyl or alkynyl—more preferably an alkyl or aryl group), OR³ is an alkoxy, and R⁴ is either an additional alkoxy group or an additional organic group (selected from aryl, alkyl, alkenyl or alkynyl), and reacting this compound with R²M¹ where M¹ is selected from group 1 of the periodic table and R² is an organic group preferably selected from aryl, alkyl, alkenyl and alkynyl, etc., so as to form R²ₐR¹MOR³₂R⁴.

In one example, R⁴ is an alkoxy group the same as OR³, such that the method comprises reacting XₐR¹MOR³₃ with R²M¹ to form R²ₐR¹MOR³₃ (where R¹ and OR³ are bound to M and R² is bound to R¹. In another example, R⁴ is an organic group selected from aryl, alkyl, alkenyl and alkynyl. Preferably OR³ is a methoxy, ethoxy or propoxy, R¹ is an aryl or alkyl (straight or branched chain) having from 1 to 14 carbons, and R² is an aryl, alkyl, alkenyl or alkynyl, where a=1 or 2 if R¹ is an alkyl and a=1, 2 or 3 if R¹ is an aryl group. R² can be an epoxy, acrylate, methacrylate, vinyl, allyl or other group capable of cross linking when exposed to an electron beam or in the presence of a photoinitiator and electromagnetic energy (e.g., UV light).

### Example A

### Forming a Compound I or IV Via Method D

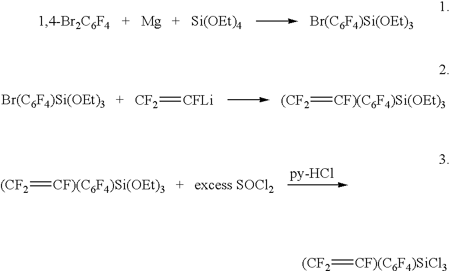

250 g (0.812 mol) 1,4-dibromotetrafluorobenzene, 21.709 g (0.8932 mol) magnesium powder, small amount of iodine (15 crystals) and 181 mL (0.812 mol, 169.164 g) tetraethoxysilane were mixed together at room temperature and diethylether was added dropwise to the vigorously stirred solution until an exothermic reaction was observed (˜250 mL). After stirring at room temperature for 16 h diethylether was evaporated. An excess of n-heptane (˜600 mL) was added to precipitate the magnesium salts. Solution was filtrated and evaporated to dryness. The residue was fractionally distilled under reduced pressure to yield 4-bromotetrafluorophenyltriethoxysilane.

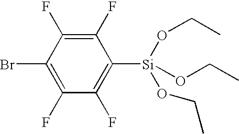

78.246 g (0.200 mol) 4-bromotetrafluorophenyltriethoxysilane in Et₂O is slowly added to solution of CF₂═CF—Li (0.200 mol, 17.592 g, prepared in situ) in Et₂O at −78° C. Reaction mixture is stirred overnight while it will slowly warm to room temperature. LiBr is removed by filtration and the product, 4-triethoxysilyl-perfluorostyrene, purified by distillation.

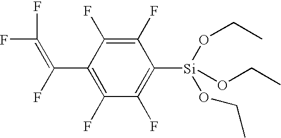

117.704 g (0.300 mol) 4-triethoxysilylperfluorostyrene, 131 mL (1.800 mol, 214.1 g) thionylchloride and 4.51 g (0.039 mol) pyridinium hydrochloride were refluxed and stirred for 16 h. Excess of SOCl₂ was evaporated and 4-trichlorosilyl-perfluorostyrene isolated by vacuum-distillation.

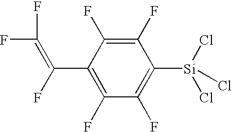

The above example could be modified where 2 or 3 halogens (in this case Br) are bound to the phenyl group so as to result in multiple vinyl substituents. Also, the phenyl group could be another organic group such as an straight or branched chain alkyl group, a multi ring aryl group, etc., whereas the vinyl group could be any suitable organic group capable of binding to a group I element (in the above example Li) and replacing the halogen (in the above example Br). Examples other than vinyl include methyl, ethyl, propyl, phenyl, epoxy and acrylate.

### Example B

### Forming a Compound I Via Method D

CF₂Cl—C(═O)—ONa+ClSi(OEt)₃→CF₂Cl—C(═O)—O—Si(OEt)₃+NaCl

CF₂═CF—Li+CF₂Cl—C(═O)—O—Si(OEt)₃→CF₂═CF—CF₂—C(═O)—O—Si(OEt)₃+LiCl

15.246 g (0.10 mol) sodium chlorodifluoroacetate, is dissolved to 100 mL Et₂O and cooled to −70° C. 19.7 mL (0.10 mol, 19.872 g) chlorotriethoxysilane in Et₂O (50 mL) was added dropwise to reaction solution. The solution was stirred for over night allowing it to warm up to room temperature. NaCl is removed by filtration and solution evaporated to dryness to result clear colourless liquid, chlorodifluoroacetic acid, triethoxysilyl ester.

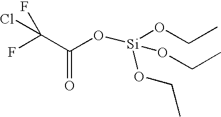

29.27 g (0.10 mol) chlorodifluoroacetic acid, triethoxysilyl ester, is dissolved to 100 mL Et₂O and slowly added to solution of CF₂═CF—Li (0.10 mol, 8.796 g, prepared in situ) in Et₂O at −78° C. Reaction mixture is stirred overnight allowing it slowly warm to room temperature. LiCl is removed by filtration and solution evaporated to dryness to result yellow liquid, crude perfluoro-3-butene acid, triethoxysilyl ester.

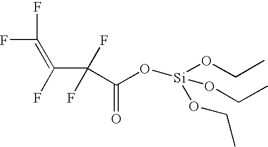

### Example C

### Forming a Compound I or IV Via Method D

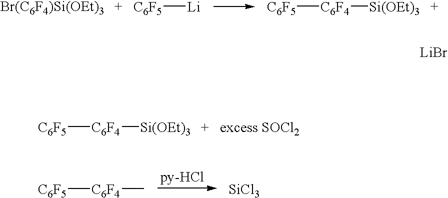

78.246 g (0.200 mol) 4-bromotetrafluorophenyltriethoxysilane in Et₂O is slowly added to solution of C₆F₅—Li (0.200 mol, 34.80 g, prepared in situ) in Et₂O at −78° C. Reaction mixture is stirred overnight while it will slowly warm to room temperature. LiBr is removed by filtration and the product, perifluorobiphenyltriethoxysilane, purified by distillation.

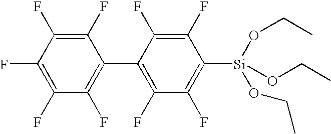

143.516 g (0.300 mol) perfluorobiphenyltriethoxysilane, 131 mL (1.800 mol, 214.1 g) thionylchloride and 4.51 g (0.039 mol) pyridinium hydrochloride were refluxed and stirred for 16 h. Excess of SOCl₂ was evaporated and perfluorobiphenyltrichlorosilane isolated by vacuum-distillation.

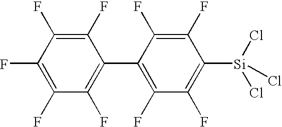

### Example D

### Forming a Compound I or IV Via Method D

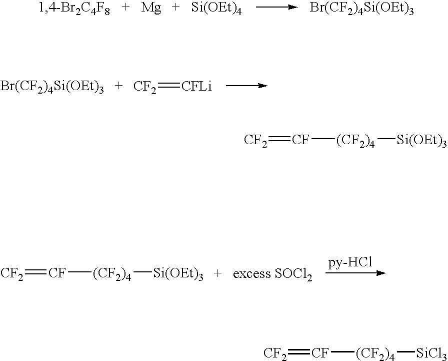

143.94 g (0.40 mol) 1,4-dibromooctafluorobutane, 10.69 g (0.44 mol) magnesium powder, small amount of iodine (15 crystals) and 88 mL (0.40 mol, 82.42 g) tetraethoxysilane were mixed together at room temperature and diethylether was added dropwise to the vigorously stirred solution until an exothermic reaction was observed (˜200 mL). After stirring at room temperature for 16 h diethylether was evaporated. An excess of n-heptane (˜400 mL) was added to precipitate the magnesium salts. Solution was filtrated and evaporated to dryness. The residue was fractionally distilled under reduced pressure to yield 4-bromooctafluorobutanetriethoxysilane.

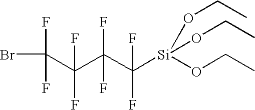

88.641 g (0.200 mol) 4-bromooctafluorobutanetriethoxysilane in Et₂O is slowly added to solution of CF₂═CF—Li (0.200 mol, 17.592 g, prepared in situ) in Et₂O at −78° C. Reaction mixture is stirred overnight while it will slowly warm to room temperature. LiBr is removed by filtration and the product, perfluoro-1-hexenetriethoxysilane, purified by distillation.

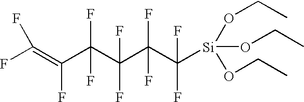

133.295 g (0.300 mol) perfluoro-1-hexenetriethoxysilane, 131 mL (1.800 mol, 214.1 g) thionylchloride and 4.51 g (0.039 mol) pyridinium hydrochloride were refluxed and stirred for 16 h. Excess of SOCl₂ was evaporated and perfluoro-1-hexenetrichlorosilane isolated by vacuum-distillation.

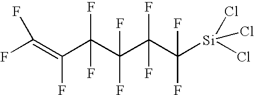

In the above “Method D” examples, R¹, R², R³ and R⁴ are preferably partially or fully fluorinated.

### Hydrolysis and Condensation of the Compound(s):

Compounds IV, VII and IX have organic (or hybrid) R group(s) and halogen(s) (preferably Br or Cl) bound to M (selected from groups 3-6 or 13-16—preferably group 14)). These compounds can be hydrolyzed alone or in any combination to result in a material having a -M-O-M-O— backbone with R groups bound to the backbone, and that preferably has a molecular weight of from 500 to 100,000. In one example, a compound selected from Compound IV is hydrolyzed with another compound selected from Compound IV. In another example, a single compound from Compound VII is hydrolyzed. Many other combinations are possible, including: a) Compound IV+Compound VII; b) Compound IV+Compound IV+Compound IV; c) Compound VII+Compound VII; d) Compound IV+Compound VII+Compound IX; e) Compound IV+Compound IV+Compound IX; f) Compound VII+Compound IX, etc. Any other combinations, in any desired ratio, can be used for the hydrolysis and eventual deposition.

The hydrolysis/condensation procedure can comprise five sequential stages: Dissolve, hydrolysis and co-condensation, neutralization, condensation and stabilization. Not all stages are necessary in all cases. In the hydrolysis, chlorine atoms are replaced with hydroxyl groups in the silane molecule. The following description takes as an example compounds that have chlorine as the halogen that takes part in the hydrolysis reaction, and silicon is the metal in the compound. Hydrochloric acid formed in the hydrolysis is removed in the neutralization stage. Silanols formed in the hydrolysis are attached together for a suitable oligomer in the condensation stage. The oligomer formed in the condensation are stabilized in the end. Each stage can be done with several different ways.

### Example I

Dissolving. Chlorosilanes are mixed together in an appropriate reaction container and the mixture is dissolved into a suitable solvent like tetrahydrofuran. Instead of tetrahydrofuran as solvent you can use any pure solvent or mixture of solvents/alternate solvents are possible either by themselves or by combinations. Traditional methods of selecting solvents by using Hansen type parameters can be used to optimize these systems. Examples are acetone, dichloromethane, chloroform, diethyl ether, ethyl acetate, methyl-isobutyl ketone, methyl ethyl ketone, acetonitrile, ethylene glycol dimethyl ether, triethylamine, formic acid, nitromethane, 1,4-dioxane, pyridine, acetic acid, di-isopropyl ether, toluene, carbon disulphide, carbon tetrachloride, benzene, methylcyclohexane, chlorobenzene.

Hydrolysis. The reaction mixture is cooled to 0° C. The hydrolysis is performed by adding water (H₂O) into the reaction mixture. The water is added in 1:4 (volume/volume) water-tetrahydrofuran-solution. Water is used equimolar amount as there are chlorine atoms in the starting reagents. The reaction mixture is held at 0° C. temperature during the addition. The reaction mixture is stirred at room temperature for 1 hour after addition. Instead of tetrahydrofuran water used in the reaction can be dissolved into pure or mixture of following solvents: acetone, dichloromethane, chloroform, diethyl ether, ethyl acetate, methyl-isobutyl ketone, methyl ethyl ketone, acetonitrile, ethylene glycol dimethyl ether, tetrahydrofuran, triethylamine, formic acid, nitromethane, 1,4-dioxane, pyridine, acetic acid. In the place of water following reagents can be used: deuterium oxide (D₂O) or HDO. A part of water can be replaced with following reagents: alcohols, deuterium alcohols, fluorinated alcohols, chlorinated alcohols, fluorinated deuterated alcohols, chlorinated deuterated alcohols. The reaction mixture may be adjusted to any appropriate temperature. The precursor solution can be added into water. Pure water can be used in the reaction. Excess or even less than equivalent amount of water can be used. Neutralization. The reaction mixture is neutralized with pure sodium hydrogen carbonate. NaHCO₃ is added into cooled reaction mixture at 0° C. temperature (NaHCO₃ is added equimolar amount as there is hydrochloric acid in the reaction mixture). The mixture is stirred at the room temperature for a while. After the pH of the reaction mixture has reached value 7, the mixture is filtered. The solvent is then evaporated with rotary evaporator.

Instead of sodium hydrogen carbonate (NaHCO₃) neutralization (removal of hydrochlorid acid) can be performed using following chemicals: pure potassium hydrogen carbonate (KHCO₃), ammonium hydrogen carbonate (NH₄HCO₃), sodium carbonate (Na₂CO₃), potassium carbonate (K₂CO₃), sodium hydroxide (NaOH), potassium hydroxide (KOH), calcium hydroxide (Ca(OH)₂), magnesium hydroxide (Mg(OH)₂) ammonia (NH₃), trialkylamines (R₃N, where R is hydrogen or straight/branched chain CₓH_{y}, x<10, as for example in triethylamine, or heteroatom containing as for example in triethanol amine), trialkyl ammonium hydroxides (R₃NOH, R₃N, where R is hydrogen or straight/branched chain CₓH_{y}, x<10), alkali metal silanolates, alkali metal silaxonates, alkali metal carboxylates. All neutralization reagents can be added into the reaction mixture also as a solution of any appropriate solvent. Neutralization can be performed also with solvent-solvent-extraction or with azeotropic water evaporation.

Procedure for solvent-solvent-extraction: The solvent is evaporated off after the hydrolysis. The material is dissolved into pure or mixture of following solvents: chloroform, ethyl acetate, diethyl ether, di-isopropyl ether, dichloromethane, methyl-isobutyl ketone, toluene, carbon disulphide, carbon tetrachloride, benzene, nitro-methane, methylcyclohexane, chlorobenzene. The solution is extracted several times with water or D₂O until pH of the organic layer is over value 6. The solvent is then evaporated with rotary evaporator. In cases when water immiscible solvent has been used in hydrolysis stage then solvent-solvent extraction can be performed right after hydrolysis without solvent evaporation. Acidic or basic water solution can be used in the extraction.

Procedure for azeotropic water evaporation: The solvent is evaporated off after the hydrolysis. The material is dissolved into mixture of water and one of the following solvents (1:10 volume/volume): tetrahydrofuran, ethanol, acetonitrile, 2-propanol, tert-butanol, ethylene glycol dimethyl ether, 2-propanol, toluene, dichloromethane. The formed solution is evaporated to dryness. The material is dissolved again into the same mixture of water and the solvent. Evaporation and addition cycle is repeated until pH value of the material solution is 7. The solvent is then evaporated with rotary evaporator.

Neutralization stage in cases where condensation stage is passed: In the neutralization stage evaporation of the solvent in the end is not necessary always. In these cases this stage is aborted after filtering (the reaction mixture is neutral) and the synthesis is continued in stabilization stage (the condensation stage is passed). Condensation. The material is stirred with magnetic stirrer bar under 12 mbar pressure for few hours. Water, which forms during this final condensation, evaporates off. The pressure in this stage can be in a large range. The material can be heated while vacuum treatment. Molecular weight of formed polymer can be increased in this stage by using base or acid catalyzed polymerizations. Procedure for acid catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloromethane, xylene, chloroform, diethyl ether, ethyl acetate, methyl-isobutyl ketone. Into the solution material solution is added catalytic amount of acid such as: triflic acid, monofluoro acetic acid, trifluoro acetic acid, trichloro acetic acid, dichloro acetic acid, monobromo acetic acid. The solution is refluxed for few hours or until polymerization is reached desired level while water formed in the reaction is removed. After polymerization, acid catalyst is removed from the material solution completely for example using solvent extraction or other methods described in alternative neutralization section. Finally solvent is removed. Procedure for base catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloromethane, xylene, chloroform, diethyl ether, ethyl acetate, methyl-isobutyl ketone. Into the solution material solution is added catalytic amount of base such as: triethanol amine, triethyl amine, pyridine, ammonia, tributyl ammonium hydroxide. The solution is refluxed for few hours or until polymerization is reached desired level while water formed in the reaction is removed. After polymerization, base catalyst is removed from the material solution completely for example by adding acidic water solution into the material solution. After that acidic solution is neutralized using solvent extraction or other methods described in alternative neutralization section. Finally solvent is removed.

Stabilization. The material is dissolved into cyclohexanone, which is added 30 weight-% of the materials weight. The pH of the solution is adjusted to value 2.0 with acetic acid. In the place of cyclohexanone can be used pure or mixture of following solvents: cyclopentanone, 2-propanol, ethanol, methanol, 1-propanol, tetrahydrofuran, methyl isobutyl ketone, acetone, nitromethane, chlorobenzene, dibutyl ether, cyclohexanone, 1,1,2,2-tetrachloroethane, mesitylene, trichloroethanes, ethyl lactate, 1,2-propanediol monomethyl ether acetate, carbon tetrachloride, perfluoro toluene, perfluoro p-xylene, perfluoro iso-propanol, cyclohexanone, tetraethylene glycol, 2-octanol, dimethyl sulfoxide, 2-ethyl hexanol, 3-octanol, diethyleneglycol butyl ether, diethyleneglycol dibutyl ether, diethylene glycol dimethyl ether, 1,2,3,4-tetrahydronaphtalene or trimethylol propane triacrylate. The material solution can be acidified using following acids: acetic acid, formic acid, propanoic acid, monofluoro acetic acid, trifluoro acetic acid, trichloro acetic acid, dichloro acetic acid, monobromo acetic acid. Also following basic compounds can be added into the material solution: triethyl amine, triethanol amine, pyridine, N-methylpyrrolidone. Stabilization in cases when the condensation stage is bypassed: Acetic acid is added into the mixture until a pH value of 3-4 is reached. The solution is evaporated until appropriate concentration of the oligomer in the solution has reached (about 50 w-% oligomer, 49 w-% solvent and 1 w-% acid, “solvent” is the solvent of the dissolving and hydrolysis stages).

In Example I above, “chlorosilanes” are initially mixed together with tetrahydrofuran. As mentioned earlier, this can be an almost unlimited number and type of compounds as disclosed in detail earlier herein—including a large number of chlorosilanes and other halo-metal-organic compounds in accordance with the invention and in accordance with the ultimate properties desired in the final material. If one of the compounds to be hydrolyzed and condensed is pentafluorophenyltrichlorosilane, this can be prepared as in the methods set forth above, by:

C₆F₅Br+Mg+excess Si(OEt)₄→C₆F₅Si(OEt)₃+(C₆F₅)₂Si(OEt)₂

C₆F₅Si(OEt)₃+SOCl₂+py.HCl→C₆F₅SiCl₃

100 mL (0.8021 mol, 198.088 g) pentafluorobromobenzene, 24.90 g (1.024 mol) magnesium powder and 716 mL (3.2084 mol, 668.403 g) tetraethoxysilane are mixed together at room temperature and diethylether is added dropwise to the vigorously stirred solution until an exothermic reaction is observed (˜200 mL). After stirring at 35° C. for 16 h the mixture is cooled to room temperature and diethylether evaporated. An excess of n-heptane (˜500 mL) is added to precipitate the magnesium salts. Solution is filtrated and evaporated to dryness. The residue is fractionally distilled under reduced pressure to yield pentafluorophenyltriethoxysilane.

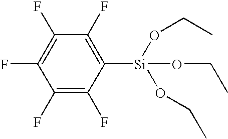

100 mL (0.375 mol, 124.0 g) pentafluorophenyltriethoxysilane, 167 mL (2.29 mol, 272.0 g) thionylchloride and 5.63 g (0.0487 mol) pyridinium hydrochloride are refluxed and stirred for 24 h. Excess of SOCl₂ is evaporated and pentafluorophenyltrichlorosilane

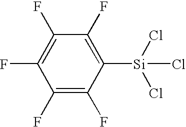

isolated by vacuum-distillation.

If a second of the compounds to be hydrolyzed and condensed is trifluorovinyltrichlorosilane, this can be prepared by:

119 mL (0.155 mol) sec-butyllithium (1.3 M solution in cyclohexane) is added under argon with stirring to 18.053 g (0.155 mol) chlorotrifluoroethylene

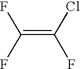

dissolved in Et₂O at −80° C. After the addition is complete the reaction mixture is stirred for 15 min to yield lithium-trifluoroethylene.

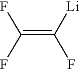

30.80 g (0.155 mol) ClSi(OEt)₃ in Et₂O is slowly added to solution of CF₂═CF—Li (0.155 mol, 13.633 g, prepared in situ) in Et₂O at −78° C. Reaction mixture is stirred overnight while it will slowly warm to room temperature. LiCl is removed by filtration and the product, trifluorovinyltriethoxysilane,

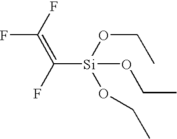

is isolated by distillation.

24.4 g (0.100 mol) trifluorovinyltriethoxysilane, 44 mL (0.60 mol, 71.4 g) thionylchloride and 0.497 g (0.0045 mol) pyridinium hydrochloride are refluxed and stirred for 24 h. Excess of SOCl₂ is evaporated and trifluorovinyltrichlorosilane

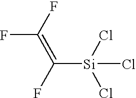

is purified by distillation.

Then, to a solution of trifluorovinyltrichlorosilane and pentafluorophenyltrichlorosilane at a molar ratio 1:1 in dehydrated tetrahydrofuran, is added dropwise a stoichiometric amount of water (e.g., H₂O or D₂O) in THF at 0° C. (nonstoichiometric amounts, higher or lower, can also be used). After stirring for 1 hour, the solution is neutralized with 3 equivalents of sodium hydrogencarbonate. After confirming the completion of generation of carbonic acid gas from the reaction solution, the solution is filtered and volatile compounds are removed by vacuum evaporation to obtain colorless, transparent viscous liquid, poly(pentafluorophenyltrifluorovinyl-siloxane), in a three dimensional network of alternating silicon and oxygen atoms.

### Example II

Dissolving. Vinyl trichlorosilane (64.89 g, 402 mmol, 50 mol %) and phenyl trichlorosilane (85.00 g, 402 mmol, 50 mol %) are dissolved in dehydrated THF.

Hydrolysis. The solution is cooled down to 0° C. Water (43.42 g, 2.41 mol, 300 mol %) is added slowly dropwise in THF (1:4 V:V) into stirred solution. The solution is then stirred for 1 hour at the room temperature.

Neutralization. The solution is cooled down to 0° C. and sodium hydrogen carbonate (202.53 g, 2.41 mol, 300 mol %) is added slowly. The solution is stirred after addition at the room temperature until pH of the mixture is neutral.

Condensation. The solution is then filtered and solvents are evaporated with rotary evaporator. After evaporation the mixture is stirred at the room temperature under high vacuum until refractive index of the material is 1.5220. Stabilization. After vacuum treatment dehydrated THF (5 w-%) and MIBK (20 w-%) are added into the material for solvents and the material is dissolved. Appropriate initiators are added and dissolved into the mixture. Finally, the material is filtered.

### Alternative Procedures for Each Stage:

Dissolve. Instead of tetrahydrofuran (THF) as solvent you can use any pure solvent or mixture of solvents/alternate solvents are possible either by themselves or by combinations. Traditional methods of selecting solvents by using Hansen type parameters can be used to optimize these systems. Examples are acetone, di-chloromethane, chloroform, diethyl ether, ethyl acetate, methyl-isobutyl ketone, methyl ethyl ketone, acetonitrile, ethylene glycol dimethyl ether, triethylamine, formic acid, nitromethane, 1,4-dioxane, pyridine, acetic acid, di-isopropyl ether, toluene, carbon disulphide, carbon tetrachloride, benzene, methylcyclohexane, chlorobenzene. Hydrolysis. Water used in the reaction can be, instead of tetrahydrofuran, dissolved into pure or mixture of following solvents: acetone, dichloromethane, chloroform, diethyl ether, ethyl acetate, methyl-isobutyl ketone, methyl ethyl ketone, acetonitrile, ethylene glycol dimethyl ether, tetrahydrofuran, triethylamine, formic acid, nitromethane, 1,4-dioxane, pyridine, acetic acid. In the place of water following reagents can be used: deuterium oxide (D₂O) or HDO. A part of water can be replaced with following reagents: alcohols, deuterium alcohols, fluorinated alcohols, chlorinated alcohols, fluorinated deuterated alcohols, chlorinated deuterated alcohols. The reaction mixture may be adjusted to any appropriate temperature. The precursor solution can be added into water. Pure water can be used in the reaction. Excess or even less than equivalent amount of water can be used.

Neutralization. Instead of sodium hydrogen carbonate (NaHCO₃) neutralization (removal of hydrochlorid acid) can be performed using following chemicals: pure potassium hydrogen carbonate (KHCO₃), ammonium hydrogen carbonate (NH₄HCO₃), sodium carbonate (Na₂CO₃), potassium carbonate (K₂CO₃), sodium hydroxide (NaOH), potassium hydroxide (KOH), calcium hydroxide (Ca(OH)₂), magnesium hydroxide (Mg(OH)₂) ammonia (NH₃), trialkylamines (R₃N, where R is hydrogen or straight/branched chain CₓH_{y}, x<10, as for example in triethylamine, or heteroatom containing as for example in triethanol amine), trialkyl ammonium hydroxides (R₃NOH, R₃N, where R is hydrogen or straight/branched chain CₓH_{y}, x<10), alkali metal silanolates, alkali metal silaxonates, alkali metal carboxylates. All neutralization reagents can be added into the reaction mixture also as a solution of any appropriate solvent. Neutralization can be performed also with solvent-solvent-extraction or with azeotropic water evaporation.

Procedure for solvent-solvent-extraction: The solvent is evaporated off after the hydrolysis. The material is dissolved into pure or mixture of following solvents: chloroform, ethyl acetate, diethyl ether, di-isopropyl ether, dichloromethane, methyl-isobutyl ketone, toluene, carbon disulphide, carbon tetrachloride, benzene, nitro-methane, methylcyclohexane, chlorobenzene. The solution is extracted several times with water or D₂O until pH of the organic layer is over value 6. The solvent is then evaporated with rotary evaporator. In cases when water immiscible solvent has been used in hydrolysis stage then solvent-solvent extraction can be performed right after hydrolysis without solvent evaporation. Acidic or basic water solution can be used in the extraction.

Procedure for azeotropic water evaporation: The solvent is evaporated off after the hydrolysis. The material is dissolved into mixture of water and one of the following solvents (1:10 volume/volume): tetrahydrofuran, ethanol, acetonitrile, 2-propanol, tert-butanol, ethylene glycol dimethyl ether, 2-propanol, toluene, dichloromethane. The formed solution is evaporated to dryness. The material is dissolved again into the same mixture of water and the solvent. Evaporation and addition cycle is repeated until pH value of the material solution is 7. The solvent is then evaporated with rotary evaporator.

Condensation. The pressure in this stage can be in a large range. The material can be heated while vacuum treatment. Molecular weight of formed polymer can be increased in this stage by using base or acid catalyzed polymerizations. Procedure for acid catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloromethane, xylene, chloroform, diethyl ether, ethyl acetate, methyl-isobutyl ketone. Into the solution material solution is added catalytic amount of acid such as: triflic acid, monofluoro acetic acid, trifluoro acetic acid, trichloro acetic acid, dichloro acetic acid, monobromo acetic acid. The solution is refluxed for few hours or until polymerization is reached desired level while water formed in the reaction is removed. After polymerization, acid catalyst is removed from the material solution completely for example using solvent extraction or other methods described in alternative neutralization section. Finally solvent is removed. Procedure for base catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloro-methane, xylene, chloroform, diethyl ether, ethyl acetate, methyl-isobutyl ketone. Into the solution material solution is added catalytic amount of base such as: triethanol amine, triethyl amine, pyridine, ammonia, tributyl ammonium hydroxide. The solution is refluxed for few hours or until polymerization is reached desired level while water formed in the reaction is removed. After polymerization, base catalyst is removed from the material solution completely for example by adding acidic water solution into the material solution. After that acidic solution is neutralized using solvent extraction or other methods described in alternative neutralization section. Finally solvent is removed.

Stabilization. In the place of THF and MIBK can be used pure or mixture of following solvents: cyclopentanone, 2-propanol, ethanol, methanol, 1-propanol, tetrahydrofuran, methyl isobutyl ketone, acetone, nitro-methane, chlorobenzene, dibutyl ether, cyclohexanone, 1,1,2,2-tetrachloroethane, mesitylene, trichloroethanes, ethyl lactate, 1,2-propanediol monomethyl ether acetate, carbon tetrachloride, perfluoro toluene, perfluoro p-xylene, perfluoro iso-propanol, cyclohexanone, tetraethylene glycol, 2-octanol, dimethyl sulfoxide, 2-ethyl hexanol, 3-octanol, diethyleneglycol butyl ether, diethyleneglycol dibutyl ether, diethylene glycol dimethyl ether, 1,2,3,4-tetrahydronaphtalene or trimethylol propane triacrylate. The material solution can be acidified using following acids: acetic acid, formic acid, propanoic acid, monofluoro acetic acid, trifluoro acetic acid, trichloro acetic acid, dichloro acetic acid, monobromo acetic acid. Also following basic compounds can be added into the material solution: triethyl amine, triethanol amine, pyridine, N-methylpyrrolidone.

Initiators: Photoinitiators that can be used are Irgacure 184, Irgacure 500, Irgacure 784, Irgacure 819, Irgacure 1300, Irgacure 1800, Darocure 1173 and Darocure 4265. The initiator can be highly fluorinated, such as 1,4-bis(pentafluorobenzoyl)benzene or Rhodosil 2074. Thermal initiators which can be used are benzoyl peroxide, 2,2′-azobisisobutyronitrile, 1,1′-Azobis(cyclohexanecarbonitrile), tert-butyl hydroperoxide, Dicumyl peroxide and Lauroyl peroxide.

### Example III

Dissolve. Pentafluorophenyl vinyl dichlorosilane (54.85 g, 187 mmol, 58 mol %), pentafluorophenyl tri-chlorosilane (24.32 g, 81 mmol, 25 mol %), acryloxypropyl trichlorosilane (5.59 g, 23 mmol, 7 mol %) and dimethyl dimethoxysilane (3.88 g, 32 mmol, 10 mol %) are dissolved in dehydrated THF.

Hydrolysis. The solution is cooled down to 0° C. and water (12.32 g, 684 mmol, 212 mol %) is added dropwise in THF (1:4 V:V) into stirred solution. The solution is stirred for 1 hour at the room temperature after addition.

Neutralization. The solution is cooled down to 0° C. Sodium hydrogen carbonate (57.46 g, 684 mmol, 212 mol %) is added slowly into this mixed solution. The solution is stirred after addition at the room temperature until pH of the mixture is neutral.

Condensation. The solution is then filtered and solvents are evaporated. After evaporation the mixture is stirred under high vacuum until refractive index of the material is 1.4670.

Stabilization. After vacuum treatment dehydrated THF (5 w-%) and cyclohexanone (40 w-%) are added for solvents and the material is dissolved. The solution is acidified to pH value 2.0. Appropriate initiators are added and dissolved into the mixture. Finally, the material is filtered.

### Alternative Procedures for Each Stage:

Dissolve. Instead of tetrahydrofuran (THF) as solvent you can use any pure solvent or mixture of solvents/alternate solvents are possible either by themselves or by combinations. Traditional methods of selecting solvents by using Hansen type parameters can be used to optimize these systems. Examples are acetone, di-chloromethane, chloroform, diethyl ether, ethyl acetate, methyl-isobutyl ketone, methyl ethyl ketone, acetonitrile, ethylene glycol dimethyl ether, triethylamine, formic acid, nitromethane, 1,4-dioxane, pyridine, acetic acid, di-isopropyl ether, toluene, carbon disulphide, carbon tetrachloride, benzene, methylcyclohexane, chlorobenzene.

Hydrolysis. Water used in the reaction can be, instead of tetrahydrofuran, dissolved into pure or mixture of following solvents: acetone, dichloromethane, chloroform, diethyl ether, ethyl acetate, methyl-isobutyl ketone, methyl ethyl ketone, acetonitrile, ethylene glycol dimethyl ether, tetrahydrofuran, triethylamine, formic acid, nitro-methane, 1,4-dioxane, pyridine, acetic acid. In the place of water following reagents can be used: deuterium oxide (D₂O) or HDO. A part of water can be replaced with following reagents: alcohols, deuterium alcohols, fluorinated alcohols, chlorinated alcohols, fluorinated deuterated alcohols, chlorinated deuterated alcohols. The reaction mixture may be adjusted to any appropriate temperature. The precursor solution can be added into water. Pure water can be used in the reaction. Excess or even less than equivalent amount of water can be used.

Neutralization. Instead of sodium hydrogen carbonate (NaHCO₃) neutralization (removal of hydrochlorid acid) can be performed using following chemicals: pure potassium hydrogen carbonate (KHCO₃), ammonium hydrogen carbonate (NH₄HCO₃), sodium carbonate (Na₂CO₃), potassium carbonate (K₂CO₃), sodium hydroxide (NaOH), potassium hydroxide (KOH), calcium hydroxide (Ca(OH)₂), magnesium hydroxide (Mg(OH)₂) ammonia (NH₃), trialkylamines (R₃N, where R is hydrogen or straight/branched chain CₓH_{y}, x<10, as for example in triethylamine, or heteroatom containing as for example in triethanol amine), trialkyl ammonium hydroxides (R₃NOH, R₃N, where R is hydrogen or straight/branched chain CₓH_{y}, x<10), alkali metal silanolates, alkali metal silaxonates, alkali metal carboxylates. All neutralization reagents can be added into the reaction mixture also as a solution of any appropriate solvent. Neutralization can be performed also with solvent-solvent-extraction or with azeotropic water evaporation.

Procedure for solvent-solvent-extraction: The solvent is evaporated off after the hydrolysis. The material is dissolved into pure or mixture of following solvents: chloroform, ethyl acetate, diethyl ether, di-isopropyl ether, dichloromethane, methyl-isobutyl ketone, toluene, carbon disulphide, carbon tetrachloride, benzene, nitro-methane, methylcyclohexane, chlorobenzene. The solution is extracted several times with water or D₂O until pH of the organic layer is over value 6. The solvent is then evaporated with rotary evaporator. In cases when water immiscible solvent has been used in hydrolysis stage then solvent-solvent extraction can be performed right after hydrolysis without solvent evaporation. Acidic or basic water solution can be used in the extraction.

Procedure for azeotropic water evaporation: The solvent is evaporated off after the hydrolysis. The material is dissolved into mixture of water and one of the following solvents (1:10 volume/volume): tetrahydrofuran, ethanol, acetonitrile, 2-propanol, tert-butanol, ethylene glycol dimethyl ether, 2-propanol, toluene, dichloromethane. The formed solution is evaporated to dryness. The material is dissolved again into the same mixture of water and the solvent. Evaporation and addition cycle is repeated until pH value of the material solution is 7. The solvent is then evaporated with rotary evaporator.

Condensation. The pressure in this stage can be in a large range. The material can be heated while vacuum treatment. Molecular weight of formed polymer can be increased in this stage by using base or acid catalyzed polymerizations. Procedure for acid catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloromethane, xylene, chloroform, diethyl ether, ethyl acetate, methyl-isobutyl ketone. Into the solution material solution is added catalytic amount of acid such as: triflic acid, monofluoro acetic acid, trifluoro acetic acid, trichloro acetic acid, dichloro acetic acid, monobromo acetic acid. The solution is refluxed for few hours or until polymerization is reached desired level while water formed in the reaction is removed. After polymerization, acid catalyst is removed from the material solution completely for example using solvent extraction or other methods described in alternative neutralization section. Finally solvent is removed. Procedure for base catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloro-methane, xylene, chloroform, diethyl ether, ethyl acetate, methyl-isobutyl ketone. Into the solution material solution is added catalytic amount of base such as: triethanol amine, triethyl amine, pyridine, ammonia, tributyl ammonium hydroxide. The solution is refluxed for few hours or until polymerization is reached desired level while water formed in the reaction is removed. After polymerization, base catalyst is removed from the material solution completely for example by adding acidic water solution into the material solution. After that acidic solution is neutralized using solvent extraction or other methods described in alternative neutralization section. Finally, solvent is removed.

Stabilization. In the place of THF and cyclohexanone can be used pure or mixture of following solvents: cyclopentanone, 2-propanol, ethanol, methanol, 1-propanol, tetrahydrofuran, methyl isobutyl ketone, acetone, nitromethane, chlorobenzene, dibutyl ether, cyclohexanone, 1,1,2,2-tetrachloroethane, mesitylene, trichloroethanes, ethyl lactate, 1,2-propanediol monomethyl ether acetate, carbon tetrachloride, perfluoro toluene, perfluoro p-xylene, perfluoro iso-propanol, cyclohexanone, tetraethylene glycol, 2-octanol, dimethyl sulfoxide, 2-ethyl hexanol, 3-octanol, diethyleneglycol butyl ether, diethyleneglycol dibutyl ether, diethylene glycol dimethyl ether, 1,2,3,4-tetrahydronaphtalene or trimethylol propane triacrylate. The material solution can be acidified using following acids: acetic acid, formic acid, propanoic acid, monofluoro acetic acid, trifluoro acetic acid, trichloro acetic acid, dichloro acetic acid, monobromo acetic acid. Also following basic compounds can be added into the material solution: triethyl amine, triethanol amine, pyridine, N-methylpyrrolidone.

Initiators: Photoinitiators that can be used are Irgacure 184, Irgacure 500, Irgacure 784, Irgacure 819, Irgacure 1300, Irgacure 1800, Darocure 1173 and Darocure 4265. The initiator can be highly fluorinated, such as 1,4-bis(pentafluorobenzoyl)benzene or Rhodosil 2074. Thermal initiators which can be used are benzoyl peroxide, 2,2′-azobisisobutyronitrile, 1,1′-Azobis(cyclohexanecarbonitrile), tert-butyl hydroperoxide, Dicumyl peroxide and Lauroyl peroxide.

### Example IV

Dissolve. Pentafluorophenyl vinyl dichlorosilane (122.96 g, 420 mmol, 58 mol %), pentafluorophenyl trichlorosilane (54.54 g, 181 mmol, 25 mol %), acryloxypropyl trichlorosilane (12.54 g, 51 mmol, 7 mol %) and di(pentafluorophenyl)dichlorosilane (31.33 g, 72 mmol, 10 mol %) are dissolved in dehydrated THF.

Hydrolysis. The solution is cooled down to 0° C. and water (30.27 g, 1.68 mol, 232 mol %) is added dropwise in THF (1:4 V:V) into stirred solution. The solution is then stirred for 1 hour at the room temperature.

Neutralization. The solution is cooled down to 0° C. and sodium hydrogen carbonate (140.97 g, 1.68 mol, 232 mol %) is added slowly. The solution is stirred after addition at the room temperature until pH of the mixture is neutral.

Condensation. The solution is then filtered and solvents are evaporated. After evaporation the mixture is stirred under high vacuum until refractive index of the material is 1.4705.

Stabilization. After vacuum treatment dehydrated THF (5 w-%) and cyclohexanone (40 w-%) are added for solvents and the material is dissolved. The solution is acidified to pH value 2.0 with trifluoro acetic acid. Appropriate initiators are added and dissolved into the mixture. Finally, the material is filtered.

### Alternative Procedures for Each Stage:

Dissolve. Instead of tetrahydrofuran (THF) as solvent you can use any pure solvent or mixture of solvents/alternate solvents are possible either by themselves or by combinations. Traditional methods of selecting solvents by using Hansen type parameters can be used to optimize these systems. Examples are acetone, di-chloromethane, chloroform, diethyl ether, ethyl acetate, methyl-isobutyl ketone, methyl ethyl ketone, acetonitrile, ethylene glycol dimethyl ether, triethylamine, formic acid, nitromethane, 1,4-dioxane, pyridine, acetic acid, di-isopropyl ether, toluene, carbon disulphide, carbon tetrachloride, benzene, methylcyclohexane, chlorobenzene. Hydrolysis. Water used in the reaction can be, instead of tetrahydrofuran, dissolved into pure or mixture of following solvents: acetone, dichloromethane, chloroform, diethyl ether, ethyl acetate, methyl-isobutyl ketone, methyl ethyl ketone, acetonitrile, ethylene glycol dimethyl ether, tetrahydrofuran, triethylamine, formic acid, nitromethane, 1,4-dioxane, pyridine, acetic acid. In the place of water following reagents can be used: deuterium oxide (D₂O) or HDO. A part of water can be replaced with following reagents: alcohols, deuterium alcohols, fluorinated alcohols, chlorinated alcohols, fluorinated deuterated alcohols, chlorinated deuterated alcohols. The reaction mixture may be adjusted to any appropriate temperature. The precursor solution can be added into water. Pure water can be used in the reaction. Excess or even less than equivalent amount of water can be used.

Neutralization. Instead of sodium hydrogen carbonate (NaHCO₃) neutralization (removal of hydrochlorid acid) can be performed using following chemicals: pure potassium hydrogen carbonate (KHCO₃), ammonium hydrogen carbonate (NH₄HCO₃), sodium carbonate (Na₂CO₃), potassium carbonate (K₂CO₃), sodium hydroxide (NaOH), potassium hydroxide (KOH), calcium hydroxide (Ca(OH)₂), magnesium hydroxide (Mg(OH)₂) ammonia (NH₃), trialkylamines (R₃N, where R is hydrogen or straight/branched chain CₓH_{y}, x<10, as for example in triethylamine, or heteroatom containing as for example in triethanol amine), trialkyl ammonium hydroxides (R₃NOH, R₃N, where R is hydrogen or straight/branched chain CₓH_{y}, x<10), alkali metal silanolates, alkali metal silaxonates, alkali metal carboxylates. All neutralization reagents can be added into the reaction mixture also as a solution of any appropriate solvent. Neutralization can be performed also with solvent-solvent-extraction or with azeotropic water evaporation.

Procedure for solvent-solvent-extraction: The solvent is evaporated off after the hydrolysis. The material is dissolved into pure or mixture of following solvents: chloroform, ethyl acetate, diethyl ether, di-isopropyl ether, dichloromethane, methyl-isobutyl ketone, toluene, carbon disulphide, carbon tetrachloride, benzene, nitromethane, methylcyclohexane, chlorobenzene. The solution is extracted several times with water or D₂O until pH of the organic layer is over value 6. The solvent is then evaporated with rotary evaporator. In cases when water immiscible solvent has been used in hydrolysis stage then solvent-solvent extraction can be performed right after hydrolysis without solvent evaporation. Acidic or basic water solution can be used in the extraction.

Procedure for azeotropic water evaporation: The solvent is evaporated off after the hydrolysis. The material is dissolved into mixture of water and one of the following solvents (1:10 volume/volume): tetrahydrofuran, ethanol, acetonitrile, 2-propanol, tert-butanol, ethylene glycol dimethyl ether, 2-propanol, toluene, dichloro-methane. The formed solution is evaporated to dryness. The material is dissolved again into the same mixture of water and the solvent. Evaporation and addition cycle is repeated until pH value of the material solution is 7. The solvent is then evaporated with rotary evaporator.

Condensation. The pressure in this stage can be in a large range. The material can be heated while vacuum treatment. Molecular weight of formed polymer can be increased in this stage by using base or acid catalyzed polymerizations. Procedure for acid catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloromethane, xylene, chloroform, diethyl ether, ethyl acetate, methyl-isobutyl ketone. Into the solution material solution is added catalytic amount of acid such as: triflic acid, monofluoro acetic acid, trifluoro acetic acid, trichloro acetic acid, dichloro acetic acid, monobromo acetic acid. The solution is refluxed for few hours or until polymerization is reached desired level while water formed in the reaction is removed. After polymerization, acid catalyst is removed from the material solution completely for example using solvent extraction or other methods described in alternative neutralization section. Finally, solvent is removed. Procedure for base catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, di-chloromethane, xylene, chloroform, diethyl ether, ethyl acetate, methyl-isobutyl ketone. Into the solution material solution is added catalytic amount of base such as: triethanol amine, triethyl amine, pyridine, ammonia, tributyl ammonium hydroxide. The solution is refluxed for few hours or until polymerization is reached desired level while water formed in the reaction is removed. After polymerization, base catalyst is removed from the material solution completely for example by adding acidic water solution into the material solution. After that acidic solution is neutralized using solvent extraction or other methods described in alternative neutralization section. Finally, solvent is removed.

Stabilization. In the place of THF and cyclohexanone can be used pure or mixture of following solvents: cyclopentanone, 2-propanol, ethanol, methanol, 1-propanol, tetrahydrofuran, methyl isobutyl ketone, acetone, nitromethane, chlorobenzene, dibutyl ether, cyclohexanone, 1,1,2,2-tetrachloroethane, mesitylene, trichloroethanes, ethyl lactate, 1,2-propanediol monomethyl ether acetate, carbon tetrachloride, perfluoro toluene, per-fluoro p-xylene, perfluoro iso-propanol, cyclohexanone, tetraethylene glycol, 2-octanol, dimethyl sulfoxide, 2-ethyl hexanol, 3-octanol, diethyleneglycol butyl ether, diethyleneglycol dibutyl ether, diethylene glycol dimethyl ether, 1,2,3,4-tetrahydronaphtalene or trimethylol propane triacrylate. The material solution can be acidified using following acids: acetic acid, formic acid, propanoic acid, monofluoro acetic acid, trifluoro acetic acid, trichloro acetic acid, dichloro acetic acid, monobromo acetic acid. Also following basic compounds can be added into the material solution: triethyl amine, triethanol amine, pyridine, N-methylpyrrolidone.

Initiators: Photoinitiators that can be used are Irgacure 184, Irgacure 500, Irgacure 784, Irgacure 819, Irgacure 1300, Irgacure 1800, Darocure 1173 and Darocure 4265. The initiator can be highly fluorinated, such as 1,4-bis(pentafluorobenzoyl)benzene or Rhodosil 2074. Thermal initiators which can be used are benzoyl peroxide, 2,2′-azobisisobutyronitrile, 1,1′-Azobis(cyclohexanecarbonitrile), tert-butyl hydroperoxide, Dicumyl peroxide and Lauroyl peroxide.

### Example V

Dissolve. Pentafluorophenyl vinyl dichlorosilane (90.00 g, 307 mmol, 60 mol %), pentafluorophenyl tri-chlorosilane (38.59 g, 128 mmol, 25 mol %) and di(pentafluorophenyl)dichlorosilane (33.25 g, 77 mmol, 15 mol %) are dissolved in dehydrated THF.

Hydrolysis. The solution is cooled down to 0° C. and water (20.72 g, 1.15 mol, 225 mol %) is added dropwise in THF (1:4 V:V) into this stirred solution. The solution is then stirred for 1 hour at the room temperature.

Neutralization. The solution is cooled down to 0° C. and sodium hydrogen carbonate (96.74 g, 1.15 mol, 225 mol %) is added slowly. The solution is stirred after addition at the room temperature until pH of the mixture is neutral.

Condensation. The solution is then filtered and solvents are evaporated. After evaporation the mixture is stirred under high vacuum until refractive index of the material is 1.4715.

Stabilization. After vacuum treatment dehydrated THF (5 w-%) and cyclohexanone (40 w-%) are added for solvents and the material is dissolved. The solution is acidified to pH value 2.0 with trifluoro acetic acid. Appropriate initiators are added and dissolved into the mixture. Finally, the material is filtered.

### Alternative Procedures for Each Stage:

Dissolve. Instead of tetrahydrofuran (THF) as solvent you can use any pure solvent or mixture of solvents/alternate solvents are possible either by themselves or by combinations. Traditional methods of selecting solvents by using Hansen type parameters can be used to optimize these systems. Examples are acetone, di-chloromethane, chloroform, diethyl ether, ethyl acetate, methyl-isobutyl ketone, methyl ethyl ketone, acetonitrile, ethylene glycol dimethyl ether, triethylamine, formic acid, nitromethane, 1,4-dioxane, pyridine, acetic acid, di-isopropyl ether, toluene, carbon disulphide, carbon tetrachloride, benzene, methylcyclohexane, chlorobenzene.

Hydrolysis. Water used in the reaction can be, instead of tetrahydrofuran, dissolved into pure or mixture of following solvents: acetone, dichloromethane, chloroform, diethyl ether, ethyl acetate, methyl-isobutyl ketone, methyl ethyl ketone, acetonitrile, ethylene glycol dimethyl ether, tetrahydrofuran, triethylamine, formic acid, nitro-methane, 1,4-dioxane, pyridine, acetic acid. In the place of water following reagents can be used: deuterium oxide (D₂O) or HDO. A part of water can be replaced with following reagents: alcohols, deuterium alcohols, fluorinated alcohols, chlorinated alcohols, fluorinated deuterated alcohols, chlorinated deuterated alcohols. The reaction mixture may be adjusted to any appropriate temperature. The precursor solution can be added into water. Pure water can be used in the reaction. Excess or even less than equivalent amount of water can be used. Neutralization. Instead of sodium hydrogen carbonate (NaHCO₃) neutralization (removal of hydrochlorid acid) can be performed using following chemicals: pure potassium hydrogen carbonate (KHCO₃), ammonium hydrogen carbonate (NH₄HCO₃), sodium carbonate (Na₂CO₃), potassium carbonate (K₂CO₃), sodium hydroxide (NaOH), potassium hydroxide (KOH), calcium hydroxide (Ca(OH)₂), magnesium hydroxide (Mg(OH)₂) ammonia (NH₃), trialkylamines (R₃N, where R is hydrogen or straight/branched chain CₓH_{y}, x<10, as for example in triethyl-amine, or heteroatom containing as for example in triethanol amine), trialkyl ammonium hydroxides (R₃NOH, R₃N, where R is hydrogen or straight/branched chain CₓH_{y}, x<10), alkali metal silanolates, alkali metal silaxonates, alkali metal carboxylates. All neutralization reagents can be added into the reaction mixture also as a solution of any appropriate solvent. Neutralization can be performed also with solvent-solvent-extraction or with azeotropic water evaporation.

Procedure for solvent-solvent-extraction: The solvent is evaporated off after the hydrolysis. The material is dissolved into pure or mixture of following solvents: chloroform, ethyl acetate, diethyl ether, di-isopropyl ether, dichloromethane, methyl-isobutyl ketone, toluene, carbon disulphide, carbon tetrachloride, benzene, nitro-methane, methylcyclohexane, chlorobenzene. The solution is extracted several times with water or D₂O until pH of the organic layer is over value 6. The solvent is then evaporated with rotary evaporator. In cases when water immiscible solvent has been used in hydrolysis stage then solvent-solvent extraction can be performed right after hydrolysis without solvent evaporation. Acidic or basic water solution can be used in the extraction.

Procedure for azeotropic water evaporation: The solvent is evaporated off after the hydrolysis. The material is dissolved into mixture of water and one of the following solvents (1:10 volume/volume): tetrahydrofuran, ethanol, acetonitrile, 2-propanol, tert-butanol, ethylene glycol dimethyl ether, 2-propanol, toluene, dichloromethane. The formed solution is evaporated to dryness. The material is dissolved again into the same mixture of water and the solvent. Evaporation and addition cycle is repeated until pH value of the material solution is 7. The solvent is then evaporated with rotary evaporator.

Condensation. The pressure in this stage can be in a large range. The material can be heated while vacuum treatment. Molecular weight of formed polymer can be increased in this stage by using base or acid catalyzed polymerizations. Procedure for acid catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloromethane, xylene, chloroform, diethyl ether, ethyl acetate, methyl-isobutyl ketone. Into the solution material solution is added catalytic amount of acid such as: triflic acid, monofluoro acetic acid, trifluoro acetic acid, trichloro acetic acid, dichloro acetic acid, monobromo acetic acid. The solution is refluxed for few hours or until polymerization is reached desired level while water formed in the reaction is removed. After polymerization, acid catalyst is removed from the material solution completely for example using solvent extraction or other methods described in alternative neutralization section. Finally, solvent is removed. Procedure for base catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, di-chloromethane, xylene, chloroform, diethyl ether, ethyl acetate, methyl-isobutyl ketone. Into the solution material solution is added catalytic amount of base such as: triethanol amine, triethyl amine, pyridine, ammonia, tributyl ammonium hydroxide. The solution is refluxed for few hours or until polymerization is reached desired level while water formed in the reaction is removed. After polymerization, base catalyst is removed from the material solution completely for example by adding acidic water solution into the material solution. After that acidic solution is neutralized using solvent extraction or other methods described in alternative neutralization section. Finally, solvent is removed.

Stabilization. In the place of THF and cyclohexanone can be used pure or mixture of following solvents: cyclopentanone, 2-propanol, ethanol, methanol, 1-propanol, tetrahydrofuran, methyl isobutyl ketone, acetone, nitromethane, chlorobenzene, dibutyl ether, cyclohexanone, 1,1,2,2-tetrachloroethane, mesitylene, trichloroethanes, ethyl lactate, 1,2-propanediol monomethyl ether acetate, carbon tetrachloride, perfluoro toluene, perfluoro p-xylene, perfluoro iso-propanol, cyclohexanone, tetraethylene glycol, 2-octanol, dimethyl sulfoxide, 2-ethyl hexanol, 3-octanol, diethyleneglycol butyl ether, diethyleneglycol dibutyl ether, diethylene glycol dimethyl ether, 1,2,3,4-tetrahydronaphtalene or trimethylol propane triacrylate. The material solution can be acidified using following acids: acetic acid, formic acid, propanoic acid, monofluoro acetic acid, trifluoro acetic acid, trichloro acetic acid, dichloro acetic acid, monobromo acetic acid. Also following basic compounds can be added into the material solution: triethyl amine, triethanol amine, pyridine, N-methylpyrrolidone.

Initiators: Photoinitiators that can be used are Irgacure 184, Irgacure 500, Irgacure 784, Irgacure 819, Irgacure 1300, Irgacure 1800, Darocure 1173 and Darocure 4265. The initiator can be highly fluorinated, such as 1,4-bis(pentafluorobenzoyl)benzene or Rhodosil 2074. Thermal initiators which can be used are benzoyl peroxide, 2,2′-azobisisobutyronitrile, 1,1′-Azobis(cyclohexanecarbonitrile), tert-butyl hydroperoxide, Dicumyl peroxide and Lauroyl peroxide.

Example I above is but one example of a method comprising: reacting a compound of the general formula R1MX³₃ with a compound of the general formula R2MX³₃ where R1 is selected from alkyl, alkenyl, aryl and alkynyl, R2 is selected from alkenyl, aryl or alkynyl, M is an element selected from groups 3-6 or 13-16 though preferably from group 14 of the periodic table, and X³ is a halogen; with H₂O or D₂O; so as to form a compound having a molecular weight of from 500 to 100,000 with a -M-O-M-O— backbone with R1 and R2 substituents on each M. In the hydrolysis example above, silicon atoms of the network are modified by pentafluorophenyl and trifluorovinyl groups in an approximate ratio 1:1. Of course other ratios are possible depending upon the ratio of starting materials, and, of course, other three dimensional networks can be achieved by having other (or additional) starting materials selected from Compound IV, VII and IX, along with other hydrolyzable materials. An alternate example is a method comprising: reacting a compound of the general formula R1R2MX³₂ where R1 is selected from alkyl, alkenyl, aryl and alkynyl, R2 is selected from alkenyl, aryl or alkynyl, M is an element selected from group 14 of the periodic table, and X³ is a halogen; with D₂O; so as to form a compound having a molecular weight of from 500 to 100,000 with a -M-O-M-O— backbone with R1 and R2 substituents on each M. As mentioned above, Compounds IV, VII and IX have organic (or hybrid) R group(s) and halogen(s) (preferably Br or Cl) bound to M (selected from groups 3-6 or 13-16—preferably group 14)) and can be combined in almost limitless combinations—e.g., a compound selected from the Compound IV group could be hydrolyzed with another compound selected from Compound IV. In another example, a single compound from Compound VII is hydrolyzed. Many other combinations are possible, including: Compound IV+Compound VII; Compound IV+Compound IV

+Compound IV; Compound VII+Compound VII; Compound IV+Compound VII+Compound IX; Compound IV+Compound IV+Compound IX; Compound VII+Compound IX, etc.—which various combinations of compounds will result in a hydrolyzed material having at least one organic substituent bound to an inorganic oxide backbone—preferably from 2 to 6 different organic substituents bound to the backbone prior to deposition and exposure. The presence of the organic groups, preferably all fluorinated, allows for improved optical absorption characteristics due to minimal or absent C—H bonds in the deposited material (preferably the hydrolyzed/condensed material has a hydrogen content of 10% or less, preferably 5% or less, and more preferably 1% or less).

Also, though “M” in the above hydrolysis example is silicon, it is possible to have materials with other M groups, or “dope” one or more silanes to be hydrolyzed with a lesser (though not necessarily lesser) amount of a compound having a different M group such as boron, a metalloid and/or an early transition metal (e.g., B, Al, Si, Ge, Sn, Sb, Pb, Ta, Ti, Zr, Er, Yb and/or Nb). As an example, a material could be formed from hydrolyzing/condensing one or more compounds each formed of silicon, chlorine and one or more fluorinated organic compounds bound to the silicon, whereas another material could be formed by hydrolyzing/condensing such compound with one or more additional compounds that each comprise an element other than silicon (Ge, Nb, Yb etc.), chlorine and one or more fluorinated organic groups. In this way, the inorganic backbone of the hydrolyzed/condensed material will comprise silicon, oxygen and the element(s) other than silicon, with fluorinated organic groups bound to this backbone.

Though halogen (e.g., chlorine) and alkoxy (e.g., ethoxy) groups are disclosed herein as the groups bound to the “M” group (e.g., silicon) via which hydrolysis occurs, it should be noted that for some of the compounds mentioned herein, an OH group could be bound to M followed by hydrolysis and deposition as will be discussed below.

### Polycycloalkyl-Substituted Siloxane Example

In another embodiment of the present invention, a large portion of an organic moiety is incorporated into a hybrid organo-silsequioxane polymer, novel low dielectric constant polymer films having excellent mechanical and thermal properties can be obtained. Such materials are preferably produced from polycycloalkyl-substituted siloxanes, in particular from polycycloalkyl-substituted siloxanes, which are substantially free of any oxygenate impurities that may impair the dielectric properties of the dielectric material.

Polycycloalkyl siloxane precusors used according to the invention for producing dielectric polymer are typically compounds, which comprise an organic moiety, formed by at least two rings. Preferably the organic moiety comprises a plurality of rings, e.g. three or more aliphatic rings, formed by covalently bound atoms, which define a volume. Such compounds can be called “cage” compounds in the sense that a straight line draw between any point within the volume to any point outside the compound will always pass through one ring of the molecule. The precursors comprise an inorganic moiety formed by a silicon atom, which is bound to the organic moiety either directly or indirectly through a linker compound. Further the silicon atom bears at least one cleavable inorganic substituent, which will form a leaving group when the precursor is polymerized, or a proton. The substituent can be cleaved, in particular, by hydrolysis.

According to a preferred embodiment, the precursor has the general formula I

(R¹—R²)ₙ—Si—(X¹)₄₋ₙ, I

wherein
each X¹ is independently selected from hydrogen and inorganic leaving groups,
R₂ is an optional group and comprises alkylene having 1 to 6 carbon atoms or arylene,
R₁ is a polycycloalkyl group and
n is an integer 1 to 3

Of the above compounds, adamantyl trihalosiloxane and adamantyl silane are particularly interesting because they can now be economically produced at high yield and purity by a novel chemical process involving as a key intermediate adamantyl dehydrate having the formula

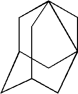

Specific preferred compounds include the following: adamantyl trichlorosilane, adamantylpropyl trichlorosilane, 3,5,7-trifluoroadamantyl trichlorosilane, 3,5,7-drifluoromethyladamantyl trichlorosilane and adamantylphenyl trichlorosilane.

In this polycyclic alkyl siloxane example, orientational and electronic polarizabilities result in a lower total dielectric constant than know in the prior art. Especially, this example relates to the use of organo-rich moieties that reduces the relative content of permanent dipoles in the film of the formed film matrix. In siloxane, the permanent dipoles of the polymers are mainly due to oxygen atoms in Si—O—Si bridges. When silane precursors containing polycyclic alkyl moieties are used for the formation of siloxane polymers, the organic content of the film is increased and, therefore, the content of carbon related oxygen is significantly reduced compared to siloxane polymers formed from precursors containing small alkyl groups. Examples of the latter kind of precursors are the methyl-substituted siloxanes. By “polycyclic alkyl moiety” we mean, for example, an adamantyl group or a similar cage compound, which is attached to silicon by (at least one) covalent bond. Thus, for example, if each silicon atom in the deposition polymer matrix contains one relative large organic group, in case of adamantyl, the atomic ratio of carbon to oxygen is increased. Thus, a conventional siloxane polymer contains significantly more permanent dipoles than a siloxane polymer made of adamantyl containing precursors. This difference in the content of permanent dipoles affects orientational polarizability so that the orientational dielectric constant can be as low as 0.3 to 0.2 for the siloxane materials made of adamantyl substituted precursors whereas an orientational dielectric constant for conventional siloxane low-k material is typically 0.7 or higher.

On the other hand, higher carbon content materials have a tendency of yielding a higher electronic polarizability especially when carbon is non-fluorinated carbon. Therefore, for example, an adamantyl siloxane polymer, in which each silicon atom contains one adamantyl group, gives an electronic dielectric constant of 2.25, whereas a similar polymer having a methyl group attached to the silicon instead results in an electronic dielectric constant of 1.89, provided that both of the materials are fully dense. It is preferable to use compositions in which the sum of electronic and orientational polarizabilities is minimized.

Therefore, according to this embodiment of the present invention, organosiloxane polymers made of adamantyl and methyl residues containing precursors at specific molar ratios are provided. Six compositional examples including their electronic dielectric, orientational dielectric and total dielectric constants with variable adamantyl and methyl concentrations in the organosiloxane polymer are reported in Table 1. The material compositions are presented in molar ratios as in the deposition polymer stage. All compositions have an intramolecular porosity of approximately 15%.

TABLE 1

| | | | | Organic content | Carbon content | Oxygen content |
|---|---|---|---|---|---|---|
| Material | Electronic k | Orientational k | Total k | (wt-%) | (at-%) | (at-%) |
| 100 adamantyl-0 methyl | 1.92 | 0.31 | 2.43 | 72.2 | 36.4 | 5.5 |
| 75 adamantyl-25 methyl | 1.86 | 0.335 | 2.4 | 66.9 | 34.8 | 6.7 |
| 50 adamantyl-50 methyl | 1.8 | 0.37 | 2.37 | 59.1 | 32.4 | 8.8 |
| 30 adamantyl-70 methyl | 1.78 | 0.35 | 2.33 | 49.5 | 28.9 | 11.7 |
| 25 adamantyl-75 methyl | 1.74 | 0.43 | 2.37 | 46.4 | 27.7 | 12.8 |
| 0 adamantyl-100 methyl | 1.68 | 0.55 | 2.43 | 22.4 | 15.4 | 23.1 |

As will appear from the table, particularly good results are obtained when the organic content is in the range of 30 to 70 wt.-%, preferably about 40 to 60 wt.-%.

Similar results are obtained when polycyclic alkyl siloxanes are used as comonomers in combination with other alkyl siloxane derivatives as well as with vinyl siloxanes and aryl siloxanes (such as phenyl siloxane) and with mixtures thereof, e.g. with methyl, vinyl, phenyl.siloxanes. As disclosed in the examples below, dielectric materials having interesting properties are obtained using about 10 to 50 mole-% of polycyclic alkyl siloxanes, about 30 to 80 mole-% alkyl siloxanes (in particular methyl siloxanes) and the rest, typically about 5 to 30 mole-% vinyl siloxanes/aryl siloxanes.

Thus, in general, the present invention provides novel polymer materials useful as low-k materials in dielectric applications, said materials comprising copolymers formed by copolymerisation of at least one comonomer having the formula

(R³—R⁴)ₙ—Si—(X²)₄₋ₙ, II

wherein
X² is hydrogen or a hydrolysable group selected from halogen, acyloxy, alkoxy and OH groups,
R⁴ is an optional group and comprises an alkylene having 1 to 6 carbon atoms or an arylene and
R³ is an alkyl having 1 to 16 carbon atoms, an alkenyl having from 2 to 16 carbon atoms, a cycloalkyl having from 3 to 16 carbon atoms, an aryl having from 5 to 18 carbon atoms or a polycyclic alkyl group having from 7 to 16 carbon atoms,
and
n is an integer 1-3,
with at least one of the following silicon compounds:
a) a silicon compound having the general formula III

X³₃₋ₐ—SiR⁵_{b}R⁶_{c}R⁷_{d} III

wherein X³ represents a hydrolyzable group; R⁷ is an alkenyl or alkynyl group, which optionally bears one or more substituents; R⁵ and R⁶ are independently selected from hydrogen, substituted or non-substituted alkyl groups, substituted or non-substituted alkenyl and alkynyl groups, and substituted or non-substituted aryl groups; a is an integer 0, 1 or 2; b is an integer a+1; c is an integer 0, 1 or 2; d is an integer 0 or 1; and b+c+d=3.
b) a silicon compound having the general formula IV

X⁴₃₋ₑ—SiR⁸_{f}R⁹_{g}R¹⁰ₕ IV

wherein X⁴ represents a hydrolyzable group; R⁸ is an aryl group, which optionally bears one or more substituents; R⁹ and R¹⁰ are independently selected from hydrogen, substituted or non-substituted alkyl groups, substituted or non-substituted alkenyl and alkynyl groups, and substituted or non-substituted aryl groups; e is an integer 0, 1 or 2; f is an integer e+1; g is an integer 0, 1 or 2; h is an integer 0 or 1; and f+g+h=3; and
c) a silicon compound having the general formula V

X⁵₃₋ᵢ—SiR¹¹ⱼR¹²ₖR¹³ₗ V

wherein X⁵ represents a hydrolyzable group; R¹¹ is a hydrogen or an alkyl group, which optionally bears one or more substituents; R¹² and R¹³ are independently selected from hydrogen, substituted or non-substituted alkyl groups, substituted or non-substituted alkenyl or alkynyl groups, and substituted or non-substituted aryl groups; i is an integer 0, 1 or 2; j is an integer i+1; k is an integer 0, 1 or 2; l is an integer 0 or 1; and j+k+I=3,
with the proviso that copolymerization is carried out using at least one comonomer having the formula II, wherein R³ is a polycyclic alkyl group having from 7 to 16 carbon atoms, in particular 9 to 15 carbon atoms.

Compounds corresponding to the above compounds a) to c) can also be designated by the more restricted general formula VI,

(R³—R⁴)ₙ—Si—(X²)₄₋ₙ, VI

wherein
X² is hydrogen or a hydrolysable group selected from halogen, acyloxy, alkoxy and OH groups,
R⁴ is an optional group and comprises an alkylene having 1 to 6 carbon atoms or an arylene and
R³ is an alkyl having 1 to 16 carbon atoms, an alkenyl having from 2 to 16 carbon atoms, a cycloalkyl having from 3 to 16 carbon atoms or an aryl having from 5 to 18 carbon atoms,
and
n is an integer 1-3.

The alkyl groups of R³ have typically 1 to 6 carbon atoms, the vinyl groups have from 2 to 6 carbon atoms, and the aryl groups have 6 carbon atoms.

The molar ratio between monomeric units derived from compounds according to formula II and one or several monomeric unit derived from compounds of a formula III to VI is in the range of 25:75 to 75:25.

Compounds a) to c) are disclosed in more detail in our copending patent application PCT/FI03/00036, the disclosure of which is herewith incorporated by reference.

The present invention also relates to the use of readily hydrolysable adamantyl materials in organosilsesquioxane polymers for forming low-k dielectrics. Precursors within the scope of the present invention include easily hydrolysable organochlorosilanes or organosilanes that result in better polymerization degrees than the similar organo-alkoxysilanes.

In connection with this embodiment of the invention, we have found that organoalkoxysilanes have a tendency of leaving residual alkoxides in the material matrix. Such residues greatly impair the use and properties of the materials in particular as regards their dielectric properties. If residual alkoxides remain in the matrix, they tend to react over time and change the properties of materials by forming contaminating alcohol and water into the matrix. These oxygenates impair dielectric and leakage current behavior of the material. In addition, residual alkoxides, such as ethoxide-based materials, cause a dangling bond effect that causes higher leakage current for the material. Moreover, alkoxy-based materials result in higher porosity and lower Young's modulus and hardness compared to well hydrolysable organochlorosilane and organosilanes. Therefore, the course of the invention is to utilize more easily hydrolysable organosilanes for dielectric thin film purposes.

The new polycycloalkyl siloxane precusors used according to the invention have the general formula I

(R¹—R²)ₙ—Si—(X¹)₄₋ₙ, I

wherein
each X¹ is independently selected from hydrogen and inorganic leaving groups,
R² is an optional group and comprises alkylene having 1 to 6 carbon atoms or arylene,
R¹ is a polycycloalkyl group and
n is an integer 1 to 3

By polymerizing a compound of formula I, a polymeric material is obtained which, in practice, is “free of silanols”. This means, typically, that they have a silanol content of less than 0.5 wt-%.

The polymers for preparing the low dielectric constant material have an organic content of about 30 to 70 wt.-%, preferably higher than 48 wt-%.

The polycyclic alkyl group has from 9 to 16 carbon atoms, and it comprises preferably a cage compound (as defined above). Typical examples of such compounds are adamantyl and diadamantyl. The adamantyl or diadamantyl ring structure can be substituted with 1 to 3 alkyl substitutents, which optionally carry 1 to 6 halogen substitutents, e.g. chloro, fluoro or bromo.

In compounds according to formula I, the inorganic leaving group is preferably selected from halogens, such as chlorine, bromine or fluorine.

In the compounds according to the above formulas I and II, respectively,

R³ is preferably selected from alkyl groups having 1 to 6 carbon atoms, alkenyl groups having from 2 to 6 carbon atoms, and aryl groups having 6 carbon atoms;
R¹ or R³, respectively, is directly bonded to the silicon atom; and
R¹ or R³, respectively, is bonded to the silicon atom via an alkylene chain, in particular an alkylene chain selected from methylene, ethylene and propylene, or an arylene group, in particular phenylene.

As discussed above, compounds of formula I, which are a part of the compound of formula II, can be copolymerized with other monomers, such as the monomers of one or several of formulas II to VI.

The molar ratio between monomeric units derived from comonomers according to formula I and of formula II, is preferably in the range of 25:75 to 75:25.

However, it is also possible to produce polymers useful as dielectric, low-k materials by homopolymerization of compounds of the formula I.

The present invention provides novel poly(organosiloxane) materials, which can be hydrolyzed and condensed (alone or with one or more other compounds) into a hybrid material having a (weight average) molecular weight of from 500 to 100,000 g/mol. The molecular weight can be in the lower end of this range (e.g., from 500 to 5,000 g/mol, or more preferably 500 to 3,000 g/mol) or the hybrid material can have a molecular weight in the upper end of this range (such as from 5,000 to 100,000 g/mol or from 10,000 to 50,000 g/mol). In addition, it may be desirable to mix a hybrid material having a lower molecular weight with a hybrid material having a higher molecular weight. The hybrid material can be suitably deposited such as by spin-on, spray coating, dip coating, or the like, as will be explained in more detail below.

### Polycyclic Example 1

### Precursor Material

### Adamantyltrichlorosilane C₁₀H₁₅SiCl₃

### Preparation Steps:

C₁₀H₁₆+2Br₂→1,3-C₁₀H₁₄Br₂+2HBr 1.

1,3-C₁₀H₁₄Br₂+2Li→C₁₀H₁₄+2LiBr 2.

C₁₀H₁₄+HSiCl₃→C₁₀H₁₅SiCl₃ 3.

106.4 g of (0.781 mol) adamantane C₁₀H₁₆ was added to a 2000 ml vessel followed by 500 ml dichloromethane. The solution was heated up to 40° C. and 92 ml (286.95 g, 1.80 mol) bromine was added to the vessel followed by a small amount of FeBr₃ as catalyst. The solution was stirred at 40° C. for 15 hours.

Refluxing was stopped and solution washed with 500 ml of dilute HCl. A sodium thiosulfate solution was added to the vessel until the colour changed from red to brown. The organic layer was separated and evaporated to dryness. Crude 1,3-C₁₀H₁₄Br₂ was dissolved in hot n-hexane and filtered. The filtrate was placed in a refrigerator and crystallized; the obtained, purified 1,3-C₁₀H₁₄Br₂

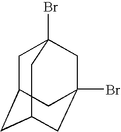

was filtered and dried in vacuum. Yield 192 g (84%).

58 g metallic lithium was added to a 2000 ml vessel followed by 500 ml Et₂O. 192 g (0.656 mol) adamantyl di-bromide was dissolved in 1000 ml Et₂O and the solution was added to the Li/Et₂O solution at room temperature during an hour. The obtained solution was stirred for 15 hours at room temperature.

Then, the solution was decanted and Et₂O evaporated. Adamantyl dehydrate was extracted from the remaining solid material by 3×200 ml n-pentane. n-pentane was evaporated. The remaining 1,3-dehydroadamantane

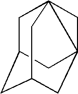

was used without further purification.

It was placed in a 1000 ml vessel and followed by 600 ml HSiCl₃ and 100 μl Speier's catalyst (H₂PtCl₆ in alcohol). The solution was heated up to 40° C. for two hours. After that, excess HSiCl₃ was distilled off and the remaining CioH₁₅SiCl₃

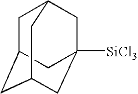

was purified by distillation. B.p. 95° C./1 mbar. Yield 123 g.

Adamantylsilane, an optional precursor, was manufactured as a derivative of adamantyl trichlorosilane.

Lithium aluminum hydride (6.18 g) and dry ether (80 mL) were placed in a rb flask. Adamantyl trichlorosilane (50.8 g), dissolved in ether (50 mL) was added dropwise in the magnetically stirred flask at rt. The reaction was allowed to reflux for 24 h. The solution was filtered, evaporated, and 1 mL Et₃N in 30 mL pentane was then added and the upper layer was carefully decanted. After evaporation, the crude reaction product was distilled, giving 22 g of adamantylsilane (70%, bp. 40 . . . 50° C./2 mbar). ¹H NMR: 1.95 (15H), 3.68 (3H). ¹³C NMR: 20.63, 28.86, 37.99, 40.61. ²⁹Si NMR: −43.55 (q, Si—H: 190 Hz). Purity was found to be 95.7% by GC.

Adamantylchlorosilylbis(dimethylamine), another optional precursor, was manufactured as a derivative of adamantyl trichlorosilane.

Adamantyltrichlorosilane (5.59 g), Et₃N (9.5 g) and dry ether (40 mL) were placed in a rb flask. Dimethylamine (3.05 g) was slowly bubbled into the solution at 0° C. in 45 minutes. The reaction was allowed to stir for 18 hours at rt. It was then filtered, and volatiles were removed by vacuum. Distillation at 88 . . . 98° C./1 mbar gave a fraction 4.54 g (76%). Purity was 97% by GC. GC/MS (m/z): 296 (62, [M]^{+),} 243 (42), 151 (100), 135 (43), 108 (33), 79 (17), 74 (37). ¹H NMR: 1.99 (3H), 2.08 (6H), 2.19 (6H), 2.74 (12H). ¹³C NMR: 28.63, 38.29, 39.07, 48.68. 14N NMR: −373.9. 29Si NMR: −10.16.

Other applicable precursors include (but are not limited to) the following:

| | | |
|---|---|---|
| (#2) | 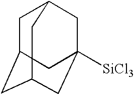 | Adamantyl trichlorosilane |
| (#3) | 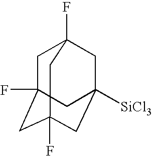 | 3,5,7-trifluoroadamantyl trichlorosilane |
| (#4) | 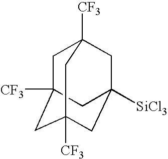 | 3,5,7-trifluoromethyl- adamantyl trichlorosilane |
| (#5) | 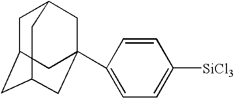 | Adamantylphenyl trichlorosilane |

In addition, an interesting precursor compound is formed by adamantylpropyl trichlorosilane.

### Polycyclic Example 2

### Polymer Preparation

### Material 1

Preparation of adamantysilanol intermediate. 7.0 g of adamantyltrichlorosilane (0.02595 mol) was dissolved in 56 ml acetone. The solution was transferred drop by drop into a solution containing acetone (70 ml), triethylamine (9.19 g, 0.0908 mol) and water (4.67 g, 0.2595 mol) within 20 min. During addition, the solution was vigorously mixed and the temperature of solution was maintained at room temperature (20° C., water bath). White precipitate was formed. After addition, the solution was mixed for an additional 20 hours at room temperature.

The solution was dried to dryness with a rotary evaporator (30° C., 200 mbar). 50 ml water was added and stirred for 10 min. After this, the solution was filtrated and the white powder obtained was flushed three times with 25 ml of water. The powder was dried under vacuum (40° C., 1 mbar), whereby 5.14 g of adamantylsilanol material was obtained that contained monomeric and oligomeric compounds.

Preparation of low-k resin. 5.0 g of adamantylsilanol was dissolved in 17.4 ml N,N-dimethylacetamide (DMAc) at 65° C. and the solution was cooled to room temperature. The solution was transferred drop by drop into a solution containing methyltrichlorosilane (15.8 g, 0.106 mol), vinyltrichlorosilane (2.0 g, 0.0123 mol), diethyl ether (77 ml), and

triethylamine (8.7 g, 0.0867 mol) within 15 min. During addition, the solution was vigorously mixed and the temperature of the solution was maintained at room temperature (20° C., water bath). After addition, the solution was mixed for 1 hour at room temperature.

The obtained solution was dried to dryness under vacuum (40° C., 1 mbar, 30 min). 77 ml of dichloromethane (DCM) was then added and the solution was placed in ice bath. 22 ml of hydrochloric acid (37%) was added drop by drop within 30 min. After that, the reaction mixture was stirred for 90 min at a temperature below 5° C. and at room temperature for 60 min.

The DCM phase was allowed to separate and was removed. HCl/water phase washed two times with 30 ml of DCM. DCM solutions were combined and extracted 8 times with 500 ml of water (pH 6). The combined DCM solution thus obtained was dried into dryness with a rotary evaporator (40° C., 10 mbar, 45 min) and finally at high vacuum (20° C., 1 mbar, 2 h). 6.0 g of material was obtained. Molecular weight (Mₚ) of the material was 17900 g/mol, determined by gel permeation chromatography (GPC) against commercially available narrow polystyrene standards

The polymeric material was dissolved in 140 ml toluene containing 1 wt. % triethylamine. The solution was refluxed for 2 hours and then dried to dryness with a rotary evaporator (60° C., 10 mbar, 40 min) and finally with high vacuum (20° C., 1 mbar, 2 h). 5.78 g of material was obtained. Molecular weight (Mₚ) was 26 080 g/mol measured by GPC. ¹H NMR showed the composition being 23 mole-% for adamantyl, 66 mole-% for methyl, and 11 mole-% for vinyl repeating units. T₀ was 460° C. and weight loss between 400-500° C. (heating rate 5° C./min) was 2.7% measured by thermal gravimetric analysis (TGA).

### Polycyclic Example 3

### Polymer Material 1A—Alternative Method

Preparation of Adamantylsilanol Intermediate. Preparation of Adamantylsilanol was Made Similarly as in Example 2, but tetrahydrofuran (THF) was used instead of acetone. Thus, 7.0 g of adamantyltrichlorosilane (0.02595 mol) was dissolved in 21 ml THF. The solution was transferred drop by drop into a solution containing THF (70 ml), triethylamine (9.19 g, 0.0908 mol), and water (4.67 g, 0.2595 mol) within 20 min. During addition, the solution was vigorously mixed and the temperature of the solution was maintained at room temperature (20° C., water bath). White precipitate was formed. After addition, the solution was mixed for a further 22 hours at room temperature.

The solution was dried to dryness with a rotary evaporator (35° C., 170 mbar). 50 ml water was added and stirred for 10 min. After this, the solution was filtrated and the obtained white powder was flushed three times with 25 ml of water. The powder was dried under vacuum (40° C., 1 mbar). 4.62 g of adamantylsilanol material was obtained that contained monomeric and oligomeric compounds.

### Polycyclic Example 4

### Polymer Material 1B—Alternative Method

9.75 g of adamantylsilanol prepared in Example 1 was dissolved in 34 ml N,N-dimethylacetamide (DMAc) at 65° C., and the solution was cooled to room temperature. The solution was transferred drop by drop into a solution containing methyltrichlorosilane (30.1 g, 0.201 mol), vinyltrichlorosilane (4.3 g, 0.026 mol), diethyl ether (146 ml), and triethylamine (16.6 g, 0.164 mol) within 30 min. During addition, the solution was vigorously mixed and the temperature of the solution was maintained at room temperature (20° C., water bath). After addition, the solution was mixed for a further 3 hours at room temperature.

The solution was dried into dryness under vacuum (40° C., 1 mbar, 2 h). 150 ml of dichloromethane (DCM) was added and the solution thus obtained was placed in ice bath. 36 ml of hydrochloric acid (37%) was added drop by drop within 60 min. After the addition of the hydrochloric acid, the reaction mixture was stirred for 90 min below 5° C. and for 24 h at room temperature.

The DCM phase was allowed to separate and was collected. HCl/water phase washed two times with 60 ml of DCM. The DCM solutions were combined and extracted with 10 times with 200 ml of water (pH 6). The combined DCM solution was dried to dryness with a rotary evaporator (40° C., 10 mbar, 60 min) and finally under vacuum (20° C., 1 mbar, 60 min). 11.6 g of material was obtained. Molecular weight (Mₚ) was 27610 g/mol measured by gel permeation chromatography (GPC).

The material was dissolved in 232 ml toluene containing 1 wt. % triethylamine. The solution was refluxed (oil bath temperature 150° C.) for 2 hours and then dried to dryness with a rotary evaporator (60° C., 10 mbar, 60 min) and finally with high vacuum (20° C., 1 mbar, 2 h). 11.8 g of material was obtained. Molecular weight (Mₚ) was 30500 g/mol, measured by GPC. ¹H NMR showed the composition being 27 mole-% for adamantyl, 62 mole-% for methyl, and 11 mole-% for vinyl repeating units. T₀ was 460° C. and weight loss between 400-500° C. (at a heating rate of 5° C./min), was 3.2% measured by thermal gravimetric analysis (TGA).

### Polycyclic Example 5

### Polymer Material 1C—Alternative Method

3.6 g of low molecular weight material prepared in Example 3 was dissolved in 18 ml xylene containing 4 wt. % triethylamine. The solution was refluxed for 3 hours. Then, it was dried to dryness with a rotary evaporator (70° C., 10 mbar, 30 min) and finally with high vacuum (70° C., 1 mbar, 2 h). 3.45 g of material was obtained. The molecular weight (Mₚ) was 46880 g/mol, measured by GPC.

### Polycyclic Example 6

### Comparative Material 2B

A comparative material 2B was prepared having a similar compositional structure as polymer material 1B, but using organotrialkoxysilanes as precursors instead of the corresponding trichlorosilanes of Example 4. Thus, adamantyltriethoxysilanesilane, methyltriethoxysilane, and vinyltriethoxysilane were used in ratios that yielded similar final compositional concentrations of organo-functional moieties in the final polymer as presented in Example 4 for Polymer Material 1B. The precursors were dissolved in acetone and the solution thus obtained was placed in ice bath and 9.52 g of 0.5 M hydrochloric acid was added drop by drop within 50 min. During addition, the solution was vigorously stirred. After the addition, the solution was refluxed for another 3 hours. An excess amount of toluene was added and acetone was evaporated. An excess amount of water was added and the solution was allowed to stir for 10 minutes at room temperature. The toluene phase was allowed to separate and was removed. The solution was dried to dryness with a rotary evaporator and, finally, with high vacuum.

Material was dissolved in an extensive amount of toluene containing 1 wt. % triethylamine. The solution was refluxed for 1 hour, dried to dryness with rotary evaporator and finally with high vacuum. A homogenous polymer with yield of 65% was obtained. Molecular weight (Mₚ) was 21840 g/mol measured by GPC.

### Polycyclic Example 7

### Processing and Testing of Example Materials

### Test Film IA

A test film was prepared from material 1B disclosed in Example 4 using spin-on deposition by applying 3000 rpm spinning speed and resulting in 500 nm thick film. The film was deposited on a n-type silicon wafer and pre-cured on a hot-plate for 5 minutes at 200° C. prior to final in a furnace treatment. The furnace anneal was done under nitrogen gas flow at 450° C. for 60 minutes. Dielectric constants were measured from MOS-capacitor (metal-insulator-semiconductor structure) type device. Applied measurement frequency was 100 kHz. Porosity was measured with porosity ellipsometer and Young's modulus and hardness by nanoindentation.

### Test Film IB

A test film was prepared from material 1B explained in Example 4 by spin-on deposition by applying a 3000 rpm spinning speed and resulting in a 500 nm thick film. The film was deposited on an n-type silicon wafer and precured on a hot-plate for 5 minutes at 200° C. prior to final treatment byrapid thermal anneal treatment. The rapid thermal anneal was done under vacuum at 450° C. for 5 minutes and a 30° C./second temperature ramp rate was utilized. Dielectric constants were measured from a MOS-capacitor (metal-insulator-semiconductor structure) type device. The applied measurement frequency was 100 kHz. Porosity was measured with porosity ellipsometer and Young's modulus and hardness by nanoindentation.

### Test Film IIA

A test film was prepared from material 2B explained in Example 6 by spin-on deposition by applying a 3000 rpm spinning speed and resulting in a 500 nm thick film. The film was deposited on an n-type silicon wafer and precured on a hot-plate for 5 minutes at 200° C. prior to final curing byfurnace treatment. The furnace anneal was done under nitrogen gas flow at 450° C. for 60 minutes. Dielectric constants were measured from a MOS-capacitor (metal-insulator-semiconductor structure) type device. The applied measurement frequency was 100 kHz. Porosity was measured with porosity ellipsometer and Young's modulus and hardness by nanoindentation.

### Test Film IIB

A test film was prepared from material 2B explained in Example 6 by spin-on deposition by applying a 3000 rpm spinning speed and resulting in a 500 nm thick film. The film was deposited on an n-type silicon wafer and precured on a hot-plate for 5 minutes at 200° C. prior to final curing byrapid thermal anneal treatment. The rapid thermal anneal was done under vacuum at 450° C. for 5 minutes and a 30° C./second temperature ramp rate was utilized. Dielectric constants were measured from a MOS-capacitor (metal-insulator-semiconductor structure) type device. The applied measurement frequency was 100 kHz. Porosity was measured with porosity ellipsometer and Young's modulus and hardness by nanoindentation.

The results of the tested films are summarized in Table 2:

TABLE 2

| | Dielectric | | Young's | | Leakage |
|---|---|---|---|---|---|
| | constant | | modulus | Hardness | current |
| Film | (10 kHz) | Porosity % | Gpa) | (GPa) | (nA/cm2) |
| I.A. | 2.53 | 8 | 6.9 | 0.52 | 0.03 |
| I.B. | 2.32 | 17 | 6.5 | 0.49 | 0.05 |
| II.A. | 2.62 | 13 | 6.4 | 0.32 | 0.7 |
| II.B. | 2.42 | 28 | 3.8 | 0.19 | 1.2 |

Clearly, based on the comparative data, it is advantageous to use organo-chlorosilanes and their derivatives as starting materials or precursors since they result in better electrical properties, such as lower dielectric constant, with lower porosity as well as better mechanical performance. The residual silanol levels are also lower in the case of using organo-chlorosilanes as precursors than can be observed as significantly lower leakage current in actual tested devices. The better overall performance of organo-chlorosilanes derives from the fact that they are easily hydrolysed and polycondensed and, thus, results in purer polymer network that is free of silanol type impurities.

### Substituted Cyclic Example

In this example of the invention, thin films comprising at least partially cross-linked siloxane structures are obtainable by hydrolysis of one or more silicon compounds of the general formula

R₁—R₂—Si—(X₁)₃,

wherein
X₁ is a leaving group,
R₂ is a cycloalkyl having from 3 to 16 carbon atoms, an aryl having from 5 to 18 carbon atoms or a polycyclic alkyl group having from 7 to 16 carbon atoms,
and
R₁ is a substituent of R₂ selected from alkyl groups having from 1 to 4 carbon atoms, alkenyl groups having from 2 to 5 carbon atoms, alkynyl groups having from 2 to 5 carbon atoms, and aromatic groups having 5 or 6 carbon atoms, each of said groups being optionally substituted, and halogens, such as Cl and F.

The poly(organo siloxane) compounds provided by the invention typically comprise a repeating Si—O backbone, carbon chain cross-linking groups and —R₁—R₂ bound to from 5% to 50% of the silicon atoms in the Si—O backbone. The Si—O-backbone can further comprise R₃ groups bound to the silicon atoms in the Si—O backbone, wherein R₃ is an alkyl chain having from 1 to 4 carbon atoms, an alkenyl chain or an aryl group.

Also in this example, a method of making an integrated circuit comprises providing alternating areas of electrically insulating and electrically conducting materials within a layer on a semiconductor substrate, wherein the electrically insulating material comprises a poly(organo siloxane) compound comprising a repeating Si—O backbone, carbon chain crosslinking groups and —R₁—R₂ bound to from 5% to 50% of the silicon atoms in the Si—O backbone, wherein R₂ is a cyclic group, such as a cycloalkyl having from 3 to 16 carbon atoms, an aryl having from 5 to 18 carbon atoms or a polycyclic alkyl group having from 7 to 16 carbon atoms, in particular an aromatic group having 6 carbon atoms, and R₁ is a substituent, in particular at position 4 of R₂, said substituent preferably being selected from an alkyl chain having from 1 to 4 carbons, an alkenyl group having from 2 to 6 carbons or OH.

Also within this example, there is provided a simplified method of making a chemical compound of the formula R₁—R₁Si—(X²)₃, wherein X₂ is a halogen, R₂ is an aromatic group having 5 to 18 carbon atoms, a cycloalkyl having from 3 to 16 carbon atoms, or a polycyclic alkyl group having from 7 to 16 carbon atoms, and R₁ is a substituent, in particular at position 4 of R₂, R₁ being selected from the group consisting of alkyl groups having from 1 to 4 carbon atoms, alkenyl groups having from 2 to 5 carbon atoms, and OH groups. The method comprises: reacting a compound of the formula R₁—R₂Br, wherein R₁ and R₂ have the same meaning as above, with Mg and with a compound of the formula Si—(OR₃)₄, wherein R₃ is an alkoxy group having from 1 to 3 carbon atoms, to form a compound of the formula R₁—R₂Si—(OR₃)₃, wherein R₁, R₂ and R₃ have the same meaning as above; reacting the thus obtained compound of the formula R₁—R₂—Si—(OR₃)₃ with a halogenating agent capable of replacing, preferably each, R₃ with a halogen substantially without affecting the rest of the compound of formula R₁—R₂—Si—(OR₃)₃ to produce a compound of the formula R₁—R₂—SiX², wherein R₁, R₂ and X² have the same meaning as above, and

recovering the thus obtained compound.

As an example of mildly halogenating (in particular “chlorinating”) agents, the combination of SO₂Cl₂ with pyridyl hydrochloride (C₅H₅N—HCl) can be mentioned.

According to a first substituted cyclic embodiment, the present invention comprises a chemical compound of the formula R1-R2-Si—(X¹)₃, wherein X¹ is a halogen, acyloxy, alkoxy or OH group, R2 is an aromatic group having 6 carbon atoms and R1 is a substituent at position 4 of R2 selected from an alkyl group having from 1 to 4 carbon atoms, an alkenyl group having from 2 to 5 carbon atoms, an alkynyl group having from 2 to 5 carbon atoms, Cl or F.

According to a second substituted cyclic embodiment, the present invention comprises a chemical compound of the formula R1-R2-Si—(X¹)₃, wherein X¹ is a halogen, acyloxy, alkoxy or OH group, R2 is an organic polycyclic or bridged ring structure with Si bound to carbon position 1, and R1 is a substituent at position 3 or higher of R2 selected from an alkyl group having from 1 or more carbons atoms, an alkenyl, an alkynyl, an acrylate, an aryl, an alcohol, OH, H, D, Cl or F.

According to a third substituted cyclic embodiment, the present invention comprises a chemical compound of the formula R1-R2-Si—(X¹)₃, wherein X¹ is a halogen, acyloxy, alkoxy or OH group, R2 is an aromatic group having 8 carbon atoms and R1 is a substituent at position 5 of R2 selected from an alkyl group having from 1 to 4 carbon atoms, an alkenyl group having from 2 to 5 carbon atoms, an alkynyl group having from 2 to 5 carbon atoms, Cl or F.

According to a fourth substituted cyclic embodiment, the present invention comprises a chemical compound of the formula R1-R2-Si—(X1)3, wherein X1 is a halogen, acyloxy, alkoxy or OH group, R2 is an aromatic group having 10 carbon atoms and R1 is a substituent at position 6 of R2 selected from an alkyl group having from 1 to 4 carbon atoms, an alkenyl group having from 2 to 5 carbon atoms, an alkynyl group having from 2 to 5 carbon atoms, Cl or F.

According to a fifth substituted cyclic embodiment, a poly(organo siloxane) compound comprises a repeating Si—O backbone, carbon chain crosslinking groups and —R1-R2 bound to from 5% to 50% of the silicon atoms in the Si—O backbone, wherein R2 is an aromatic group having 6 carbon atoms and R1 is a substituent at position 4 of R2.

According to a sixth substituted cyclic embodiment, a poly(organo siloxane) compound comprises a repeating Si—O backbone, —R1-R2 bound to from 25% to 50% of the silicon atoms in the Si—O backbone, wherein R2 is an aromatic group having 6 carbon atoms and R1 is a substituent at position 4 of R2 (again this could be drawn out for clarity), and R3 bound to from 5% to 50% of the silicon atoms, wherein R3 is an alkenyl group having from 2 to 5 carbon atoms, acrylic group or epoxy group.

According to a seventh substituted cyclic embodiment, a poly(organo siloxane) compound comprises a repeating Si—O backbone, carbon chain crosslinking groups and —R1-R2 bound to from 5% to 50% of the silicon atoms in the Si—O backbone, wherein R2 is polycyclic or bridged ring structure and R1 is a substituent at position 4 of R2 selected from an alkyl chain having from 1 to 4 carbons, H, D, F or OH.

According to an eight substituted cyclic embodiment, a poly(organo siloxane) compound comprises a repeating Si—O backbone, —R1-R2 bound to from 25% to 50% of the silicon atoms in the Si—O backbone, wherein R2 is a polycyclic or bridged ring structure and R1 is a substituent at position 4 of R2 selected from H, D, F, OH, an alkyl group having from 1 to 4 carbon atoms, and an alkenyl group having from 2 to 5 carbon atoms, and further comprising R3 bound to from 5% to 50% of the silicon atoms, wherein R3 is an alkenyl group having from 2 to 5 carbon atoms, acrylic group, aryl group or epoxy group.

According to a ninth substituted cyclic embodiment, a poly(organo siloxane) compound comprises a repeating Si—O backbone, carbon chain crosslinking groups and —R1-R2 bound to from 5% to 50% of the silicon atoms in the Si—O backbone, wherein R2 is an aromatic group having 8 carbon atoms and R1 is a substituent at position 5 of R2.

According to a tenth substituted cyclic embodiment, a poly(organo siloxane) compound comprises a repeating Si—O backbone, —R1-R2 bound to from 25% to 50% of the silicon atoms in the Si—O backbone, wherein R2 is an aromatic group having 8 carbon atoms and R1 is a substituent at position 5 of R2 (again this could be drawn out for clarity), and R3 bound to from 5% to 50% of the silicon atoms, wherein R3 is an alkenyl group having from 2 to 5 carbon atoms, acrylic group or epoxy group.

According to an eleventh substituted cyclic embodiment, a poly(organo siloxane) compound comprises a repeating Si—O backbone, carbon chain crosslinking groups and —R1-R2 bound to from 5% to 50% of the silicon atoms in the Si—O backbone, wherein R2 is an aromatic group having 10 carbon atoms and R1 is a substituent at position 6 of R2.

According to a twelfth substituted cyclic embodiment, a poly(organo siloxane) compound comprises a repeating Si—O backbone, —R1-R2 bound to from 25% to 50% of the silicon atoms in the Si—O backbone, wherein R2 is an aromatic group having 10 carbon atoms and R1 is a substituent at position 6 of R2 (again this could be drawn out for clarity), and R3 bound to from 5% to 50% of the silicon atoms, wherein R3 is an alkenyl group having from 2 to 5 carbon atoms, acrylic group or epoxy group.

The present substituted cyclic examples provide, for example, the following kinds of integrated circuits:

an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 6 carbon atoms and R1 is a substituent at position 4 of R2;
an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is a polycyclic or bridged ring structure and R1 is a substituent at position 4 of R2 selected from H, D, F, OH, an alkyl group having from 1 to 4 carbon atoms, and an alkenyl group having from 2 to 5 carbon atoms;
an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 8 carbon atoms and R1 is a substituent at position 5 of R2; and
an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 10 carbon atoms and R1 is a substituent at position 6 of R2.

A computer according to the invention comprises an integrated circuit of the above kind, having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 6 carbon atoms and R1 is a substituent at position 4 of R2). It can also have a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is a polycyclic or bridged ring structure and R1 is a substituent at position 4 of R2. Further, the integrated circuit of the computer can have a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is a polycyclic or bridged ring structure and R1 is a substituent at position 4 of R2.

A computer according to the invention can further comprise an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 8 carbon atoms and R1 is a substituent at position 5 of R2) or having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 10 carbon atoms and R1 is a substituent at position 6 of R2.

In the method for making an integrated circuit, alternating areas of electrically insulating and electrically conducting materials within a layer on a semiconductor substrate, wherein the electrically insulating material comprises any of the above poly(organo siloxane) compounds.

The chemical compounds of the formula R1-R2-Si—(X2)3, wherein X2 is a halogen or an alkoxy group, R2 is an aromatic group having 6 carbon atoms and R1 is a substituent at position 4 of R2, R1 being selected from an alkyl group having from 1 to 4 carbon atoms, an alkenyl group having from 2 to 5 carbon atoms, or OH, can be produced by a (Grignard-type) process comprising the steps of:

reacting R1-R2—Br with Mg and Si—(OR3)₄ to form R1-R2-Si—(OR3)3+BrMgOR, where R1 is selected from an alkyl group having from 1 to 4 carbon atoms, an alkenyl having from 2 to 5 carbon atoms, R2 is an aromatic or non-aromatic ring structure having from 5 to 7 carbon atoms, and R3 is an alkoxy group having from 1 to 3 carbon atoms; and
reacting R1-R2-Si—(OR3)3 with 3SO2Cl2 in the presence of C5H5N—HCl to yield R1-R2-SiCl3+3SO2+3EtCl.

Such a process can be used for preparing a chemical compound of the formula R1-R2-Si—(X²)₃, wherein X² is a halogen or alkoxy group, R2 is an aromatic group and R1 is a substituent at position 4 of R2, R1 being selected from an alkyl group having from 1 to 4 carbon atoms, an alkenyl, an alkynyl, F, whereby R1-R2—Br is reacted with Mg and Si—(OR3)₄ to form R1-R2-Si—(OR3)3+BrMgOR, where R1 is selected from an alkyl group having from 1 to 4 carbon atoms, R2 is an aromatic or non-aromatic ring structure having from 5 to 7 carbon atoms, and R3 is an alkoxy group having from 1 to 3 carbon atoms; and

R1-R2-Si—(OR3)3 is reacted with 3SO2Cl2 in the presence of C5H5N—HCl to yield R1-R2-SiCl3+3SO2+3EtCl.

Similarly, a chemical compound of the formula R1-R2-Si—(X2)3, wherein X2 is a halogen or alkoxy group, R2 is an aromatic group having 8 carbon atoms and R1 is a substituent at position 5 of R2, R1 being selected from an alkyl group having from 1 to 4 carbon atoms, an alkenyl group having from 2 to 5 carbon atoms, or OH, can be prepared by reacting

R1-R2—Br with Mg and Si—(OR3)4 to form R1-R2-Si—(OR3)3+BrMgOR, where R1 is selected from an alkyl group having from 1 to 4 carbon atoms, an alkenyl having from 2 to 5 carbon atoms, R2 is an aromatic or non-aromatic ring structure having from 5 to 7 carbon atoms, and R3 is an alkoxy group having from 1 to 3 carbon atoms; and reacting
R1-R2-Si—(OR3)3 with 3SO2Cl2 in the presence of C5H5N—HCl to yield R1-R2-SiCl3+3 SO2+3EtCl.

A chemical compound of the formula R1-R2-Si—(X2)3, wherein X2 is a halogen or alkoxy group, R2 is an aromatic group having 10 carbon atoms and R1 is a substituent at position 6 of R2, R1 being selected from an alkyl group having from 1 to 4 carbon atoms, an alkenyl group having from 2 to 5 carbon atoms, or OH, can be prepared by reacting

R1-R2—Br with Mg and Si—(OR3)4 to form R1-R2-Si—(OR3)3+BrMgOR, where R1 is selected from an alkyl group having from 1 to 4 carbon atoms, an alkenyl having from 2 to 5 carbon atoms, R2 is an aromatic or non-aromatic ring structure having from 5 to 7 carbon atoms, and R3 is an alkoxy group having from 1 to 3 carbon atoms; and reacting
R1-R2-Si—(OR3)3 with 3SO2Cl2 in the presence of C5H5N—HCl to yield R1-R2-SiCl3+3SO2+3EtCl.

According to this example, a thin film comprising a composition can be obtained by hydrolyzing a monomeric silicon compound having at least one hydrocarbyl radical, containing an unsaturated carbon-to-carbon bond, and at least one hydrolyzable group attached to the silicon atom of the compound with another monomeric silicon compound having at least one aryl group and at least one hydrolyzable group attached to the silicon atom of the compound to form a siloxane material.

In the above substituted cyclic formulas, R₁ is typically a linear or branched carbon chain having from 1 to 4 carbons, which is optionally fluorinated or perfluorinated. Thus, R₁, can be selected from the group consisting of —CF₃, —CF₂CF₃, —CF₂CF₂CF₃, —CF₂OH, CF₂CF₂OH, —CF₂(CF₂)₂OH, —CF₂(CF₂)₂CF₃, —CF₂(CF₂)₃OH, a carbon chain having a carbon-carbon double bond and from 2 to 5 carbons, a vinyl group, an acrylic group, an alkenyl group having from 1 to 4 carbons, and —Si—(X₂)₃, where X₂ is a halogen (X₁ is preferably chlorine or ethoxy, X₂ is chlorine). R₁ can also be —CH₃, —CH₂CH₃, —CH₂CH₂CH₃, —(CH₂)CF₃, —CH₂CH₂OH or —CH₂CF₂OH.

R₂ is an aromatic group selected from the group of aromatic groups having 5 or 6 carbon atoms and further substituted at positions 3 and 5. It can be substituted at positions 3 and 5 with a group —CF₃.

In poly(organo siloxane) compounds comprising a repeating Si—O backbone, wherein there is a group R3 bound to, for example, from 5% to 50% of the silicon atoms, such a group R3 is an alkenyl group having from 2 to 5 carbon atoms, acrylic group or epoxy group. Typically, R3 is an epoxy group, such as a glycidoxypropyl group, an acrylic group, an acryl group, such as a methacrylic group, an alkenyl group having from 2 to 5 carbon atoms, a vinyl group.

The compounds can also comprise R₄ groups bound to from 5 to 50% of the silicon atoms of the Si—O backbone, wherein R₄ is an alkyl group having from 1 to 4 carbon atoms.

Examples of R₄ include CH₃, CH₂CH₃, (CH₂)₂CH₃, CF₃, CF₂CF₃ and (CF₂)₂CF₃.

In one embodiment, the composition comprises a poly(organosiloxane) obtained by hydrolyzing a first silicon compound having the general formula I

Y1₃₋ₐ—SiR1_{b}R2_{c}R3_{d} I

wherein Y1 represents a hydrolyzable group;
R1 is an aromatic group having 6 carbon atoms and R1 is a substituent at position 4 of R1 selected from an alkyl group having from 1 to 4 carbon atoms, an alkenyl group having from 2 to 5 carbon atoms, an alkynyl group having from 2 to 5 carbon atoms, Cl or F;
R2 and R3 are independently selected from hydrogen, substituted or non-substituted alkyl groups, substituted or non-substituted alkenyl and alkynyl groups, and substituted or non-substituted aryl groups;
a is an integer 0, 1 or 2;
b is an integer a+1;
c is an integer 0, 1 or 2;
d is an integer 0 or 1; and
b+c+d=3

with a second silicon compound having the general formula II

Y2₃₋ₑ-SiR4_{f}R5_{g}R6ₕ II

wherein Y2 represents a hydrolyzable group;
R4 is an aromatic group having 6 carbon atoms and R4 is a substituent at position 4 of R4 selected from an alkyl group having from 1 to 4 carbon atoms, an alkenyl group having from 2 to 5 carbon atoms, an alkynyl group having from 2 to 5 carbon atoms, Cl or F;
R5 and R6 are independently selected from hydrogen, substituted or non-substituted alkyl groups, substituted or non-substituted alkenyl and alkynyl groups, and substituted or non-substituted aryl groups;
e is an integer 0, 1 or 2;
f is an integer e+1;
g is an integer 0, 1 or 2;
h is an integer 0 or 1; and
f+g+h=3.

### Design of Molecules:

All actual calculations were done using Gaussian-98 computational chemistry program. The structures of each molecule were built using ChemDraw and Chem3D Pro programs. The Chem3D includes MOPAC package and the initial structural optimizations were done using AM1 theory.

In Gaussian LSDA theory was used to describe the exchange—and correlation. LSDA is a reliable method for electronic densities and quantities like that. It does not describe well the weak molecule-molecule bonds. In this molecule design work, the properties of interest are related to electron density.

The used basis set was cc-pVDZ. Also larger basis sets, viz. 6-311+(2d) and aug-cc-pVDZ, were tested. The dipole moments did not change much but the polarizations were found to be rather sensitive to the basis.

The structural optimizations were done starting form the Chem3D/AM1 optimized structures. In case of mol10, different conformations of the molecules were tested. The reported numbers were from the lowest energy structure. The optimization for the larger molecules was done using the loose option in Gaussian. This was necessary because the molecules are rather flexible, they will change their structures somewhat but the energy will not change much. This should not effect to the main conclusions or trends of the calculations. All structures were optimized with LSDA and cc-pVDZ basis.

The effective charges were computed using the Merz-Collman fitting procedure to reproduce the true electrostatic potential. (prop=fitcharge and pop=mk, keywords in Gaussian). The local dipole moments are based on these effective charges.

Last the bond stretching calculations were done using the optimized geometries and stretching a single bond with constant steps of 0.05 Å.

Based on the calculations, some molecules were synthesized as precursors to obtain low-k dielectric films with optimal electrical thermal and mechanical properties.

The synthesis methods involved the following steps. Generally, the Grignard reaction can be carried out at room temperature or at an elevated temperature (temperature 10 to 70 degC, in particular about 20 to 50 degC). Depending on the quality of the elemental magnesium used, it is possible or recommendable to add some iodine or to ultrasonicate the reaction mixture. In addition to the mild halogenating agent formed by the combination of thionyl chloride and pyridyl hydrochloride it is possible to use other agents capable of replacing the alkoxy groups with halogens without hydrolyzing of oxidizing the group R2. As an example of such substances, carbon tetrachloride can be mentioned.

### Synthesis of Molecules

### (#1) 4-(trifluoromethyl)phenyl trichlorosilane, 4-(F₃C)C₆H₄SiCl₃

### Preparation:

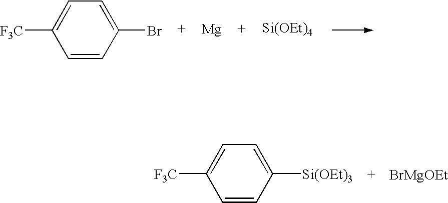

First, 96.24 g (0.427 mol) 4-(trifluoromethyl)phenyl bromide, 10.38 g (0.427 mol) magnesium, and a small amount of iodine were stirred for half an hour. Then, 356.78 g (382 ml, 1.708 mol) Si(OEt)₄ was added to the solution. Et₂O was added until exothermic reaction occurred (˜200 ml) and the solution was refluxed overnight. Et₂O was evaporated off and 250 ml n-heptane added. Mg-salts were filtered off, and n-heptane evaporated. The remaining 4-(F₃C)C₆H₄Si(OEt)₃ was purified by distillation. Bp 68° C./1 mbar. Yield 50.22 g (38%).

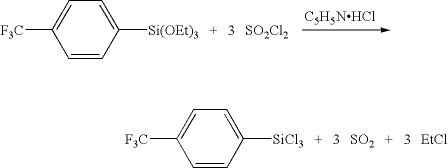

The product of the preceding steps, viz. 50.22 g (0.163 mol) 4-(trifluoromethyl)phenyl triethoxysilane, was mixed with 83 mL (1.140 mol, 135.62 g) thionylchloride and 2.45 g (0.021 mol) pyridinium hydrochloride, and the mixture was refluxed and stirred for 16 h. Excess of SO₂Cl₂ was evaporated and the residue was fractionally distilled to obtain 37 g (81%) 4-(trifluoromethyl)phenyl trichlorosilane. Bp 44° C./4.0 mbar.

### Characterization:

### 4-(trifluoromethyl)phenyl triethoxysilane, 4-(CF₃)C₆H₄Si(OEt)₃

NMR (Et₂O):

| | |
|---|---|
| ²⁹Si: | −63.0 ppm |
| ¹³C: | 139.3 ppm (C₁) |
| | 137.4 ppm (C_{2,6}) |
| | 126.4 ppm (C_{3,5}) |
| | 134.4 ppm (qu, C₄), ²J_{C4-F} 31.7 Hz |
| | 126.6 ppm (qu, C₇), ¹J_{C7-F} 271.4 Hz |
| | 60.8 ppm (C₈) |
| | 20.0 ppm (C₉) |

### 4-(trifluoromethyl)phenyl trichlorosilane, 4-(CF₃)C₆H₄SiCl₃

NMR (Et₂O):

| | |
|---|---|
| ²⁹Si: | −1.5 ppm |
| ¹³C: | 138.1 ppm (C₁) |
| | 136.0 ppm (C_{2,6}) |
| | 127.7 ppm (C_{3,5}) |
| | 137.0 ppm (qu, C₄), ²J_{C4-F} 33.3 Hz |
| | 125.9 ppm (qu, C₇), ¹J_{C7-F} 272.2 Hz |
| ¹⁹F: | −65.3 ppm |

### (#2) 3,5-Bis(trifluoromethyl)phenyl trichlorosilane, 3,5-(F₃C)₂C₆H₃SiCl₃

### Preparation:

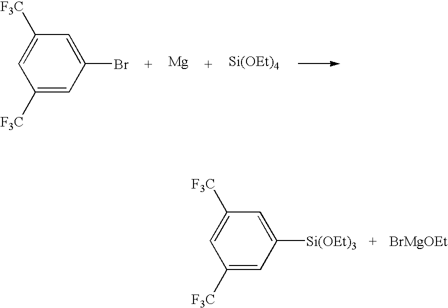

First, 125.11 g (0.427 mol) 3,5-bis(trifluoromethyl)phenyl bromide, 10.38 g (0.427 mol) magnesium, and a small amount of iodine were stirred for half an hour. Then, 356.78 g (382 ml, 1.708 mol) Si(OEt)₄ were added to the solution. Et₂O was added until exothermic reaction occurred (˜200 ml) and the solution was refluxed overnight. Et₂O was evaporated off and 250 ml n-heptane added. The Mg-salts were filtered off and n-heptane evaporated. The remaining 3,5-(F₃C)₂C₆H₃Si(OEt)₃ was purified by distillation. Bp 80° C./0.8 mbar. Yield 78.72 g (52%).

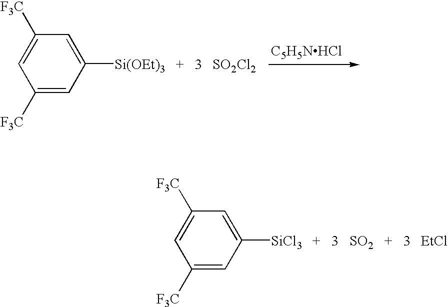

The product of the preceding step, viz. 61.35 g (0.163 mol) 3,5-bis(trifluoromethyl)phenyl triethoxysilane, was mixed with 83 mL (1.140 mol, 135.62 g) thionylchloride and 2.45 g (0.021 mol) pyridinium hydrochloride, and the mixture was refluxed and stirred for 16 h. Excess of SO₂Cl₂ was evaporated and the residue was fractionally distilled to obtain 44.2 g (78%) of 3,5-bis(trifluoromethyl)phenyl trichlorosilane. Bp 41° C./3.1 mbar.

### (#3) Pentafluorophenyl methyl trichlorosilane, C₆F₅CH₂SiCl₃

### Preparation:

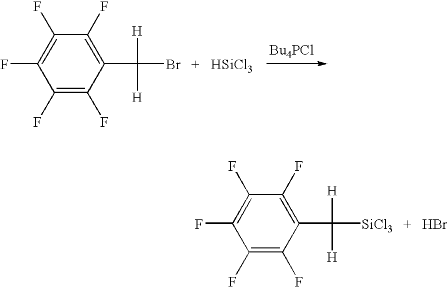

First, 106.29 g (0.407 mol) pentafluorophenylmethyl bromide, 1.20 g (0.004 mol) Bu₄PCl, and 187.55 g (140 ml, 1.385 mol) HSiCl₃ were added to high pressure vessel. The solution was heated to 150° C. for four hours. Excess HSiCl₃ was evaporated and C₆F₅CH₂SiCl₃ was purified by distillation. Bp 56° C./2.4 mbar. Yield 91.18 g (71%). Other applicable precursors based on molecular modeling are, but not limited to, the following:

| | | |
|---|---|---|
| (#4) | 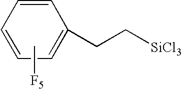 | Pentafluorophenyl ethyl trichlorosilane |
| (#5) | 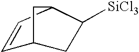 | Norbornyl trichlorosilane |
| (#6) | 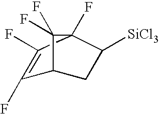 | Pentafluoronorbornyl trichlorosilane |
| (#7) | 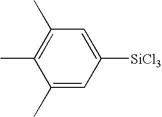 | 3,4,5-trimethylphenyl trichlorosilane |
| (#8) | 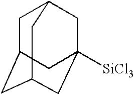 | Adamantyl trichlorosilane |
| (#9) | 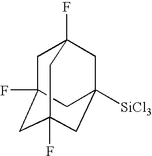 | 3,5,7-trifluoro- adamantyl trichlorosilane |
| (#10) | 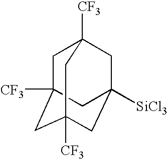 | 3,5,7-trifluoromethyl- adamantyl trichlorosilane |
| (#11) | 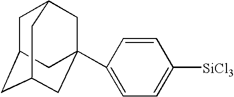 | Adamantylphenyl trichlorosilane |
| (#12) | 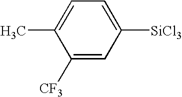 | 3-trifluoromethyl-4- (methyl)phenyl trichlorosilane |
| (#13) | 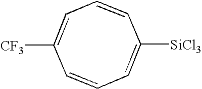 | 5-trifluoromethyl cyclooctatetraenetri- chlorosilane |
| (#14) | 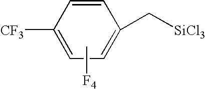 | 4-trifluoromethyl tetrafluorophenyl methyl trichlorosilane |

### Deposition of the Hydrolyzed and Condensed Material:

The material formed as above preferably has a molecular weight between 500 and 100,000. The substrate can be any suitable substrate, such as any article of manufacture that could benefit from the combined benefits of a hybrid organic-inorganic material. In the fields of electronics and optical communications, the material could be deposited as a final passivation layer, as a glob top coating, as an underfill in a flip chip process, as a hermetic packaging layer, etc., though in the present invention, the preferred application of the material is as a dielectric in an integrated circuit. In general, the siloxane oligomer—the hybrid organic-inorganic material having the molecular weight as set forth above—is mixed with a suitable solvent and deposited. The solvent can be any suitable solvent, such as isopropanol, ethanol, methanol, THF, mesitylene, toluene, cyclohexanone, cyclopentanone, di-oxane, methyl isobutyl ketone, or perfluorinated toluene.

Deposition is generally at a temperature of 200 C or less (can be at 15° C. or less). If the material is annealed after deposition, it is preferably at 20° C. or less. If the material is to be patterned by exposure to electromagnetic radiation (e.g., UV light) then a photoinitiator can be mixed into the material along with the solvent. There are many suitable types of photoinitiators that could be used, such as Irgacure 184, Irgacure 500, Irgacure 784, Irgacure 819, Irgacure 1300, Irgacure 1800, Darocure 1173 or Darocure 4265. The initiator could be highly fluorinated, such as 1,4-bis(pentafluorobenzoyl)benzene or Rhodosil 2074 photoinitiator. Also, thermal initiators can be applied for thermal crosslinking of organic carbon double bond moieties, such as with Benzoyl peroxide, 2,2′-Azo-bisisobutyronitrile, or tert-Butyl hydroperoxide. The amount of these photo or thermal initiators may vary from 0.1 to 5 w-%. They may appear in solid or liquid phase. The initiator is carefully mixed with the material that already contains “processing solvent”. (Organic dopants or liquid crystal dopants—or erbium—can be mixed with the material at this point if desired.) Finally, the material is filtered through inert semiconductor grade filter to remove all undissolved material.

Spin-on processing. After hydrolysis and condensation, the material solution is deposited on a substrate in a spin-on process (or by dipping, spray and meniscus coating, etc.). Both static and dynamic deposition can be used. The material is first spread over a wafer or other substrate at low speed (50 to 700 rpm) for 5 to 10 seconds and then the speed is increased by 500 to 5000 rpm/s acceleration to 1000 rpm or higher depending upon starting speed. However, slower speeds may be used if very thick films are required. If 1000 rpm spinning speed is applied film thicknesses from 100 nm to 30,000 nm are achieved depending on material viscosity. Material viscosity can be tuned by increasing the amount of process solvent, which typically have relative low vapor pressure and high boiling point. Spinning is continued for 30 to 60 seconds to obtain uniform film over the wafer. After the spinning, an edge bead removal process is accomplished and the wafer is pre-baked (in nitrogen on hot-plate or in furnace) at temperature around 100 Celsius for 1 minute to remove the process solvent (if used) and improve adhesion to the substrate or to the layer underneath of the current material. Adhesion promoter such as 1% aminopropyltrimethoxy silane in IPA or plasma activation may be applied between the main layers to improve adhesion between them.

The substrate can be any suitable substrate or article. In many cases, the substrate will be a planar wafer-type substrate, such as a glass, plastic, quartz, sapphire, ceramic or a semiconductor substrate (e.g., germanium or silicon). The substrate can have electronic or photonic circuitry already thereon prior to deposition of the dielectric material of the invention. In the present invention, a silicon wafer is the preferred substrate.

Deposition Example 1: Add 10 w-% of methyl isobutyl ketone and 1 w-% of Darocure 1173 photoinitiator to result in the formation of a spin-coatable and photo-sensitive material. The material is deposited by spin coating, spray coating, dip coating, etc. onto a substrate or other article of manufacture. As mentioned herein, many other organic groups can be used in place of the above groups, though preferably one of the groups in one of the compounds is capable of cross linking when exposed to electromagnetic energy (or an electron beam)−e.g., an organic group with a ring structure (e.g., an epoxy) or a double bond (e.g., vinyl, allyl, acrylate, etc.). And, preferably such a cross linking group is partially or fully fluorinated so that the organic cross linking groups in the material after cross linking will be fluorinated cross linking groups—ideally perfluorocarbon cross linking groups in the finally formed material.

### Patterning by RIE:

In the above examples, organic cross linking groups (alkenyl, alkynyl, epoxy, acrylic, etc.) are selectively exposed to light or a particle beam so as to further cross link the material in particular areas, followed by removal with developer of non-exposed areas. However, it is also possible to expose the entire material (or write the entire area with a particle beam, or heat the entire article) so as to organically cross link the material in all areas. Then, following standard processing (spin on and developing of photoresist, etc.) the material can be patterned by etching (e.g., RIE or other plasma etch process). In addition, it is possible to deposit and pattern the electrically conductive areas first, followed by deposition (and optional chemical mechanical polishing) of the dielectric material of the invention. In addition, it is not necessary to have organic cross linking groups at all. A material having a molecular weight of from 500 to 100,000 (due to partial hydrolysis of precursors as mentioned elsewhere herein) is deposited on a substrate. Then, additional hydrolysis is performed e.g., by heating the material on the substrate so as to cause additional (inorganic) cross linking of the material (i.e., extending the -M-O-M-O three dimensional backbone and substantially increasing the molecular weight). The material can then be chemical-mechanical polished and patterned by RIE or other suitable methods.

### Exposure:

One use of the material set forth above is as a layer within an integrated circuit. However, many other devices, from simple hybrid coatings to complex optical devices, can be formed from the materials and methods described above. Regardless of the article being formed, it will be desirable to cross link the deposited material. As mentioned above, any suitable cross linking agent can be used, including common thermal and photo initiators. Assuming that a photoinitator has been used, then the deposited hybrid material acts as a negative tone photoresist, i.e., exposed regions becomes less soluble in a developer. The deposited material can be exposed with any suitable electromagnetic energy, though preferably having a wavelength from 13 nm to 700 nm, including DUV (210-280 nm), mid-UV (280-310 nm), standard I-line or G-line UV-light. DUV exposure is preferred. A stepper can be used for the UV exposure. Typically contact mask exposure techniques are applied. Exposure times may vary between 1 second to several hundred seconds. After the exposure the unexposed areas are removed by soaking the substrate/article (e.g., wafer) or otherwise exposing the substrate/article to a suitable developer (e.g., spray-development may also be used). A developer such as Dow Chemical DS2100, Isopropanol, methyl isobutyl ketone etc. or their combinations can be used to remove unexposed material. Typically 2 minutes development time is used and a solvent rinse (e.g., an ethanol rinse) is preferred to finalize the development. The rinsing removes development residues from the wafer. The adhesion of the exposed structures and the effectiveness of the exposure can be increased by heat-treating the article/substrate (e.g., a slow anneal at elevated temperature—typically less than 200 C). Other exposure techniques, such as exposure with a laser or with Deep UV, could also be performed in place of the above.

Post-baking process. The final hardening of the material is achieved by baking (in air, nitrogen, argon or helium) the article/substrate for several hours typically at less than 200 C. Step-wise heating ramp-up and ramp-down are preferred. The material can also be fully or partially hardened with deep UV light curing.

In the alternative to the above, the material to be patterned is spun on, prebaked, hard baked (typically less than 200 C). Then standard photoresist and RIE etching techniques are applied.

### Hydrolysis and Condensation:

Description. The synthesis of deposition materials is preferably based on hydrolysis and condensation of chlorosilanes (though alkoxysilanes, silanols or other hydrolysable precursors could be used). The synthesis procedure consists of five sequential stages: dissolve, hydrolysis, neutralization, condensation and stabilization. In the hydrolysis chlorine atoms are replaced with hydroxyl groups in the silane molecule. Hydrochloric acid formed in the hydrolysis is removed in the neutralization stage. Silanols formed in the hydrolysis are attached together for a suitable oligomer in the condensation stage. The extent of the condensation can be controlled with terminal groups, that is, silane precursors having multiple organic groups and a single hydrolysable (e.g., chlorine) group. Another advantage of terminal modified hybrid silanols is their stability against condensation. In addition, the material purification stability is improved since the evaporative purification can be done at slightly elevated temperatures without causing harmful post synthesis condensation.

Terminal groups. Compound of the general formula R₁R₂R₃SiR₄ can act as a terminal group, wherein R₁, R₂, R₃ are independently (non-fluorinated, partially fluorinated or perfluorinated) aromatic groups (e.g., phenyl, toluene, biphenyl, naphthalene, etc.) or cross linkable groups (e.g., vinyl, allyl, acrylate, styrene, epoxy etc.) or any alkyl group having from 1-14 carbons, wherein R₄ is either an alkoxy group, OR⁵, or a halogen (Br, Cl). Perfluorinated R₁, R₂ and R³ groups are preferred.

Example method 1 for preparation of a deposition material with tris(perfluorovinyl)chlorosilane as a terminal group:

Dissolve. Tris(perfluorovinyl)chlorosilane, pentafluorophenyltrifluorovinyl dichlorosilane and pentafluorophenyltrichlorosilane are mixed together in molar ratio 1:4:4 in an appropriate reaction flask and the mixture is dissolved into appropriate solvent like tetrahydrofuran.

Hydrolysis and Co-condensation. The reaction mixture is cooled to 0° C. The hydrolysis is performed by adding water (H₂O) into the reaction mixture. The water is added as 1:4 (volume/volume) water-tetrahydrofuran-solution. The amount of water used is equimolar with the amount of chlorine atoms in the starting reagents. The reaction mixture is held at 0° C. temperature during the addition. The reaction mixture is stirred at room temperature for 1 hour after addition.

Neutralization. The reaction mixture is neutralized with pure sodium hydrogencarbonate. NaHCO₃ is added into cooled reaction mixture at 0° C. temperature (The amount of NaHCO₃ added is equimolar with the amount of hydrochloric acid in the reaction mixture). The mixture is stirred at the room temperature for a while. After the pH of the reaction mixture has reached the value 7, mixture is filtered. The solvent is then evaporated with a rotary evaporator.

Condensation. The material is stirred with a magnetic stirrer bar under 12 mbar pressure for few hours. Water, which forms during this final condensation, evaporates off.

Stabilization. The material is dissolved into cyclohexanone, which is added 30 weight-% of the materials weight. The pH of the solution is adjusted to value 2.0 with acetic acid.

Example method 2 for preparation of a deposition material with bis(pentafluorophenyl)-trifluorovinylchlorosilane as a terminal group:

Dissolve. Bis(pentafluorophenyl)trifluorovinylchlorosilane, pentafluorophenyl-trifluorovinyldichlorosilane and pentafluorophenyltrichlorosilane are mixed together in molar ratio 1:6:4 in an appropriate reaction flask and the mixture is dissolved into appropriate solvent like tetrahydrofuran.

Hydrolysis, neutralization, condensation and stabilization stages are performed as in example method 1.

Example method 3 for preparation of a deposition material with tris(perfluorotoluene)chlorosilane as a terminal group:

Dissolve. Tris(perfluorotoluene)chlorosilane, pentafluorophenyltrifluorovinyl-dichlorosilane and pentafluorophenyltrichlorosilane are mixed together in molar ratio 1:6:8 in an appropriate reaction flask and the mixture is dissolved into appropriate solvent like tetrahydrofuran.

Hydrolysis, neutralization, condensation and stabilization stages are performed as in example method 1.

### Alternative Procedures for Each Stage:

Dissolve. Instead of tetrahydrofuran (THF) as solvent you can use any pure solvent or mixture of solvents/alternate solvents are possible either by themselves or by combinations. Traditional methods of selecting solvents by using Hansen type parameters can be used to optimize these systems. Examples are acetone, dichloromethane, chloroform, diethyl ether, ethyl acetate, methyl-isobutyl ketone, methyl ethyl ketone, acetonitrile, ethylene glycol dimethyl ether, triethylamine, formic acid, nitromethane, 1,4-dioxane, pyridine, acetic acid, di-isopropyl ether, toluene, carbon disulphide, carbon tetrachloride, benzene, methylcyclohexane, chlorobenzene. Hydrolysis. Water used in the reaction can be, instead of tetrahydrofuran, dissolved into pure or mixture of following solvents: acetone, dichlormethane, chloroform, diethyl ether, ethyl acetate, methyl-isobutyl ketone, methyl ethyl ketone, acetonitrile, ethylene glycol dimethyl ether, tetrahydrofuran, triethylamine, formic acid, nitromethane, 1,4-dioxane, pyridine, acetic acid. In the place of water following reagents can be used: deuterium oxide (D₂O) or HDO. A part of water can be replaced with following reagents: alcohols, deuterium alcohols, fluorinated alcohols, chlorinated alcohols, fluorinated deuterated alcohols, chlorinated deuterated alcohols. The reaction mixture may be adjusted to any appropriate temperature. The precursor solution can be added into water. Pure water can be used in the reaction. Excess or even less than equivalent amount of water can be used. Neutralization. Instead of sodium hydrogen carbonate (NaHCO₃) neutralization (removal of hydrochlorid acid) can be performed using following chemicals: pure potassium hydrogen carbonate (KHCO₃), ammonium hydrogen carbonate (NH₄HCO₃), sodium carbonate (Na₂CO₃), potassium carbonate (K₂CO₃), sodium hydroxide (NaOH), potassium hydroxide (KOH), calcium hydroxide (Ca(OH)₂), magnesium hydroxide (Mg(OH)₂) ammonia (NH₃), trialkylamines (R₃N, where R is hydrogen or straight/branched chain CₓH_{y}, x<10, as for example in triethylamine, or heteroatom containing as for example in triethanol amine), trialkyl ammonium hydroxides (R₃NOH, R₃N, where R is hydrogen or straight/branched chain CₓH_{y}, x<10), alkali metal silanolates, alkali metal silaxonates, alkali metal carboxylates. All neutralization reagents can be added into the reaction mixture also as a solution of any appropriate solvent. Neutralization can be performed also with solvent-solvent-extraction or with azeotropic water evaporation.

Procedure for solvent-solvent-extraction: The solvent is evaporated off after the hydrolysis. The material is dissolved into pure or mixture of following solvents: chloroform, ethyl acetate, diethyl ether, di-isopropyl ether, di-chloromethane, methyl-isobutyl ketone, toluene, carbon disulphide, carbon tetrachloride, benzene, nitromethane, methylcyclohexane, chlorobenzene. The solution is extracted several times with water or D₂O until pH of the organic layer is over value 6. The solvent is then evaporated with rotary evaporator. In cases when water immiscible solvent has been used in hydrolysis stage then solvent-solvent extraction can be performed right after hydrolysis without solvent evaporation. Acidic or basic water solution can be used in the extraction.

Procedure for azeotropic water evaporation: The solvent is evaporated off after the hydrolysis. The material is dissolved into mixture of water and one of the following solvents (1:10 volume/volume): tetrahydrofuran, ethanol, acetonitrile, 2-propanol, tert-butanol, ethylene glycol dimethyl ether, 2-propanol, toluene, dichloromethane. The formed solution is evaporated to dryness. The material is dissolved again into the same mixture of water and the solvent. Evaporation and addition cycle is repeated until pH value of the material solution is 7. The solvent is then evaporated with rotary evaporator.

Condensation. The pressure in this stage can be in a large range. The material can be heated while vacuum treatment. Molecular weight of formed polymer can be increased in this stage by using base or acid catalyzed polymerizations. Procedure for acid catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloromethane, xylene, chloroform, diethyl ether, ethyl acetate, methyl-isobutyl ketone. Into the solution material solution is added catalytic amount of acid such as: triflic acid, monofluoro acetic acid, trifluoro acetic acid, trichloro acetic acid, dichloro acetic acid, monobromo acetic acid. The solution is refluxed for few hours or until polymerization is reached desired level while water formed in the reaction is removed. After polymerization, acid catalyst is removed from the material solution completely for example using solvent extraction or other methods described in alternative neutralization section. Finally solvent is removed. Procedure for base catalyzed polymerization: Pure material is dissolved into any appropriate solvent such as: tetrahydrofuran, ethanol, acetonitrile, 2-propanol, tert-butanol, ethylene glycol dimethyl ether, 2-propanol, toluene, dichloro-methane, xylene, chloroform, diethyl ether, ethyl acetate, methyl-isobutyl ketone. Into the solution material solution is added catalytic amount of base such as: triethanol amine, triethyl amine, pyridine, ammonia, tributyl ammonium hydroxide. The solution is refluxed for few hours or until polymerization is reached desired level while water formed in the reaction is removed. After polymerization, base catalyst is removed from the material solution completely for example by adding acidic water solution into the material solution. After that acidic solution is neutralized using solvent extraction or other methods described in alternative neutralization section. Finally, solvent is removed.

Stabilization. In the place of THF and cyclohexanone can be used pure or mixture of following solvents: cyclopentanone, 2-propanol, ethanol, methanol, 1-propanol, tetrahydrofuran, methyl isobutyl ketone, acetone, nitromethane, chlorobenzene, dibutyl ether, cyclohexanone, 1,1,2,2-tetrachloroethane, mesitylene, trichloroethanes, ethyl lactate, 1,2-propanediol monomethyl ether acetate, carbon tetrachloride, perfluoro toluene, perfluoro p-xylene, perfluoro iso-propanol, cyclohexanone, tetraethylene glycol, 2-octanol, dimethyl sulfoxide, 2-ethyl hexanol, 3-octanol, diethyleneglycol butyl ether, diethyleneglycol dibutyl ether, diethylene glycol dimethyl ether, 1,2,3,4-tetrahydronaphtalene or trimethylol propane triacrylate. The material solution can be acidified using following acids: acetic acid, formic acid, propanoic acid, monofluoro acetic acid, trifluoro acetic acid, trichloro acetic acid, dichloro acetic acid, monobromo acetic acid. Also following basic compounds can be added into the material solution: triethyl amine, triethanol amine, pyridine, N-methylpyrrolidone.

Stabilization in cases when the condensation stage is passed: Acetic acid is added into the mixture until pH value is 34. The solution is evaporated until appropriate concentration of the oligomer in the solution has reached (about 50 w-% oligomer, 49 w-% solvent and 1 w-% acid, solvent is the solvent of the dissolve and hydrolysis stages).

Initiators: Photoinitiators that can be used are Irgacure 184, Irgacure 500, Irgacure 784, Irgacure 819, Irgacure 1300, Irgacure 1800, Darocure 1173 and Darocure 4265. The initiator can be highly fluorinated, such as: 1,4-bis(pentafluorobenzoyl)benzene or Rhodosil 2074 or other suitable initiator. Thermal initiators which can be used are benzoyl peroxide, 2,2′-azobisisobutyronitrile, 1,1′-Azobis(cyclohexanecarbonitrile), tert-butyl hydroperoxide, Dicumyl peroxide and Lauroyl peroxide.

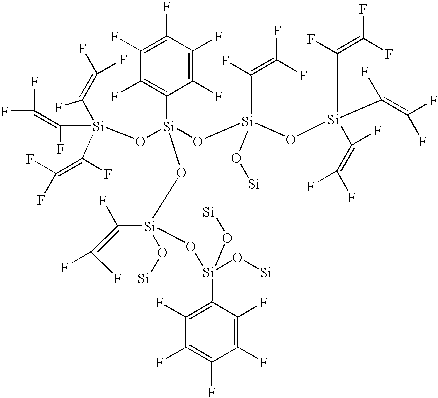

Figure above: Example of oligomeric molecule formed in above type of reactions. (Of course this is but one of many examples of materials formed after hydrolysis of precursors).

As mentioned above in relation to the appended Figures, the hydrolyzed and condensed material is mixed with a solvent (this can be a fluorinated solvent) and deposited (by spin-on, spray-on, dip coating, etc) on a substrate. Often the substrate will be a silicon substrate on which have been formed electronic circuitry (including p and n type regions) and on which may optionally be one or more layers of alternating regions of electrically insulating and electrically conducting materials (e.g for vias and interconnects). Thus, the substrate of the invention may be a silicon wafer, doped or not, with or without subsequent films or layers thereon. Of course, the invention is not limited to silicon substrates, as any suitable substrate, semiconductor or not (glass, quartz, SOI, germanium etc) can be used depending upon the desired final product. Often the hybrid material of the invention will be deposited in a particular layer and patterned (e.g. by RIE or by cross linking and developing if there is a cross linkable group in the material) after which an electrically conductive material (such as aluminum or copper or alloys of these or other electrically conductive materials as known in the art) is deposited in areas where the electrically insulating material has been removed, followed if desired by chemical mechanical polishing down to the level of the electrically insulating material. It is also possible to deposit and pattern the electrically conductive material first, though deposition after the insulating material is preferred. Capping layers can be deposited prior to depositing the electrically conductive material to provide a chemical mechanical polishing stop. Barrier layers can also be deposited to prevent the electrically conductive material from physically or chemically passing into or reacting with the electrically insulating material. Also hard masks can be deposited for providing a via etch stop. Adhesion promoting layers can be desirable to improve adhesion of some of the more highly fluorinated hybrid materials of the invention. Such adhesion promoting layers can be non (or low) fluorinated materials in accordance with the invention or other adhesion promoting layers as known in the art. Primers can be deposited for example between the electrically conductive layer and the dielectric layer, between two dielectric layers, between a capping layer and a dielectric layer or between a hard mask and a dielectric layer. Primers and coupling agents are typically liquids that may be applied to adhered surfaces prior to the adhesive or coating, or particularly prior to spin-on dielectric film deposition. Such primers can be desirable for a number of reasons, including i) a coating of primer applied to a freshly prepared surface serves to protect it until the bonding operation is carried out, ii) primers wet the surface more readily that the coating. This may be achieved by using, as the primer the coating dissolved in a solution of much lower viscosity. Alternatively, it may be a solution of a different polymer, which after drying is easily wetted by the coating, iii) a primer may serve to block a porous surface, thus preventing escape of the coating. With structural coating binds this is probably only important for porous layers underneath of it. However, some penetration of the coating may be very desirable and viscosity can be adjusted to give optimum penetration, iv) a primer can act as the vehicle for corrosion inhibitors, keeping such inhibitors near the surface where they are needed, v) the primer may be a coupling agent capable of forming chemical bonds both with the adhered surface and the coating, and vi) the adsorption of the primer to the substrate may be so strong that, instead of merely being physically adsorbed, it has the nature of a chemical bond. Such adsorption is referred to as chemisorption to distinguish it from the reversible physical adsorption. The primers and coupling agents may also be deposited from a gas phase. Primer examples include 3-aminopropyl triethoxysilane, 3-aminopropyl trimethoxysilane, 3-glysidoxypropyl trimethyoxysilane, vinyl triethoxysilane and 3-thiopropyl triethoxysilane.

### Organic-Inorganic Ratio of the Compostions:

In the course of the invention it is also advantageous to control concentrations of inorganic and organic component in the dielectric matrix. This is particularly important in terms of the control planarization capability of the spin-on dielectric (SOD). It is preferable from planarization capability point of view that the SOD material also contains relatively high concentration of organic components to improve the materials planarization capability. However, is it also important from the application point of view that the organic compounds are stable in the matrix and will not outgas during the elevated temperature processing. Excellent thermal stability of the organic compounds in at high concentration is achievable through bonding the organic compound or substituents via covalent bonds to the silicon dioxide matrix. Furthermore, in the course of the invention it is advantageous to apply matrices wherein the organic compound attached to the silicon is relatively large, but still inherently thermally stable. This approach allows to introduce higher concentrations of organic compounds into the matrix without losing the thermal stability characteristics. Based on this invention it is preferable to introduce high organic-inorganic ratio SOD composition that results in better degree of planarization on topography containing semiconductor surfaces (or any surface with topography). Therefore, it is preferable that C/Si (carbon/silicon) ratio in the SOD composition is 1.5/1 or high more preferably 3/1 or higher, most preferably 10/1 or higher. For practical applications, usually a ratio of 50/1 is a maximum, in particular 30/1, preferably about 25/1.

### Rapid Thermal Curing:

The present invention also concerns a method of forming a thin film having a dielectric constant of 2.5 or less, comprising

hydrolyzing a first silicon compound in accordance with any of the compounds referred to hereinabove, optionally with
a second silicon compound as disclosed hereinabove;
depositing the siloxane material in the form of a thin layer on a substrate; and
curing the thin layer to form a film;
followed by rapid thermal curing (RTC). In such a process, the dielectric material is cured (densified and/or crosslinked) by increasing the temperature of the material at a rate, which is at least 6 times faster than in conventional curing. As a result, the heating ramp (the time it takes to reach curing temperature) is steep. The actual curing time can also be shorter than conventionally. Typically, the curing time is one sixth of the conventional time in the same heating tool. However, the rapid cure step can also be followed by conventional longer cure. The temperature difference between the starting temperature and actual the curing temperature is at least 150° C. At larger temperature differences, lower dielectric constants are achieved due to changed microstructure of the film material. It is not the course of the invention to claim the changed microstructure, but the changes in the structures due to the RTC treatment are likely due to phase change between ordered and disordered microstructures in silicon dioxide part of the matrix that results less densely packed structure than can be obtained as slightly increased micro-porosity. Alternatively, the microstructure changes may also take a place between or within organic residues attached to the silicon or even between organic residues and silicon dioxide matrix. All these reactions to cause the microstructure changes may also take a place simultaneously.

According to a preferred embodiment of the above methods, a non-porous dielectric material is first provided by conventional processing, e.g. by a spin-on or CVD process.

The temperature (also called “the first temperature”) of the typically paste-like material is in the range of 100 to 200° C. The material is free from intentionally incorporated free evaporating porogens in order to provide a non-porous dielectric material. The elastic modulus of the paste-like material is low. After the deposition of the material on a suitable support, in particular on a semiconductor substrate, the material can optionally be pretreated, as will be explained below in more detail, and then cured by a thermal curing process, in which the material is rapidly heated to an increased (second) temperature.

In the RTC method alternative, the temperature can be increased at an average rate of at least 1° C., preferably at least 10° C., in particular at least 30° C., per second. Thus, a densified nonporous dielectric material having an elastic modulus, which is greater than the elastic modulus of the starting material, can be obtained.

Accordingly, the polymerization and densification reactions of the material are activated in a rapid curing furnace so that relative dielectric constant of the dielectric film is lower than a predetermined value. Such a predetermined value corresponds to that of a conventional furnace, which means a furnace in which the material is heated at a rate of about 10 deg C. or less per minute and in which it is cured for extensive periods of at least 15 minutes, typically more than 30 minutes. By the RTC process, the dielectric constant of the same material will be reduced by more than 0.1 as a result of the rapid thermal curing.

However, the RTC process can be followed by conventional type of heat treatment.

As mentioned above, the temperature difference between the second and the first temperature should be large, preferably it is at least 200° C., and in particular in the range of from 225 to 425° C., and most preferably at least 275° C. However, it should be pointed out that the present materials can also be processed by conventional thermal processing. The dielectric constant of the densified material is 2.60 or less, preferably 2.50 or less, in particular 2.40 or less. The CTE of the film is less than 25×10⁻⁶1/degC.

The material can be characterized as being “nonporous” which, in the present context means, in particular, that the porosity is low, typically less than 25%, preferably less than 20%, in particular less than 15% (by volume), and the average pore size is less than 5 nm, preferably less than 2 nm and in particular less than 1 nm. As a result of the processing, the electronic polarizability of the film is decreased more than 0.1 compared to a predetermined value obtained by conventional processing, as explained above.

As mentioned above, the nonporous dielectric material can be subjected to annealing or a similar pretreatment or post-treatment of heated to the second temperature, i.e. the actual curing temperature. Annealing is carried out, e.g., by a process in which the material is subjected to UV radiation, DUV radiation, Extreme UV radiation, IR radiation or e-beam radiation or a combination thereof. The annealed material is then subjected to curing at an elevated temperature in air, nitrogen, argon, forming gas or vacuum.

The pre-cure and rapid cure processes according to the present invention, result in a dielectric film free of silanols.

The annealed and cured (densified, crosslinked) material can be subjected to deposition of a second layer selected from a metal, a barrier, a liner or an additional dielectric layer.

Based on the above, the present invention provides a process for preparing a siloxane-based dielectric material on a semiconductor substrate by hydrolysis and condensation of corresponding reactants, applying the prepared compositions on a substrate in the form of a thin layer, patterning the film by selective radiation and developing the radiated film and curing the formed structure.

As an embodiment of the above process, the material above is processed first by introducing a monomeric or polymerized material on a semiconductor substrate by a spin-on or CVD method, and then forming a siloxane polymer film on the semiconductor substrate by activating polymerization and densification reactions by rapid curing processing so as to produce a material having a relative dielectric constant lower than 2.6, preferably less than 2.5, in particular less than 2.4. Typically the dielectric constant is between 2.0 and <2.6.

The pore size of the nonporous dielectric material is less than 2 nm, the co-efficient of thermal expansion less than 25 ppm/degC, and the thermal decomposition temperature higher than 450° C.

### Material Characteristics:

Material processed and formed on a substrate as above, was tested to determine various characteristics of the deposited and cross linked material. In a test of the hydrophobicity of the hybrid material, a water contact angle measurement can be measured. The phenomenon of wetting or non-wetting of a solid by a liquid can be understood in terms of the contact angle. A drop of a liquid resting on a solid surface forming an angle relative to the surface may be considered as resting in equilibrium by balancing the three forces involved (namely, the interfacial tensions between solid and liquid, that between solid and vapor and that between liquid and vapor). The angle within the liquid phase is known the contact angle or wetting angle. It is the angle included between the tangent plane to the surface of the liquid and the tangent plane to the surface of the solid, at any point along their line of contact. The surface tension of the solid will favor spreading of the liquid, but this is opposed by the solid-liquid interfacial tension and the vector of the surface tension of the liquid in the plane of the solid surface.

In the present invention, contact angles of 90 degrees or more, and generally 100 degrees or more are easily achieved (from 50 ul of ultrapure water). Depending upon the compounds selected for hydrolysis/condensation, water contact angles of 125 degrees or more, or even 150 degrees or more can be achieved. Particularly if all organic groups, including those that provide bulk to the final material (e.g., a longer alkyl chain or a single or multi ring aryl group) as well as those that allow for cross linking (e.g., organic groups with unsaturated double bonds), are fully fluorinated—then the resulting material can be highly hydrophobic and result in very large contact angles. The hydrophobicity can easily be tailored depending upon which compounds are selected, and in what amounts, for hydrolysis/condensation.

Other properties of the materials, such as surface and sidewall roughness, feature size, aspect ratio, and glass transition temperature were also measured. The glass transition temperature, Tg, of the deposited materials was measured using a Mettler-Toledo Differential Scanning Calorimeter (DSC) and found to be 200° C. or greater, and generally 250° C. or greater (or even 310° C. or more). Surface roughness, Rq, of the material (measured by atomic force microscopy and WYKO—white light interferometry) was found to be 10 nm or less, and generally 5 nm or less. In many cases, the surface roughness is 1 nm or less. When the material is patterned, sidewalls are formed in the surface topography that is created. A measurement of the sidewall roughness (measured by atomic force microscopy, SEM and WYKO—white light interferometry) was found to be 50 nm or less, and generally 10 nm or less. Depending upon the compounds used for hydrolysis/condensation, as well as exposure and development technique, a sidewall roughness, Rq, or 5 nm or less, or even 1 nm or less, can be achieved. Pattering of the material was able to create feature sizes (e.g., ridge or trench width) as small as 100 nm or less, or even 50 nm or less, as well as aspect ratios of such features of 2:1, 3:1 or even as high as 10:1 (also measured by atomic force microscopy, SEM and WYKO—white light interferometry).

Due to the hydrophobic nature of some of the materials within the present invention (e.g., those having a higher degree of fluorination), it may be desirable in some cases to first provide an adhesion promoting layer before depositing the hybrid material. For example, a 1:100 dilution of the material of the invention could be applied as an adhesion promoting layer before spinning on (or otherwise depositing) the hybrid material. The diluted SOD is very stable (photo, thermal, humidity, 85/85 tests) and easy to detect, spreads well on Silicon and is optically clear all the way to UV.

Other adhesion promoting materials that could be used include Onichem organosilane G602, (N (beta aminoethyl)-gamma aminopropyl dimethyl siloxane (CA 3069-29-2)—high boiling, high Rl (1.454), thermally stable low density and is compatible with acrylics, silicones, epoxies, and phenolics), or Dow AP8000, propyloxysilane (e.g., 3(2 3 epoxy propoxy propyl) trimethoxy silane), Ormocer (low viscosity), Halar, Orion/Dupont Teflon primer, trifluoroacetic acid, barium acetate, fluorethers (from Cytonix), PFC FSM 660 (a fluoroalkyl monosilane in a fluorinated solvent)—can be diluted to 0.1 to 0.05 percent in alcohol or fluorinated solvent, PFC FSM 1770 (a tri-fluoroalkyl monosilane in a fluorinated solvent, providing very low surface energy to oxide surfaces and good adhesion for fluoropolymers)—can be diluted to 0.1 to 0.05 percent in alcohol or fluorinated solvent, and/or HMDS.

The materials of the invention can be deposited as very thin layers (as thin as from 1 to 10 molecular layers), or in thicker films from 1 nm up to 100 um (or more). Generally, the material is deposited at a thickness of from 0.5 to 50 um, preferably from 1 to 20 um—though of course the thickness depends upon the actual use of the material. The thickness of the deposited layer can be controlled by controlling the material viscosity, solvent content and spinning speed (if deposited by spin on). Material thickness can also be controlled by adjusting the deposition temperature of both the deposition solution and the spinner (if spin on deposition). Also, adjusting the solvent vapor pressure and boiling point by selection of solvent can affect the thickness of the deposited material. Spin on deposition can be performed on a Karl Suss Cyrset enhanced RC8 spinner. Spray coating, dip-coating, meniscus coating, screen printing and “doctor blade” methods can also be used to achieve films of varying thickness.

Further properties of the densified materials include a density of at least 1.2, preferably 1.45 g/cm³ or more, 1.60 g/cm³ or more, or even 1.75 g/cm³ or more, in practice 3 g/cm³ at the most, preferably 2.5 g/cm³ at the most. The final material has a glass transition temperature, which is higher than 200° C., in particular 400° C. or more, in particular 500° C. or more. The glass transition temperature (and, naturally, the decomposition temperature) should be higher than processing temperature of the semiconductor substrate. At the same time, the dielectric constant is favorably low—easily 3.0 or less, more typically 2.7 or less or even 2.5 or less. In addition, the hybrid material after being formed has a coefficient of thermal expansion of 12-22 ppm, generally 15-20 ppm. The modulus of the hybrid siloxane-type material is 4.0 GPa or more, preferably 5.0 GPa or more. Though many precursor materials achieve the above material characteristics, preferred precursors are silanes having organic substitutents selected from a) aromatic and aliphatic ring structures (single or multi-ring) such as aryl and adamantyl groups, b) alkyl groups, preferably having from 1 to 5 carbons, and c) cross linking groups such as alkenyl groups (preferably vinyl). And, by having a surface roughness Rq, of 10 nm or less (e.g. 5 nm or less Rq), chemical mechanical polishing is minimized.

The present invention provides novel siloxane materials, which can be hydrolyzed and condensed (alone or with one or more other compounds) into a hybrid material having a (weight average) molecular weight of from 500 to 100,000 g/mol. The molecular weight can be in the lower end of this range (e.g., from 500 to 5,000 g/mol, or more preferably 500 to 3,000 g/mol) or the hybrid material can have a molecular weight in the upper end of this range (such as from 5,000 to 100,000 g/mol or from 10,000 to 50,000 g/mol). In addition, it may be desirable to mix a hybrid material having a lower molecular weight with a hybrid material having a higher molecular weight. The hybrid material can be suitably deposited such as by spin-on, spray coating, dip coating, or the like, as will be explained in more detail below.

The dielectric constant of the present materials can be lowered by rapid thermal curing (RTC), as mentioned above. However, it should be pointed out that the present materials can also be processed by conventional thermal processing.

The dielectric constant of the densified material is 2.70 or less, advantageously 2.60 or less, preferably 2.50 or less, in particular 2.40 or less, and suitably 2.30 or less. The CTE of the film is less than 25*10⁻⁶1/degC. The material can be characterized as being “nonporous” which, in the present context means, in particular, that the porosity is low, typically less than 25%, preferably less than 20%, in particular less than 15% (by volume), and the average pore size is less than 5 nm, preferably less than 2 nm and in particular less than 1 nm. As a result of the processing, the electronic polarizability of the film is decreased more than 0.1 compared to a predetermined value obtained by conventional processing, as explained above.

As mentioned above, the nonporous dielectric material can be subjected to annealing or a similar pretreatment or post-treatment of heated to the second temperature, i.e. the actual curing temperature. Annealing is carried out, e.g., by a process in which the material is subjected to UV radiation, DUV radiation, Extreme UV radiation, IR radiation or e-beam radiation or a combination thereof. The annealed material is then subjected to curing at an elevated temperature in air, nitrogen, argon, forming gas or vacuum.

The pre-cure and rapid cure processes according to the present invention, result in a dielectric film free of silanols (less 0.5 wt-%).

The annealed and cured (densified, crosslinked) material can be subjected to deposition of a second layer selected from a metal, a barrier, a liner or an additional dielectric layer.

As an embodiment of the above process, the material above is processed first by introducing a monomeric or polymerized material on a semiconductor substrate by a spin-on or CVD method, and then forming a siloxane polymer film on the semiconductor substrate by activating polymerization and densification reactions by rapid curing processing so as to produce a material having a relative dielectric constant lower than 2.6, preferably less than 2.5, in particular less than 2.4. Typically the dielectric constant is between 2.0 and <2.6.

The pore size of the nonporous dielectric material is less than 2 nm, the co-efficient of thermal expansion less than 25 ppm/degC, and the thermal decomposition temperature higher than 450° C.

### High Temperature Processing:

Because the materials of the present invention are stable at very high temperatures, they are particularly suitable for high temperature processing. In general, the materials can be exposed to temperatures of 450° C. or more, or 500° C. or more without degradation. Thus, after deposition and curing, one or more following process steps can be at a temperature of 450° C. or more (or even 500° C. or more). As one example, in place of a tungsten via, a hot aluminum (also known as “aluminum reflow process”) via fill could be performed following deposition of the siloxane material of the invention.

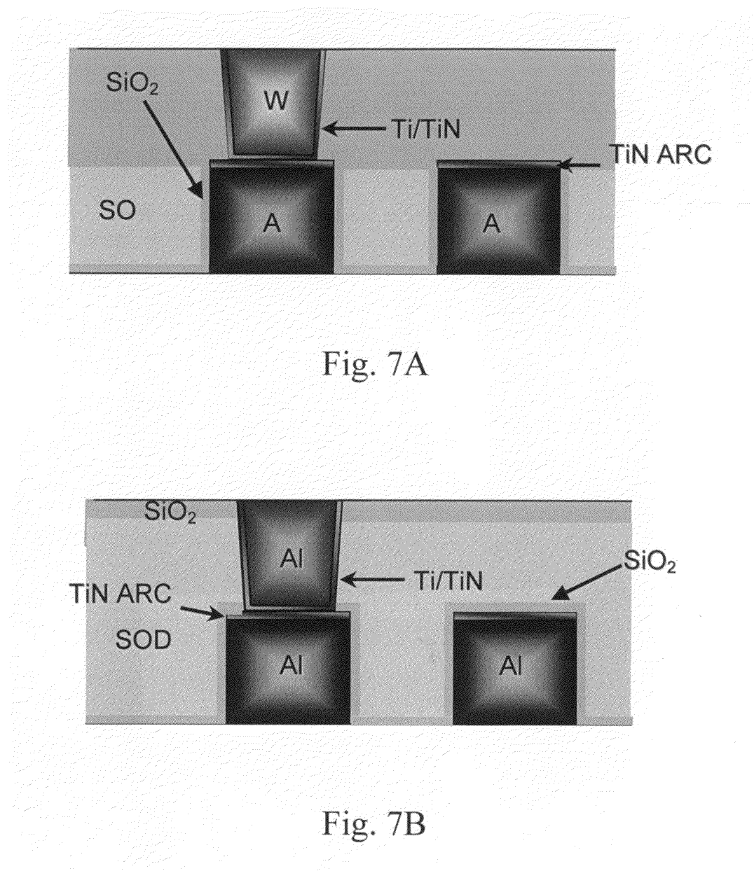

In a tungsten via process in accordance with the present invention, as can be seen in FIG. 7a, after depositing a layer of aluminum, the aluminum is patterned to form “gaps” within the aluminum layer. Into these gaps is deposited silicon dioxide (by CVD), followed by deposition of the siloxane (SO) material to fill the gaps. Additional silicon dioxide is deposited on the siloxane material, followed by chemical mechanical planarization (CMP). Vias are formed in this layer of silicon dioxide by photolithography and etching down to a TiNx stop on the aluminum layer. After ashing, wet cleaning and degassing, a barrier layer of Ti/TiNx is deposited (this could also be SiOx) within the via “gaps”, followed by deposition of tungsten (CVD of tungsten from WF6 precursor at 300 C). Finally the tungsten layer is chemically mechanically planarized, before proceeding to the next metal layer.

Though this is one suitable method for the materials disclosed herein, due to the lower cost of aluminum as compared to tungsten, and the lower need for a CMP step, it is sometimes preferred to form the tungsten vias from aluminum—though achieving uniform filling within the vias with aluminum requires a “hot aluminum” step—generally deposition of aluminum at 450° C. or more, or even 500° C. or more if desired. In such a hot aluminum process, as can be seen in FIG. 7b, first is deposited and patterned the lower aluminum and TiNx (ARC) layers to form “gaps” Into these gaps is deposited first a barrier SiOx layer, followed by the siloxane material of the invention. The spin-on dielectric siloxane material of the present invention (SOD) is deposited not only in the patterned gaps in the aluminum layer (e.g. around 500 nm thick Al layer), but also above the aluminum layer (e.g. 300 nm higher). On top of the SOD material (this could also be deposited by CVD) is deposited a layer of SiOx by CVD (more particularly, this can be TEOS—tetra ethyl ortho silicate/silicon tetra ethoxide). Without performing a chemical mechanical planarizing step (or by removing through planarization 45% or less of the thickness of this SiOx/TEOS layer—or generally 35% or even 25% or less), via lithography is performed to form vias down to the aluminum layer. After ashing, wet cleaning and degassing, a barrier layer is deposited (e.g. Ti/TiNx), followed by deposition of the hot aluminum at a temperature of 450° C. or more, often 500° C. or more. The aluminum is chemically mechanically planarized prior to proceeding to the next metal layer. Desirably, the siloxane material of the present invention has no detectable change in k value or modulus (or no substantial change that affects the ability of the siloxane material to be used in such processes), nor does the siloxane material outgas, even if exposed to temperatures of 450° C. or more, or 500° C. or more (or even 525° C. or more depending upon the length of time of such exposure).

The foregoing description of a preferred embodiment of the invention has been presented for purposes of illustration and description. It is not intended to be exhaustive or to limit the invention to the precise forms disclosed. Obviously, many modifications and variations will be apparent to practitioners skilled in this art. It is intended that the scope of the invention be defined by the following claims and their equivalents.

1. A method for making an integrated circuit device, comprising:
forming a plurality of transistors on a semiconductor substrate;
forming multilayer interconnects by:
depositing a layer of metal;
patterning the metal layer;
depositing a first dielectric material having a first modulus and a first k value;
depositing a second dielectric material having a second modulus higher than the first modulus of the first material;
without performing chemical mechanical planarization, patterning the first and second dielectric materials and depositing a via filling metal material into the patterned areas; and
wherein the k value of the first material is 2.9 or less.

2. A method for making an integrated circuit device, comprising:
forming a plurality of transistors on a semiconductor substrate;
forming multilayer interconnects by:
depositing a layer of metal;
patterning the metal layer;
depositing a first dielectric material having a first modulus;
depositing a second dielectric material having a second modulus higher than the first modulus of the first material
without performing chemical mechanical planarization, patterning the first and second dielectric materials and depositing a via filling metal material into the patterned areas;
wherein the first dielectric material is a hybrid material.

3-4. (canceled)

5. A method for making an integrated circuit device, comprising:
forming a plurality of transistors on a semiconductor substrate;
forming multilayer interconnects by:
depositing a layer of metal;
patterning the metal layer;
depositing a first dielectric material having a first modulus;
depositing a second dielectric material having a second modulus higher than the first modulus of the first material;
without performing chemical mechanical planarization, patterning the first and second dielectric materials and depositing a via filling metal material into the patterned areas, wherein the via filling metal material is at 65 nm or less.

6-9. (canceled)

10. A method for making an integrated circuit device, comprising:
forming a plurality of transistors on a semiconductor substrate;
forming multilayer interconnects by:
depositing a layer of metal;
patterning the metal layer;
depositing a first dielectric material having a first modulus;
depositing a second dielectric material having a second modulus higher than the first modulus of the first material;
removing 45% or less of the total thickness of the second dielectric material by chemical mechanical planarization, patterning the first and second dielectric materials and depositing a via filling metal material into the patterned areas, wherein the via filling metal material is at 65 nm or less.

11. A method for making an integrated circuit device, comprising:
forming a plurality of transistors on a semiconductor substrate;
forming multilayer interconnects by:
depositing a layer of metal;
patterning the metal layer;
depositing a first dielectric material having a first modulus;
depositing a second dielectric material having a second modulus higher than the first modulus of the first material;
patterning the first and second dielectric materials and depositing a via filling metal material into the patterned areas; wherein the depositing of the via filling metal material is at a temperature of 450° C. or more; and
wherein the first dielectric material has a modulus of 10 or less and the second dielectric material has a modulus of 40 or more.

12. (canceled)

13. A method for making an integrated circuit device, comprising:
forming a plurality of transistors on a semiconductor substrate;
forming multilayer interconnects by:
depositing a layer of metal;
patterning the metal layer;
depositing a first dielectric material having a first modulus;
depositing a second dielectric material having a second modulus higher than the first modulus of the first material;
patterning the first and second dielectric materials and depositing a via filling metal material into the patterned areas; wherein the depositing of the via filling metal material is at a temperature of 450° C. or more; and
wherein the first dielectric material is a hybrid organic-inorganic siloxane material.

14-15. (canceled)

16. A method for making an integrated circuit device, comprising:
forming a plurality of transistors on a semiconductor substrate;
forming multilayer interconnects by:
depositing a layer of metal;
patterning the metal layer;
depositing a first dielectric material having a first modulus;
depositing a second dielectric material having a second modulus higher than the first modulus of the first material;
without performing chemical mechanical planarization on the second dielectric material, patterning the first and second dielectric materials and depositing a via filling metal material into the patterned areas; wherein the depositing of the via filling metal material is at a temperature of 450° C. or more.

17. A method for making an integrated circuit device, comprising:
forming a plurality of transistors on a semiconductor substrate;
forming multilayer interconnects by:
depositing a layer of metal;
patterning the metal layer;
depositing a first dielectric material having a first modulus;
depositing a second dielectric material having a second modulus higher than the first modulus of the first material;
removing 45% or less of the total thickness of the second dielectric material by performing chemical mechanical planarization on the second dielectric material, patterning the first and second dielectric materials and depositing a via filling metal material into the patterned areas; wherein the depositing of the via filling metal material is at a temperature of 450° C. or more.

18. A method for making an integrated circuit device, comprising:
forming a plurality of transistors on a semiconductor substrate;
forming multilayer interconnects by:
depositing a first layer of metal;
patterning the metal layer;
depositing a first dielectric material having a first modulus;
depositing a second dielectric material having a second modulus higher than the first modulus of the first material;
removing 45% or less of the total thickness of the second dielectric material by chemical mechanical planarization, patterning the first and second dielectric materials and depositing a via filling metal material into the patterned areas, wherein a first metal gap distance is at 65 nm or less.

19. A method for making an integrated circuit device, comprising:
forming a plurality of transistors on a semiconductor substrate;
forming multilayer interconnects by:
depositing a layer of metal;
patterning the metal layer;
depositing a first dielectric material;
depositing a second dielectric material;
patterning the first and second dielectric materials and depositing a via filling metal material into the patterned areas; wherein the first dielectric material is a hybrid material having a carbon to silicon ratio of 1.5 to 1 or more.

20. A method for making an integrated circuit device, comprising:
forming transistors on a substrate;
depositing one of an electrically insulating or electrically conducting material;
patterning said one of an electrically insulating or electrically conducting material;
depositing the other of the electrically insulating or electrically conducting material, so as to form a layer over said transistors having both electrically insulating and electrically conducting portions;
wherein the electrically insulating material has a carbon to silicon ratio of 1.5 to 1 or more.

21. The method of claim 1, wherein the first dielectric material is a hybrid siloxane material.

22. The integrated circuit device of claim 21, wherein the hybrid material is a spin coated material.

23. The integrated circuit device of claim 22, wherein the hybrid material is a poly(organosiloxane) and has a coefficient of thermal expansion of 12 to 20 ppm.

24. (canceled)

25. The integrated circuit device of claim 21, wherein the deposited hybrid material has a glass transition temperature of 200° C. or more.

26. The integrated circuit device of claim 25, wherein the deposited hybrid material has a glass transition temperature of 400° C. or more.

27-28. (canceled)

29. The integrated circuit device of claim 21, wherein the hybrid material has a repeating -M-O-M-O— back-bone having a first organic substituent bound to the backbone, the material having a molecular weight of from 500 to 100,000 g/mol, where M is silicon and O is oxygen.

30. The integrated circuit device of claim 29, wherein the molecular weight is from 1,500 to 30,000 g/mol.

31-32. (canceled)

33. The integrated circuit device of claim 30, wherein the hybrid material comprises organic cross linking groups between adjacent -M-O-M-O— strands.

34-35. (canceled)

36. The integrated circuit device of claim 29, wherein the organic substitutent is a single or multi ring aryl group, an adamantyl group, or an alkyl group having from 1 to 4 carbons.

37. The integrated circuit device of claim 36, wherein the first organic substituent is an adamantyl group.

38. The integrated circuit device of claim 36, wherein the first organic substitutent is an aryl group.

39. The integrated circuit device of claim 36, wherein the first organic substituent is an alkyl group having from 1 to 5 carbon atoms.

40. The integrated circuit device of claim 21, wherein the hybrid material has a modulus of 4.0 GPa or more.

41. The integrated circuit device of claim 40, wherein the hybrid material has a modulus of 3.0 GPa or more.

42-45. (canceled)

46. The integrated circuit device of claim 29, wherein the hybrid material comprises methyl, vinyl, and adamantyl groups.

47-50. (canceled)

51. The method of claim 19, wherein the first dielectric material is a hybrid material having a carbon to silicon ratio of 1.5 to 1 or more.

52. The method of claim 51, wherein the first dielectric material is a hybrid material having a carbon to silicon ratio of 3 to 1 or more.

53. The method of claim 52, wherein the first dielectric material is a hybrid material having a carbon to silicon ratio of 10 to 1 or more.

54. The method of claim 20, wherein the dielectric material is a hybrid material having a carbon to silicon ratio of 1.5 to 1 or more.

55. The method of claim 54, wherein the dielectric material is a hybrid material having a carbon to silicon ratio of 3 to 1 or more.

56. The method of claim 55, wherein the dielectric material is a hybrid material having a carbon to silicon ratio of 10 to 1 or more.

57. An integrated circuit device, comprising: a substrate having transistors formed thereon; a layer over said transistors having alternating areas of electrically insulating and electrically conducting material; wherein the electrically insulating material has a carbon to silicon ratio of 1.5 to 1 or more.

58. The integrated circuit device of claim 57, wherein the carbon to silicon ratio is 3 to 1 or more.

59. The integrated circuit device of claim 57, wherein the carbon to silicon ratio is 10 to 1 or more.

60. The integrated circuit device of claim 29, wherein the hybrid material comprises methyl, vinyl and phenyl groups.

61. (canceled)
